(19) United States
(12) Patent Application Publication
(10) Pub. No.: US 2007/0298351 A1
(43) Pub. Date: Dec. 27, 2007

(54) IMAGE RECORDING MATERIAL, PLANOGRAPHIC PRINTING PLATE PRECURSOR, AND PLANOGRAPHIC PRINTING METHOD USING THE SAME

(75) Inventors: Kazuto SHIMADA, Shizuoka-ken (JP); Akihiro Endo, Shizuoka-ken (JP); Koji Wariishi, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 11/757,438

(22) Filed: Jun. 4, 2007

(30) Foreign Application Priority Data
Jun. 2, 2006 (JP) 2006-155266
Jul. 20, 2006 (JP) 2006-198634

(51) Int. Cl. G03F 7/20

(52) U.S. Cl. 430/281.1; 430/309

(57) ABSTRACT

The invention provides: an image recording material comprising a support having provided thereon in this order an image recording layer containing a binder polymer (A), a compound having a polymerizable unsaturated group (B), and a polymerization initiator (C), and a layer containing a hydrophilic polymer and a compound having within the molecule thereof an acid group and a partial structure functioning as a base.

### CROSS REFERENCES TO RELATED APPLICATIONS

This invention claims priority under 35 USC 119 from Japanese Patent Application Nos. 2006-155266 and 2006-198634, the disclosure of which is incorporated by reference herein.

### BACKGROUND OF THE INVENTION

1. Field of the Invention

The present invention relates to an image recording material, and more specifically, to an image recording material preferably used as a negative-working planographic printing plate precursor which allows so-called direct plate making, in which the precursor is directly made into a printing plate using a laser based on digital signals outputted from a computer or the like.

2. Description of the Related Art

As the conventionally known method of forming an image with a photopolymerizable composition by light exposure, there are various kinds of known methods such as a method of forming a hardened relief image by forming a recording layer using a photopolymerizable composition containing an ethylenically unsaturated compound and a photopolymerizable initiator on the surface of a support and then subjecting it to imagewise exposure to polymerize and cure the ethylenically unsaturated compound in a light-exposed portion, followed by removing a light-unexposed portion by dissolution, a method of forming an image by changing the bonding strength of a photopolymerizable composition layer (recording layer) to a support by light exposure and then removing the support, and a method of forming an image by utilizing a change in the adhesion of a toner to a photopolymerizable composition caused by light. The photopolymerization initiator used in each of these methods is an initiator that is responsive to light having shorter wavelength centered in the ultraviolet region of 400 nm or less, such as benzoin, benzoin alkyl ether, benzyl ketal, benzophenone, anthraquinone, benzyl ketone or Michler's ketone.

On the other hand, with the recent developments in the image formation techniques, photosensitive materials highly sensitive to lights in the visible region are strongly demanded. For example, many photopolymerizable compositions with a sensitivity range extended to about 500 nm are proposed for a laser plate making system employing an oscillation beam at 488 nm of an argon ion laser. Further, photopolymerizable compositions sensitive to lights in the longer wavelength range exceeding 600 nm are actively studied in response to laser plate making systems employing a He—Ne laser or semiconductor laser, and reproduction techniques for full color images.

There is a known photopolymerizable composition which includes an ethylenically unsaturated compound and a photopolymerization initiation system, wherein the photopolymerization initiation system is composed of a cyanine dye having a specific structure and heterocycles linked through a monomethine, trimethine, pentamethine, or heptamethine chain, and a s-triazine derivative having a specific structure (e.g. see Japanese Patent Application Laid-Open (JP-A) No. 58-29803 and JP-A 4-31863). Besides, another photopolymerizable composition containing a polymerization initiator system composed of a squarylium compound having a specific structure and a specific s-triazine compound is proposed (e.g. see JP-A No. 4-106548).

However in ordinary cases, for lights having a wavelength of 500 nm or more, particularly lights having a wavelength exceeding 600 nm, the active radical generating capacity of photopolymerization initiators is known to rapidly decrease in sensitivity with the decrease in the photoexcitation energy. Any of the above-described conventionally proposed photopolymerizable compositions does not has a sufficient sensitivity for lights in longer wavelength regions, and cause photopolymerization reaction during handling under a white fluorescent lamp. Under such circumstance, it is difficult to achieve a photopolymerizable composition of stable quality.

In order to increase the sensitivity of the photopolymerizable compositions and improve their handleability under a white light, a photopolymerizable composition and the like containing an ethylenically unsaturated compound, a specific dye, and a photopolymerization initiator (triazine compound, etc.) (e.g. triazine compound) are proposed (e.g. see JP-A No. 2000-131837).

However, when the composition is used in a recording layer of a planographic printing plate, radicals generated from the photopolymerization initiator can be deactivated by the influence of atmospheric oxygen to decrease the recording sensitivity. Therefore, the planographic printing plate must have an oxygen barrier layer composed of polyvinyl alcohol on the image recording layer for ensuring sensitivity. In often cases, a planographic printing plate having an oxygen barrier layer on the surface of an image recording layer is subjected to a water washing process to remove the water-soluble oxygen barrier layer before development in order to reduce the developing time and preventing the decrease of stability during development.

Although favorable developability is ensured by water washing, the water washing process requires additional apparatuses and drainage treatment. Therefore, a method for ensuring favorable developability without water washing is needed. In order to improve the removability (developability) of the oxygen barrier layer thereby eliminating the water washing process, it is studied to add a compound having higher hydrophilicity than polyvinyl alcohol to the oxygen barrier layer. This method improves the developability, however can decrease the sensitivity, which may result in decreased printing durability under exposure to the same amount of light.

Generally, a planographic printing plate includes a lipophilic image region receiving ink in a printing process and a hydrophilic non-image region receiving dampening water. Planographic printing is a method wherein the property of repellency between water and oil-based ink is utilized to cause a difference in adhesion of the ink to the surface of the planographic printing plate in which the lipophilic image region serves as an ink receiving part and the hydrophilic non-image region serves as a dampening water receiving part (part not receiving the ink), and the ink is allowed to adhere to only the image region and then transferred to a material to be printed such as paper.

For making such a planographic printing plate, a planographic printing plate precursor (PS plate) having a lipophilic photosensitive resin layer (image recording layer) arranged on a hydrophilic substrate has been widely used. Usually, the planographic printing plate is obtained by a method wherein the planographic printing plate precursor is exposed to light via an original image on a lithographic film or the like, and the image recording layer in the image region is allowed to remain, while the image recording layer in the non-image region is removed by dissolution with an alkali developing solution or an organic solvent, thereby exposing the surface of the hydrophilic substrate to make a printing plate.

In a plate-making process using a conventional planographic printing plate precursor, a process of removing the non-image region by dissolution with a developing solution corresponding to the image recording layer is necessary after exposure to light, and elimination or simplification of such additional wet treatment is mentioned as a task to be achieved. In recent years, disposal of waste liquid discharged in the wet treatment is a matter of high concern for the whole industry in consideration of the global environment, so there is an increasing demand for achieving this task.

In response to this demand, a method called in-machine development wherein an image recording layer from which a non-image region on a planographic printing plate precursor can be removed in an ordinary printing process is used and the non-image region is removed in a printing machine after exposure to light to provide a planographic printing plate has been proposed as an easy plate-making method.

Specifically, the method of in-machine development includes, for example, a method of using a planographic printing plate precursor having an image recording layer capable of being dissolved or dispersed in dampening water, an ink solvent or an emulsion of ink and dampening water, a method which involves physical removal of an image recording layer by contact with a roller or a blanket cylinder in a printing machine, and a method which involves physical removal of an image recording layer by contact with a roller or a blanket cylinder after weakening either the cohesive force of the image recording layer or the adhesion between the image recording layer and a substrate by permeation with dampening water, an ink solvent, or the like.

Unless otherwise noted, “development treatment process” in the invention refers to a process wherein the region of a planographic printing plate precursor which has not been exposed to light from an infrared laser is removed by contact with a liquid (usually an alkaline developing solution) in an apparatus (usually an automatic developing machine) other than a printing machine, to expose the surface of a hydrophilic substrate, and “in-machine development” refers to a method and process wherein the region of a planographic printing plate precursor which has not been exposed to light from an infrared laser is removed by contact with a liquid (usually printing ink and/or dampening water) in a printing machine. However, when an image recording layer in a conventional image recording system using ultraviolet rays or visible light is used, the image recording layer is not fixed even after light exposure, thus making it necessary to use a troublesome method wherein the exposed planographic printing plate precursor is stored in a completely shaded state or under thermostatic conditions until it is fitted into a printing machine.

In recent years, digitalization techniques which involve electronic processing, accumulation and output of image information with a computer are spreading, and a wide variety of new image output systems compatible with the digitalization techniques have come to be practically used. As a result, attention has been paid to computer-to-plate (CTP) techniques of producing a planographic printing plate directly by scanning a planographic printing plate precursor with highly directional light such as laser light carrying digitized image information without using a lithographic film. Accordingly, it is an important technical problem to provide a planographic printing plate precursor adapted to these techniques.

As described above, simplification of a plate-making operation as well as providing a dry, treatment-free plate-making operation has been desired more strongly than in the past because of concern about both the global environment and adaptation to digitalization.

Because high-power lasers such as semiconductor lasers, YAG lasers, and the like have come to be inexpensively available in recent years, a method of using such a high-power laser as an image recording means is regarded as a promising method of producing a planographic printing plate by scanning light which can be easily adapted to digitalization techniques.

The conventional plate-making method involves imagewise exposure to light at low to medium intensity, to record an image by an imagewise change in physical properties due to a photochemical reaction in the image recording layer. On the other hand, the method of using a high-power laser involves emitting a large amount of light energy in a very short time onto a region to be exposed to light, to convert the light energy efficiently into heat energy by which the image recording layer is caused to undergo thermal change such as a chemical change, a phase change, or a change in form or structure, and then utilizing the change in image recording. Accordingly, although the image information is outputted by light energy such as laser light, image recording is conducted not only by light energy but also by heat energy. Usually, the recording system using generation of heat by exposure to high-power density light is called heat mode recording, and conversion of light energy into heat energy is called light/heat conversion.

A great advantage of the plate-making method using heat mode recording is that the image recording layer is not sensitive to light at an ordinary intensity level such as interior illumination, and also that fixation of an image recorded by exposure to high-intensity light is not essential. That is, the planographic printing plate precursor used in heat mode recording is not sensitive to indoor light before light exposure is carried out, and fixation of the resulting image after light exposure is carried out is not essential. Accordingly, the plate-making process wherein an image recording layer to be made insoluble or soluble by exposure to light from a high-power laser is exposed to imagewise light to form a planographic printing plate can be carried out using in-machine development, thereby realizing a printing system wherein the image is not influenced even by exposure to indoor ambient light. Accordingly, it is expected that a planographic printing plate precursor used preferably in in-machine development can be obtained by utilizing heat mode recording.

The development of lasers in recent years has been remarkable, and in particular, high-power, small-size solid lasers and semiconductor lasers emitting infrared rays of wavelengths of from 760 to 1200 nm can be easily obtained. These infrared lasers are very useful as recording light sources for direct plate-making by digital data from computers, etc.

However, many photosensitive recording materials that are practically useful as the image recording layer have photosensitive wavelengths in the visible light range of 760 nm or less and therefore cannot be used in recording an image with an infrared laser. Accordingly, there is a need for materials capable of image recording with an infrared laser.

In response to this demand, for example, a planographic printing plate precursor including a hydrophilic support having thereon an image formation layer composed of hydrophobic thermoplastic polymer particles dispersed in a hydrophilic binder is described (e.g. see Japanese Patent No. 2938397). According to the description, the planographic printing plate precursor is exposed to infrared laser light, thereby hydrophobic thermoplastic polymer particles are heated and merged to form an image. After the light exposure, the precursor is mounted on a cylinder of a printing machine, and developed in the machine using a dampening water and/or an ink.

The image region formed by mere heat fusion of fine particles has very low strength, more specifically, adhesiveness between the support and image region, thus possess a problem of insufficient printing durability.

Examples of the planographic printing plates suitable for in-machine development include a planographic printing precursor including a hydrophilic support having thereon microcapsules containing a polymerizable compound (e.g. see JP-A No. 2001-277740, and JP-A No. 2001-277742), and a planographic printing plate precursor including a support having thereon a photosensitive layer containing an infrared ray absorbing agent, a radical polymerization initiator, and a polymerizable compound (e.g. see JP-A No. 2002-287334).

An image region formed through polymerization reaction has relatively higher strength than an image region formed by heat fusion of polymer fine particles owing to the high density of chemical bonds in the image region. However, from the viewpoint of practicality, the method does not provide sufficient in-machine developability, printing durability, and polymerization efficiency (sensitivity). Therefore, the method has not been implemented.

In the method of forming an image through polymerization reaction, a protective layer containing a hydrophilic polymer is often provided on an image recording layer in order to suppress polymerization inhibition by oxygen thereby improving the sensitivity. The protective layer improves the sensitivity, however must be removed together with the non-image region during printing, which tends to decrease the in-machine developability in comparison with those having no protective layer. In addition, removal of the protective layer may be made even harder by, for example, storage at high temperature, which can decrease the in-machine developability over time.

### SUMMARY OF THE INVENTION

The invention has been made in view of the above circumstances and provides an image recording material, planographic printing plate precursor, and planographic printing method using the same.

A first aspect of the invention provides an image recording material comprising a support having provided thereon in this order an image recording layer containing a binder polymer (A), a compound having a polymerizable unsaturated group (B), and a polymerization initiator (C), and a layer containing a hydrophilic polymer and a compound having within the molecule thereof an acid group and a partial structure functioning as a base.

### DETAILED DESCRIPTION

The image recording material of the present invention is provided in consideration of the above-described problems, and is composed of a support having provided thereon in this order an image recording layer containing (A) a binder polymer, (B) a compound having a polymerizable unsaturated group, and (C) a polymerization initiator, and a layer containing a hydrophilic polymer and a compound having within the molecule thereof an acid group and a partial structure functioning as a base.

It is preferable that the image recording layer preferably further contain (D) a dye having the absorption maximum in a range of from 300 to 1200 nm, and the polymerization initiator (C) be an onium salt from the viewpoint of sensitivity, and that the binder polymer (A) used in the image recording layer be a polymer having within the molecule thereof an alkali soluble group from the viewpoint of improving developability.

Further, it is preferable that an inorganic compound be contained in the layer containing a hydrophilic polymer and a compound having within the molecule thereof an acid group and a partial structure functioning as a base from the viewpoint of effectiveness.

The material of the invention is useful for both the planographic printing methods employing ordinary developing treatment, and employing no wet process developing treatment.

The planographic printing method according to one aspect of the invention includes an exposure process of imagewise exposing a planographic printing plate precursor to infrared laser light, and a printing process of supplying an oil-based ink and an aqueous component to the light-exposed planographic printing plate precursor and performing printing without subjecting the planographic printing plate precursor to any developing treatment, wherein the planographic printing plate precursor is composed of a support having provided thereon in this order an image recording layer which is recordable by irradiation with infrared rays and contains a binder polymer (A), a compound having a polymerizable unsaturated group (B), a polymerization initiator (C), and an infrared ray absorbing agent (D), and a layer containing a hydrophilic polymer and a compound having within the molecule thereof an acid group and a partial structure functioning as a base, and a portion of the planographic printing plate precursor unexposed to infrared laser light is removed during printing. The material of the invention is further described in detail below.

<Layer Containing a Hydrophilic Polymer and a Compound Having within the Molecule thereof an Acid Group and a Partial Structure Functioning as a Base>

A planographic printing plate precursor for printing method of the present invention contains a hydrophilic polymer and further a layer containing a compound having within the molecule thereof an acid group and a partial structure functioning as a base (The above layer is called as a specific protective layer in the following). A specific protective layer preferably contains mainly a hydrophilic polymer having high water solubility and high water dispersibility in the viewpoint of improving development performance.

When an image is formed on the planographic printing plate precursor, light exposure is normally conducted in the atmosphere. However, low molecular weight compounds in the atmosphere such as oxygen and basic substances inhibit the image formation reaction in the image recording layer initiated by light exposure. The planographic printing plate precursor of the invention includes the specific protective layer for the purpose of preventing the low molecular weight compounds from being included in the image recording layer, and thereby preventing the inhibition of the image formation reaction initiated by light exposure in the atmosphere. Accordingly, the specific protective layer according to the invention is desired to have low permeability to low molecular weight compounds such as oxygen, favorable permeability to light used for light exposure, and excellent adhesiveness to the image recording layer. In addition, when an automatic development system including developing process is employed, the specific protective layer after development is desired to be easily removed in the developing process.

Hydrophilic polymers commonly used in a protective layer have low oxygen permeability, however do not have sufficient developability. In the invention, improved developability is achieved with low oxygen permeability is maintained by combining the hydrophilic polymer with a compound having within the molecule thereof an acid group and a partial structure such as a basic group which functions as a base.

The specific protective layer according to the invention is composed essentially of a hydrophilic polymer (a) and a compound (b) having within the molecule thereof an acid group and a partial structure functioning as a base, and if desired, further contains an inorganic compound (c), which is preferably an inorganic layered compound (c-1).

The components contained in the specific protective layer will be described below.

[Water-Soluble Polymer (a)]

In the specific protective layer, the water-soluble polymer used as the main component, or the film forming component, is preferably a water-soluble polymer compound having relatively excellent crystallinity, and specific examples thereof include water-soluble polymers such as polyvinyl alcohol, polyvinyl pyrrolidone, acidic celluloses, gelatin, gum arabic, and polyacrylic acid. Among them, polyvinyl alcohol is particularly preferable as the main component from the viewpoint of achieving favorable basic properties such as oxygen impermeability and development removability.

Commercially available water-soluble polymers are also useful, and specific examples thereof include PVA-105, PVA-110, PVA-117, PVA-117H, PVA-120, PVA-124, PVA-124H, PVA-CS, PVA-CST, PVA-HC, PVA-203, PVA-204, PVA-205, PVA-210, PVA-217, PVA-220, PVA-224, PVA-217EE, PVA-217E, PVA-220E, PVA-224E, PVA-405, PVA-420, PVA-613, and L-8 (manufactured by Kuraray Co., Ltd.).

Polyvinyl alcohols according to the invention used in the specific protective layer may be used in combination with those partially substituted by ester, ether, or acetal as long as it contains unsubstituted vinyl alcohol units in an amount enough to develop required oxygen impermeability and water solubility. Also, it may be a copolymer which partially includes repeating units other than vinyl alcohol units.

Examples of the copolymer containing unsubstituted vinyl alcohol units and other repeating units include 88 to 100% hydrolyzed polyvinyl acetate chloroacetate or propionate, polyvinyl formal, polyvinyl acetal, and copolymers thereof. Examples of other useful water-soluble polymer compounds include polyvinyl pyrrolidone, gelatin, and gum arabic, which may be used alone or in combination thereof.

Examples of polyvinyl alcohols preferably used in the specific protective layer include those having a saponification degree of from 71 to 100%, and a molecular weight in a range of from 200 to 2400. It is more preferable to use a polyvinyl alcohol having a saponification degree of 91 mol % or more from the viewpoint of achieving favorable oxygen impermeability, excellent film forming property, and low adhesiveness of the surface.

Specifically, commercial polyvinyl alcohols usable in the recording layer include PVA-102, PVA-103, PVA-104, PVA-105, PVA-110, PVA-117, PVA-120, PVA-124, PVA-117H, PVA-135H, PVA-HC, PVA-617, PVA-624, PVA-706, PVA-613, PVA-CS and PVA-CST manufactured by Kuraray Co., Ltd., GOSENOL NL-05, NM-11, NM-14, AL-06, P-610, C-500, A-300 and AH-17 manufactured by Nippon Synthetic Chemical Industry Co., Ltd., and JF-04, JF-05, JF-10, JF-17, JF-17L, JM-05, JM-10, JM-17, JM-17L, JT-05, JT-13 and JT-15 manufactured by JAPAN VAM&POVAL CO., LTD.

Acid-modified polyvinyl alcohols can also be preferably used. Preferable examples include a carboxy-modified polyvinyl alcohol modified with itaconic acid or maleic acid and a polyvinyl alcohol modified with sulfonic acid. Use of an acid-modified polyvinyl alcohol having a saponification degree of 91 mol % or higher is more preferable.

Specific examples of the acid-modified polyvinyl alcohol include KL-118, KM-618, KM-118, SK-5102, MP-102 and R-2105 manufactured by Kuraray Co., Ltd., GOSENAL CKS-50, T-HS-1, T-215, T-350, T-330 and T-330H manufactured by Nippon Synthetic Chemical Industry Co., Ltd., and AF-17, AT-17 etc. manufactured by JAPAN VAM&POVAL CO., LTD.

From the viewpoint of adhesion to the image recording layer, sensitivity, and occurrence of unnecessary fogging, polyvinyl alcohol and polyvinyl pyrrolidone may be simultaneously used in the specific protective layer. As to the ratio between the respective components in this case, the ratio of (polyvinyl alcohol having a saponification degree of 91 mol % or more/polyvinyl pyrrolidone ratio (mass ratio)) is preferably not higher than 3/1. Other than polyvinyl pyrrolidone, acidic cellulose, gelatin, gum arabic, and polyacrylic acid, which are relatively high in crystallinity, and copolymers thereof can also be used in combination with polyvinyl alcohol.

The content of the water-soluble polymer (a) is preferably in a range of from 45 to 95% by mass, and more preferably in a range of from 50 to 90% by mass to the total solid content in the specific protective layer from the viewpoints of suppressing decrease in the sensitivity of the resulting planographic printing precursor, and suppressing adhesion between laminated planographic printing plate precursors.

The water-soluble polymer (a) may be used at least one kind, or in combination of a plurality kinds of them. Even when a plurality kinds of water-soluble polymer compounds are used, the total amount is preferably in the above-described mass range.

[Compound Having within the Molecule thereof an Acid Group and a Partial Structure Functioning as a Base (b)]

The compound having within the molecule thereof an acid group and a partial structure functioning as a base which is used in the specific protective layer according to the invention is not particularly limited as long as it has within one molecule thereof at least one acid group (acidic group) and at least one partial structure functioning as a base, preferably a basic functional group.

Examples of the acid group (acidic group) of the compound include a carboxyl group, phenol group (phenolic hydroxy group), sulfonic acid group, sulfinic acid group, phosphate group, phosphate group, monosulfate group, thiophenol group, and sulfonamide group.

The partial structure functioning as a base (basic functional group) is preferably an amino group, and may be a primary, secondary, or tertiary amine.

Other preferable examples of the compound having within one molecule thereof an acid group and a partial structure functioning as a base include a compound in which an acid group and a partial structure functioning as a base are present as a cation structure and an anion structure, respectively, which forms an intramolecular salt.

The compound is preferably a compound having (1) a cyclic structure and an amino group and (2) an acid group from the viewpoint of suppressing the variation in developability over time. Compounds having (1) a cyclic amino structure and (2) an acid group are also preferable.

The molecular weight is not particularly defined, but preferably in a range of 75 to 1000 from the viewpoint of developability.

Specific examples of the compound having within the molecule thereof an acid group and a partial structure functioning as a base which is useful in the invention are listed below, however the invention is not limited to the following compounds.

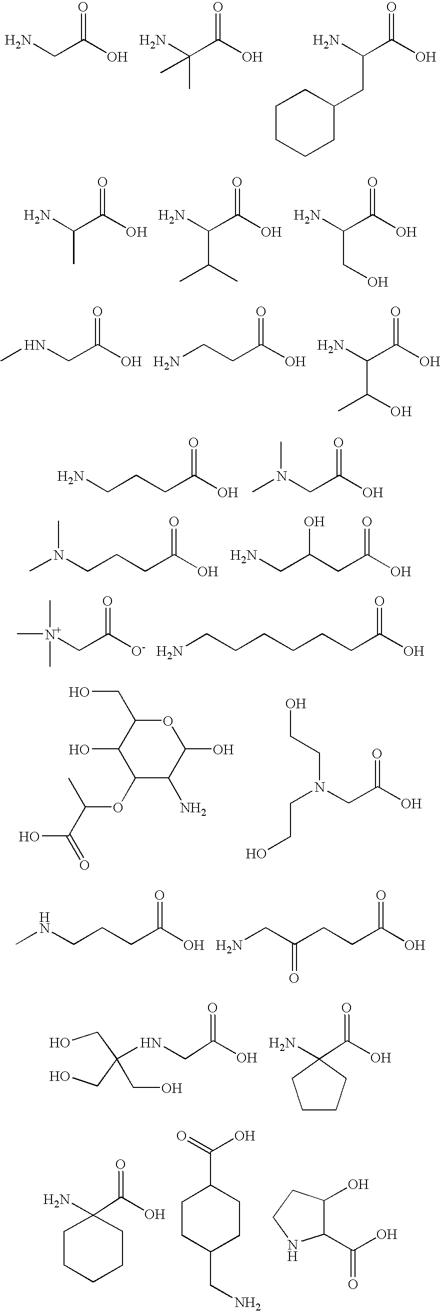

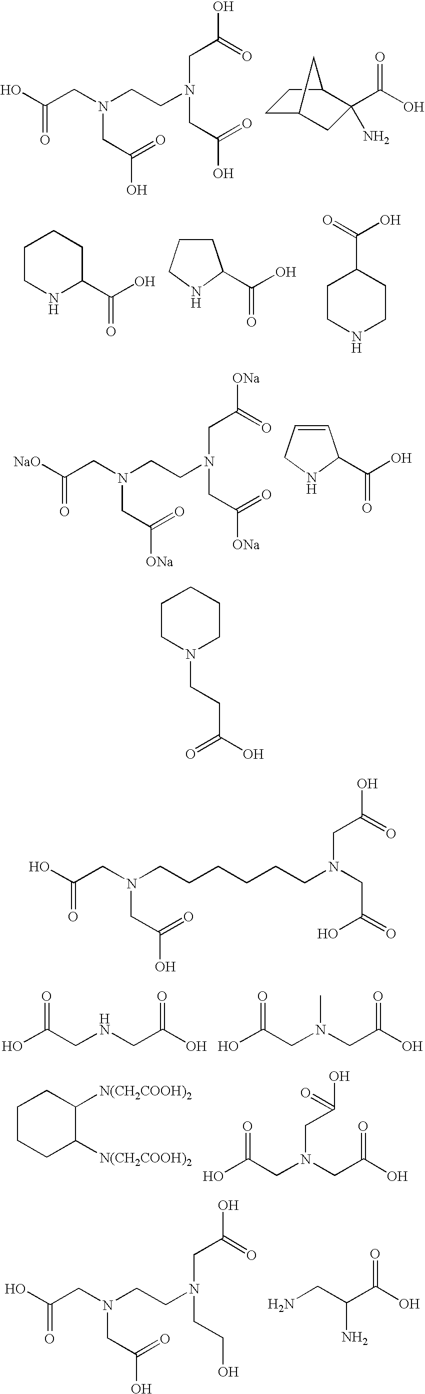

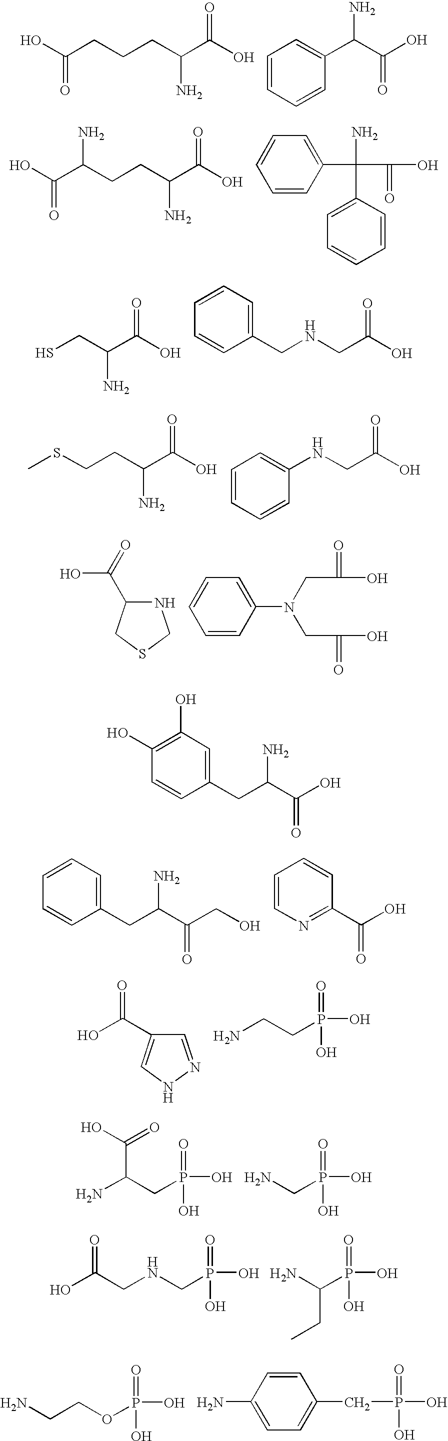

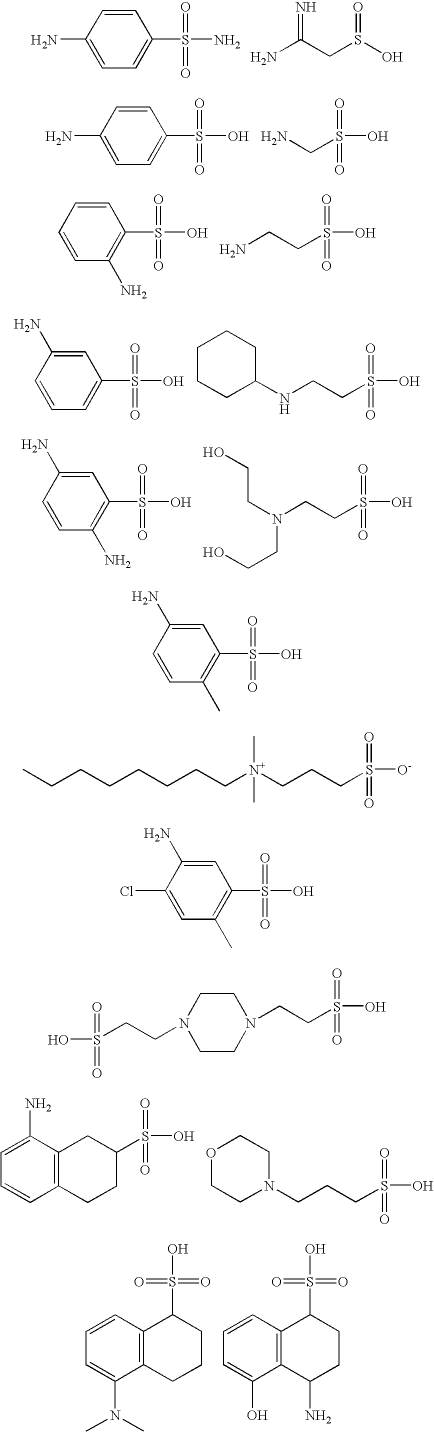

The solid content of the compound (b) having within the molecule thereof an acid group and a partial structure functioning as a base in the specific protective layer is preferably in a range of from 0.5% by mass to 50% by mass, more preferably from 1% by mass to 30% by mass, and most preferably from 2% by mass to 25% by mass.

As necessary, other components may be added to the specific protective layer containing a hydrophilic polymer and a compound having within the molecule thereof an acid group and a base.

The specific protective layer preferably contains an inorganic compound (c) from the viewpoint of improving oxygen permeability and abrasion resistance. The inorganic compound (c) refers to, for example, a metal oxide or an oxide having a plurality of metal atoms, and may be selected as appropriate from these compounds to achieve excellent oxygen impermeability and favorable light permeability. The compound is preferably soluble or dispersible in water. It is preferable that the inorganic layered compound (c-1) be used as the inorganic compound (c).

[Inorganic Layered Compound (c-1)]

The specific protective layer according to the invention preferably contains an inorganic layered compound, more specifically, an inorganic compound having a layered structure and a plate shape. The combined use of such an inorganic layered compound further improves the oxygen impermeability, further improves the film strength of the protective layer to improve the flaw resistance, and imparts matting property to the specific protective layer.

As a result, the specific protective layer, not only has oxygen impermeability as described above, but can also prevent flaws and deterioration due to deformation. By imparting matting property to the protective layer, the adhesion of the surface of the protective layer of a planographic printing plate precursor to the back surface of the support of an adjacent planographic printing plate precursor can be suppressed when planographic printing plate precursors are stacked.

In the case where the inorganic layered compound (preferably a mica compound) is used in combination with the “compound (b) having within the molecule thereof an acid group and a partial structure functioning as a base” in the specific protective layer, they are mixed in a solvent to make a protective layer coating solution with no precipitation of the inorganic layered compound. Generally, when an inorganic layered compound is used in combination with a hydrophilic compound having a highly polar hydrophilic site such as a sulfonic acid group alone or ammonium group alone, precipitation may be readily caused by mixing. The reason for the ready formation of a precipitate by combination of an inorganic layered compound and a compound having a hydrophilic site, however it is considered that the inorganic layered compound and the hydrophilic site interacts to form a precipitate. On the other hand, the “compound (b) having within the molecule thereof an acid group and a partial structure functioning as a base” used in the specific protective layer of the invention scarcely produces precipitates probably due to little interaction with an inorganic layered compound. It is thus considered that the combination use of an inorganic layered compound in the specific protective layer of the invention allows the efficient development in the addition effects of a mica compound and others.

Examples of the inorganic layered compound include mica compounds such as a natural mica and a synthetic mica represented by, for example, the Formula: A(B, C)₂-5D₄O₁₀(OH, F, O)₂ wherein A is K, Na or Ca; each of B and C is Fe(II), Fe(III), Mn, Al, Mg, or V; and D is Si or Al.

Examples of natural mica compounds include white mica, paragonite, bronze mica, black mica and flaky mica. Examples of synthetic mica compounds include non-swelling mica such as fluorine bronze mica KMg₃ (AlSi₃O₁₀)F₂ and potassium tetrasilicate mica KMg_{2.5}(Si₄O₁₀)F₂ and swelling mica such as Na tetrasilyric mica NaMg_{2.5} (Si₄O₁₀)F₂, Na or Li teniolite (Na, Li)Mg₂Li(Si₄O₁₀)F₂, montmorillonite type Na or Li hectorite (Na, Li)_{1/8}Ng_{2/5}Li_{1/8}(Si₄O₁₀)F₂. Synthetic smectite is also useful.

Among the mica compounds, fluorine-based swelling mica is particularly useful. More specifically, the swelling synthetic mica has a laminated structure composed of unit crystal latticed layers having a thickness of about 10 to 15 A, and the metal atom substitution within the lattice is considerably large in comparison with other clay minerals. Consequently, the latticed layer lacks a positive charge, and cations such as Na⁺, Ca²+ and Mg²⁺ are adsorbed between layers to compensate therefor. These interlayer cations are called exchangeable cations because they are exchanged with various cations. In particular, when the interlayer cations are Li⁺ or Na⁺ having a small ion radius, the layered crystal lattices are so weakly bonded each other that they cause large swelling by water. When the compound is sheared in this state, cleavage occurs easily and a stable sol is formed in water. Swelling synthetic mica exhibits a strong tendency to swell in this manner, and useful for an aspect of the invention. In particular, swelling synthesis mica is preferable from the viewpoints of availability and uniform quality.

The mica compound has a plate shape. The thickness of the compound is preferably smaller from the viewpoint of diffusion control, and the size of the plate is preferably larger as long as it does not impair the smoothness of the coated surface and permeability of active lights. Accordingly, the aspect ratio is 20 or more, preferably 100 or more, and most preferably 200 or more. The aspect ratio is a ratio of the thickness to major axis of a particle, and is measured from, for example, a microphotographic projection view of the particle. The higher the aspect ratio, the higher effect is achieved.

The particle diameter of the mica compound may be 0.3 to 20 μm, preferably 0.5 to 10 μm, more preferably 1 to 5 μm, in terms of the average length of the major axis. The average thickness of the particles may be 0.1 μm or less, preferably 0.05 μm or less, more preferably 0.01 μm or less. Specifically, the size of the swelling synthetic mica as a typical compound has a thickness of from 1 to 50 nm and a major axis length (plane size) of from about 1 to about 20 μm.

The amount of the inorganic layered compound contained in the specific protective layer is preferably in a range of from 5 to 50 mass %, more preferably in a range of from 10 to 40 mass %, based on the total solid content of the protective layer, from the viewpoint of suppression of the adhesion between the planographic printing plate precursors when stacked, suppression of flaw generation, deterioration in sensitivity due to shielding at the time of exposure to laser light, and low oxygen permeability. When plural inorganic layered compounds are simultaneously used, the total amount of the inorganic layered compounds is preferably in the range (mass %) described above.

The kind and content of the components of the specific protective layer, for example, a water-soluble polymer (a) such as polyvinyl alcohol, a compound (b) having within the molecule thereof an acid group and a partial structure functioning as a base, an inorganic layered compound (c-1), and other compounds such as additives, the coating amount of the specific protective layer, and other factors may be determined as appropriate in consideration of required oxygen impermeability, development removability, fogging property, adhesiveness, and flaw resistance.

The specific protective layer in the invention preferably has an oxygen permeability of 0.5 ml/m² per day or more and 100 ml/m² per day or less at 25° C. and 1 barometric pressure. It is preferable that the coating amount be adjusted in such a manner that the oxygen permeability is achieved.

The specific protective layer coating solution may contain known additives such as a surfactant for improving the coatability, and a water-soluble plasticizing agent for improving the physical property of the resulting coating film.

Examples of the water-soluble plasticizing agent or flexibilizer for the coating film include propionamide, cyclohexanediol, glycerol, and sorbitol dipropylene glycol, which can be added in an amount of several % by mass with respect to the water-soluble polymer (a). Further, a water-soluble (meth)acrylic polymer may be added. Examples of the surfactant include: anionic surfactants such as sodium alkylsulfate and sodium alkylsulfonate; amphoteric surfactants such as alkylamino carboxylates and alkylamino dicarboxylate; and nonionic surfactants such as polyoxyethylene alkyl phenyl ether, which can be added in an amount of several % by mass with respect to the water-soluble polymer (a).

The specific protective layer may also contain a coloring agent (water-soluble dye) which has excellent permeability to lights used for exposing the image recording layer, and efficiently absorbs lights having a wavelength not involved in the light exposure. As a result of this, the safelight suitability is improved with no decrease in the sensitivity.

[Formation of Specific Protective Layer]

Application of the protective layer is not particularly limited as to the method, and is performed by applying an aqueous coating solution for protective layer containing the above-described components onto the image recording layer which will be further described later. For example, the methods described in U.S. Pat. No. 3,458,311 or JP-A No. 55-49729 are also applicable.

The method for applying the protective layer containing an inorganic layered compound (c-1) such as a mica compound, a water-soluble polymer (a) such as polyvinyl alcohol, and a compound (b) having within the molecule thereof an acid group and a partial structure functioning as a base is further described below.

In the first place, the inorganic layered compound (c-1) such as a mica compound is dispersed to make a dispersion liquid, and the dispersion liquid is mixed with the water-soluble polymer (a) such as polyvinyl alcohol (or an aqueous solution of the water-soluble polymer) and the compound (b) having within the molecule thereof an acid group and a partial structure functioning as a base to form a protective layer coating solution, and the coating solution is applied onto the image recording layer to form a protective layer.

An example of the method for dispersing the inorganic layered compound such as a mica compound used for the protective layer is described below. In the first place, 5 to 10 parts by mass of a swelling mica compound, which has been exemplified as a preferable mica compound, to 100 parts by mass of water, thoroughly blended with water for swelling, and dispersed with a disperser.

Examples of the disperser include various mills which perform dispersion by mechanically applying direct force, a high-speed stirring dispersers having a large shearing force, and dispersers giving strong ultrasonic energy. Specific examples thereof include a ball mill, a sand grinder mill, a visco mill, a colloid mill, a homogenizer, a dissolver, a polytron, a homomixer, a homoblender, a keddy mill, a jet aditor, a capillary emulsifier, a liquid siren, an electromagnetic strictive ultrasonic wave generator, and an emulsifying device with a Paulman whistle.

Generally, 2 to 15% by mass of the dispersion of the mica compound dispersed by the above-described method is highly viscous or gelatinous, and has significantly favorable storage stability. When the dispersion is used for the preparation of the protective layer coating solution, it is preferable that the dispersion be diluted with water, thoroughly stirred, and then blended with a water-soluble polymer such as polyvinyl alcohol (or an aqueous solution of a water-soluble polymer such as polyvinyl alcohol).

The coating amount of the specific protective layer is preferably from 0.1 g/m² to 4.0 g/m², and more preferably from 0.3 g/m² to 3.0 g/m² in the viewpoints of the film strength and flaw resistance of the resulting protective layer, maintenance of the image quality, and adequate oxygen permeability for imparting safelight suitability.

The thickness of the protective layer is preferably from 0.1 to 5 μm, and particularly preferably from 0.2 to 2 μm. Other properties such as the adhesiveness to the image region and flaw resistance are also significantly important factors for handling the planographic printing plate precursor. More specifically, when the protective layer having hydrophilicity due to the water-soluble polymer component is laminated to the image recording layer having lipophilicity, insufficient adhesive force tends to cause the separation of the protective layer, where defects such as insufficient curing of the film may be caused by polymerization inhibition by oxygen.

Regarding the specific protective layer, the adhesiveness to the image region on the image recording layer and uniformity of the film are also regarded as significantly important properties. More specifically, when the hydrophilic protective layer composed mainly of a water-soluble polymer (a) is laminated to the lipophilic image recording layer, insufficient adhesive force tends to cause the separation of the protective layer, where defects such as insufficient curing of the film may occur due to polymerization inhibition by oxygen. For improving the adhesiveness between the two layers, various proposals have been made. For example, U.S. Application No. 292,501 and U.S. Application No. 44,563 describe that sufficient adhesiveness is achieved by adding 20 to 60% by mass of an acrylic emulsion or water-insoluble vinyl pyrrolidone-vinyl acetate copolymer to a hydrophilic polymer composed mainly of polyvinyl alcohol, and laminating to the image recording layer. These known techniques for improving the adhesiveness between an image recording layer and a hydrophilic layer such as the specific protective layer are all applicable for the planographic printing method of the invention, and the preparation of the planographic printing plate precursor of the invention used therefor.

<Image Recording Layer>

The image recording material of the invention is composed of a support; an image recording layer provided on the support, which contains (a) a binder polymer, (b) a compound having a polymerizable unsaturated group, and (c) a polymerization initiator; and the above-described specific protective layer formed on the surface of the image recording layer in a direct manner or via an appropriate layer for improving the adhesiveness.

The image recording layer preferably further contains (d) a dye having the absorption maximum in a range of from 300 to 1200 nm in the viewpoint of sensitivity.

In the image recording layer, the polymerization initiator (c) existing in the binder polymer (a) generates polymerization initiating species such as radicals upon heat and/or light energy, and the initiating species causes polymerization of the compound (b) having a polymerizable unsaturated group to cure the light-exposed portion alone. Thereafter the image recording layer is subjected to alkali developing treatment for rapidly removing the uncured region to form an image.

The components of the image recording layer will be described below.

[Polymerization Initiator (C)]

The polymerization initiator used in the invention may be a compound which generates radicals upon heat and/or light energy to initiate and promote the polymerization of a compound having a polymerizable unsaturated group. Specific examples thereof include known radical generators. The radical generator used in the invention may be a known heat polymerization initiator, a compound with smaller dissociation energy, or a photopolymerization initiator. The radical-generating compound preferably used in the invention refers to a compound which generates radicals upon heat energy to initiate and promote the polymerization of a compound having a polymerizable unsaturated group.

The polymerization initiator which generates radicals upon energy deposition may be contained alone or in combination of two or more of them in the image recording layer.

Examples of the radical generator include organic halogenated compounds (a), carbonyl compounds (b), organic peroxide compounds (c), azo-based polymerization initiators (d), azido compounds (e), metallocene compounds (f), hexaarylbiimidazol compounds (g), organic boric acid compounds (h), disulfon compounds (i), oxime ester compounds (j), and onium salt compounds (k).

These compounds will be described below.

Specific examples of the organic halogenated compounds (a) include the compounds described in, for example, Wakabayashi et al. “Bull Chem. Soc Japan” 42, 2924 (1969), U.S. Pat. No. 3,905,815, Japanese Patent Application Publication (JP-B) No. 46-4605, JP-A No. 48-36281, JP-A No. 55-32070, JP-A No. 60-239736, JP-A No. 61-169835, JP-A No. 61-169837, JP-A No. 62-58241, JP-A No. 62-212401, JP-A No. 63-70243, and JP-A No. 63-298339, M. P. Hutt “Journal of Heterocyclic Chemistry” 1 (No. 3), (1970)”, and particularly trihalomethyl group-substituted oxazole compounds and S-triazine compounds.

The organic halogenated compound is more preferably an s-triazine derivative wherein at least one mono, di or trihalogen-substituted methyl group is bonded to an s-triazine ring, and specific examples include 2,4,6-tris(monochloromethyl)-s-triazine, 2,4,6-tris(dichloromethyl)-s-triazine, 2,4,6-tris(trichloromethyl)-s-triazine, 2-methyl-4,6-bis(trichloromethyl)-s-triazine, 2-n-propyl-4,6-bis(trichloromethyl)-s-triazine, 2-(α,α,β-trichloroethyl)-4,6-bis(trichloromethyl)-s-triazine, 2-phenyl-4,6-bis(trichloromethyl)-s-triazine, 2-(p-methoxyphenyl)-4,6-bis(trichloromethyl)-s-triazine, 2-(3,4-epoxyphenyl)-4,6-bis(trichloromethyl)-s-triazine, 2-(p-chlorophenyl)-4,6-bis(trichloromethyl)-s-triazine, 2-[1-(p-methoxyphenyl)-2,4-butadienyl]-4,6-bis(trichloromethyl)-s-triazine, 2-styryl-4,6-bis(trichloromethyl)-s-triazine, 2-(p-methoxystyryl)-4,6-bis(trichloromethyl)-s-triazine, 2-(p-1-propyloxystyryl)-4,6-bis(trichloromethyl)-s-triazine, 2-(p-tolyl)-4,6-bis(tichloromethyl)-s-triazine, 2-(4-naphthoxynaphthyl)-4,6-bis(trichloromethyl)-s-triazine, 2-phenylthio-4,6-bis(trichloromethyl)-s-triazine, 2-benzylthio-4,6-bis(trichloromethyl)-s-triazine, 2,4,6-tris(dibromomethyl)-s-triazine, 2,4,6-tris(tribromomethyl)-s-triazine, 2-methyl-4,6-bis(tribromomethyl)-s-triazine, 2-methoxy-4,6-bis(tribromomethyl)-s-triazine, etc.

Examples of the carbonyl compound (b) include benzophenone, benzophenone derivatives such as Michler's ketone, 2-methyl benzophenone, 3-methyl benzophenone, 4-methyl benzophenone, 2-chlorobenzophenone, 4-bromobenzophenone, 2-carboxybenzophenone, etc., acetophenone derivatives such as 2,2-dimethoxy-2-phenyl acetophenone, 2,2-diethoxy acetophenone, 1-hydroxycyclohexylphenyl ketone, α-hydroxy-2-methyl phenyl propane, 1-hydroxy-1-methylethyl-(p-isopropylphenyl)ketone, 1-hydroxy-1-(p-dodecylphenyl)ketone, 2-methyl-(4′-(methylthio)phenyl)-2-morpholino-1-propanone, 1,1,1-trichloromethyl-(p-butylphenyl)ketone, etc., thioxanthone, thioxanthone derivatives such as 2-ethyl thioxanthone, 2-isopropyl thioxanthone, 2-chlorothioxanthone, 2,4-dimethyl thioxanthone, 2,4-diethyl thioxanthone, 2,4-diisopropyl thioxanthone, etc., and benzoate esters such as ethyl p-dimethylaminobenzoate, ethyl p-diethylaminobenzoate, etc.

Examples of the organic peroxide compounds (c) include trimethylcyclohexanone peroxide, acetylacetone peroxide, 1,1-bis(tert-butylperoxy)-3,3,5-trimethylcyclohexane, 1,1-bis(tert-butylperoxy)cyclohexane, 2,2-bis(tert-butylperoxy)butane, tert-butylhydroperoxide, cumenehydroperoxide, diisopropylbenzenehydroperoxide, 2,5-dimethylhexane-2,5-dihydroperoxide, 1,1,3,3-tetramethylbutylhydroperoxide, tert-butylcumylperoxide, dicumylperoxide, 2,5-dimethyl-2,5-di(tert-butylperoxy)hexane, 2,5-oxanoylperoxide, succinic acid peroxide, benzoyl peroxide, 2,4-dichlorobenzoyl peroxide, diisopropylperoxy dicarbonate, di-2-ethylhexylperoxy dicarbonate, di-2-ethoxyethylperoxy dicarbonate, dimethoxyisopropylperoxy carbonate, di(3-methyl-3-methoxybutyl)peroxy dicarbonate, tert-butylperoxy acetate, tert-butylperoxy pivalate, tert-butylperoxyneodecanoate, tert-butylperoxy octanoate, tert-butylperoxy laurate, tertiary carbonate, 3,3′,4,4′-tetra-(t-butylperoxycarbonyl)benzophenone, 3,3′,4,4′-tetra-(t-hexylperoxycarbonyl)benzophenone, 3,3,4,4′-tetra-(p-isopropylcumylperoxycarbonyl)benzophenone, carbonyldi(t-butylperoxydihydrogen diphthalate), and carbonyldi(t-hexylperoxydihydrogen diphthalate).

Example of the azo-based polymerization initiators (d) include azo compounds described in JP-A No. 8-108621.

Examples of the azido compounds (e) include 2,6-bis(4-azidobenzylidene)-4-methylcyclohexanone.

Examples of the metallocene compounds (f) include various titanocene compounds described in JP-A No. 59-152396, JP-A No. 61-151197, JP-A No. 63-41484, JP-A No. 2-249, JP-A No. 2-4705, and JP-A No. 5-83588, such as di-cyclopentadienyl-Ti-bis-phenyl, di-cyclopentadienyl-Ti-bis-2,6-difluorophen-1-yl, di-cyclopentadienyl-Ti-bis-2,4-di-fluorophen-1-yl, di-cyclopentadienyl-Ti-bis-2,4,6-trifluorophen-1-yl, di-cyclopentadienyl-Ti-bis-2,3,5,6-tetrafluorophen-1-yl, di-cyclopentadienyl-Ti-bis-2,3,4,5,6-pentafluorophen-1-yl, di-methylcyclopentadienyl-Ti-bis-2,6-difluorophen-1-yl, di-methyl cyclopentadienyl-Ti-bis-2,4,6-trifluorophen-1-yl, di-methylcyclopentadienyl-Ti-bis-2,3,5,6-tetrafluorophen-1-yl, di-methylcyclopentadienyl-Ti-bis-2,3,4,5,6-pentafluorophen-1-yl, and iron-allene complexes described in JP-A No. 1-304453 and JP-A No. 1-152109.

Examples of the hexaarylbiimidazol compounds (g) include various compounds described in JP-B No. 6-29285, U.S. Pat. No. 3,479,185, U.S. Pat. No. 4,311,783, and U.S. Pat. No. 4,622,286, such as 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methyl phenyl)-4,4′,5,5′-tetraphenylbiimidazole, and 2,2′-bis(o-trifluorophenyl)-4,4′,5,5′-tetraphenyl biimidazole.

Specific examples of the (h) organic boric aid compounds include organic borates described in, for example, JP-A No. 62-143044, JP-A No. 62-150242, JP-A No. 9-188685, JP-A No. 9-188686, JP-A No. 9-188710, JP-A No. 2000-131837, JP-A No. 2002-107916, Japanese Patent No. 2764769, Japanese Patent Application No. 2000-310808, and Kunz, Martin ‘Rad Tech’ 98. Proceeding Apr. 19-22, 1998, Chicago”, organic boron sulfonium complexes or organic boron oxosulfonium complexes described in JP-A No. 6-157623, JP-A No. 6-175564, and JP-A No. 6-175561, organic boron iodonium complexes described in JP-A No. 6-175554 and JP-A No. 6-175553, organic boron phosphonium complexes described in JP-A No. 9-188710, and organic boron transition metal coordination complexes described in JP-A No. 6-348011, JP-A No. 7-128785, JP-A No. 7-140589, JP-A No. 7-306527, and JP-A No. 7-292014.

Examples of the disulfone compounds (i) include compounds described in JP-A No. 61-166544, and Japanese Patent Application No. 2001-132318.

Examples of the oxime ester compounds (j) include compounds described in J. C. S. Perkin II, pp. 1653-1660 (1979), J. C. S. Perkin II, pp. 156-162 (1979), Journal of Photopolymer Science and Technology, pp. 202-232 (1995) and JP-A No. 2000-66385, and compounds described in JP-A No. 2000-80068, and specific examples thereof include the following compounds.

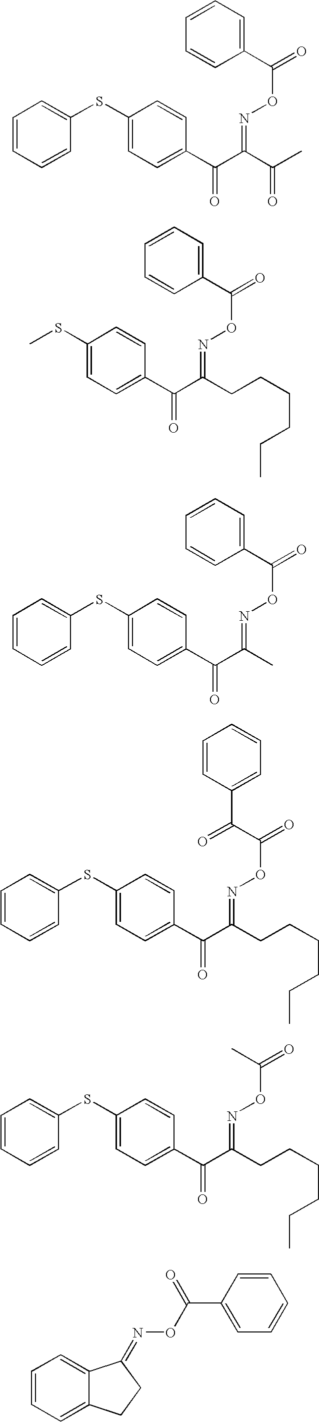

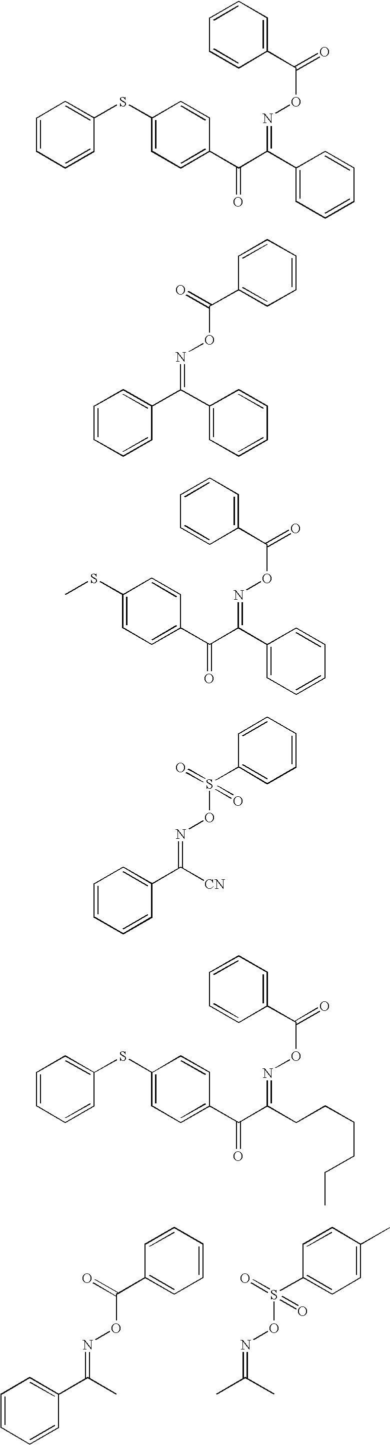

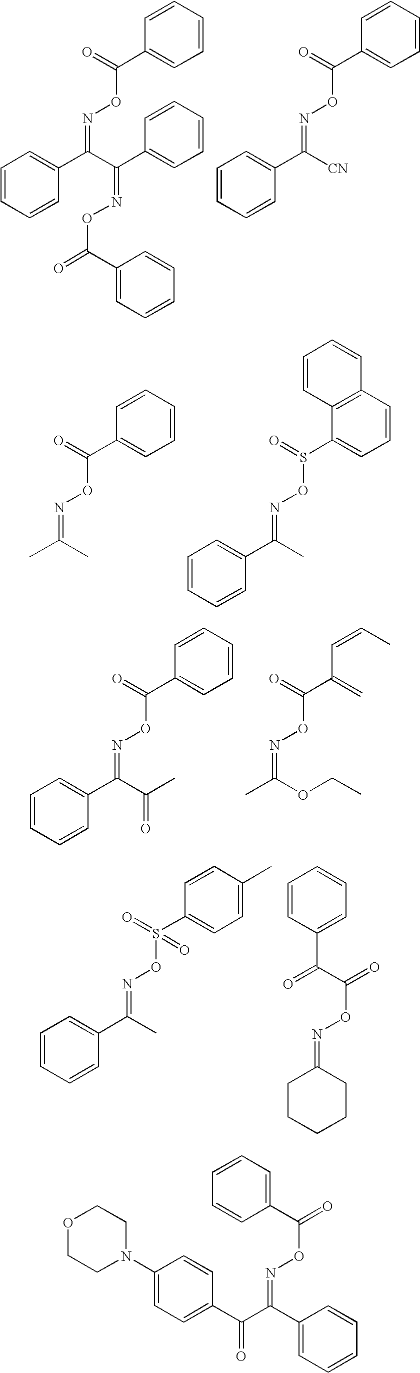

Examples of theonium salt compounds (k) include diazonium salts described in S. I. Schlesinger, Photogr, Sci, Eng., 18,387 (1974), T. S. Bal et al, Polymer, 21,423 (1980), ammonium salts described in U.S. Pat. No. 4,069,055 and JP-A No. 4-365049, phosphonium salts described in U.S. Pat. No. 4,069,055 and U.S. Pat. No. 4,069,056, iodonium salts described in European Patent Application No. 104,143, U.S. Pat. No. 339,049 and U.S. Pat. No. 410,201, JP-A No. 2-150848 and JP-A No. 2-296514, sulfonium salts described in European Patent Application No. 370,693, European Patent Application No. 390,214, European Patent Application No. 233,567, European Patent Application No. 297,443, European Patent Application No. 297,442, U.S. Pat. No. 4,933,377, U.S. Pat. No. 161,811, U.S. Pat. No. 410,201, U.S. Pat. No. 339,049, U.S. Pat. No. 4,760,013, U.S. Pat. No. 4,734,444, U.S. Pat. No. 2,833,827, German Patent No. 2,904,626, German Patent No. 3,604,580, and German Patent No. 3,604,581, selenonium salts described in J. V. Crivello et al, Macromolecules, 10 (6), 1307 (1977), J. V. CriveIlo et al, J. Polymer Sci., Polymer Chem, Ed., 17, 1047 (1979), and arsonium salts described in C. S. Wen et al, Teh, Proc. Conf. Rad, Curing ASIA, p. 478, Tokyo, October (1988).

From the viewpoint of the reactivity and stability, the above-described oxime ester compounds and diazonium salts, iodonium salts, and sulfonium salts, which will be further described later, are particularly preferable examples of the polymerization initiator. In the invention, the onium salt functions not as an acid generator, but as an ionic radical polymerization initiator.

In the invention, the onium salts represented by the following Formulae (RI-I) to (RI-III) are preferable.

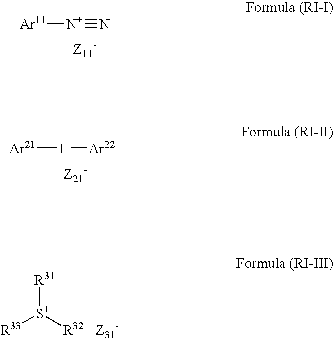

In the Formula (RI-I), Ar¹¹ represents an aryl group containing 20 or less carbon atoms, which may have 1 to 6 substituents, and the substituents are preferably selected from alkyl groups each containing 1 to 12 carbon atoms, alkenyl groups each containing 1 to 12 carbon atoms, alkynyl groups each containing 1 to 12 carbon atoms, aryl groups each containing 1 to 12 carbon atoms, alkoxy groups each containing 1 to 12 carbon atoms, aryloxy groups each containing 1 to 12 carbon atoms, halogen atoms, alkylamino groups each containing 1 to 12 carbon atoms, dialkylamino groups each containing 1 to 12 carbon atoms, alkyl amide groups each containing 1 to 12 carbon atoms, aryl amide groups each containing 1 to 12 carbon atoms, carbonyl groups, carboxyl groups, cyano groups, sulfonyl groups, thioalkyl groups each containing 1 to 12 carbon atoms, and thioaryl groups each containing 1 to 12 carbon atoms. Z¹¹⁻ represents a monovalent anion which may be selected from a halogen ion, a perchlorate ion, a hexafluorophosphate ion, a tetrafluoroborate ion, a sulfonate ion, a sulfinate ion, a thiosulfonate ion and a sulfate ion. Z¹¹⁻ preferably represents a perchlorate ion, a hexafluorophosphate ion, a tetrafluoroborate ion, a sulfonate ion, a sulfinate ion, or a carboxylate ion from the viewpoint of stability and reactivity.

In the Formula (RI-II), Ar²¹ and Ar²² each independently represent an aryl group containing 20 or less carbon atoms, which may have 1 to 6 substituents, and the substituents are preferably selected from alkyl groups each containing 1 to 12 carbon atoms, alkenyl groups each containing 1 to 12 carbon atoms, alkynyl groups each containing 1 to 12 carbon atoms, aryl groups each containing 1 to 12 carbon atoms, alkoxy groups each containing 1 to 12 carbon atoms, aryloxy groups each containing 1 to 12 carbon atoms, halogen atoms, alkylamino groups each containing 1 to 12 carbon atoms, dialkylamino groups each containing 1 to 12 carbon atoms, alkyl amide groups each containing 1 to 12 carbon atoms, aryl amide groups each containing 1 to 12 carbon atoms, carbonyl groups, carboxyl groups, cyano groups, sulfonyl groups, thioalkyl groups each containing 1 to 12 carbon atoms, and thioaryl groups each containing 1 to 12 carbon atoms. Z²¹⁻ represents a monovalent anion which may be selected from a halogen ion, a perchlorate ion, a hexafluorophosphate ion, a tetrafluoroborate ion, a sulfonate ion, a sulfinate ion, a thiosulfonate ion and a sulfate ion. Z²¹⁻ preferably represents a perchlorate ion, a hexafluorophosphate ion, a tetrafluoroborate ion, a sulfonate ion, or a sulfinate ion from the viewpoint of stability.

In the Formula (RI-III), R³¹, R³² and R³³ each independently represent an aryl group, alkyl group, alkenyl group or alkynyl group containing 20 or less carbon atoms which may have 1 to 6 substituents, and is preferably an aryl group in respect of reactivity and safety. The substituents are preferably selected from alkyl groups each containing 1 to 12 carbon atoms, alkenyl groups each containing 1 to 12 carbon atoms, alkynyl groups each containing 1 to 12 carbon atoms, aryl groups each containing 1 to 12 carbon atoms, alkoxy groups each containing 1 to 12 carbon atoms, aryloxy groups each containing 1 to 12 carbon atoms, halogen atoms, alkylamino groups each containing 1 to 12 carbon atoms, dialkylamino groups each containing 1 to 12 carbon atoms, alkyl amide groups each containing 1 to 12 carbon atoms, aryl amide groups each containing 1 to 12 carbon atoms, carbonyl groups, carboxyl groups, cyano groups, sulfonyl groups, thioalkyl groups each containing 1 to 12 carbon atoms, and thioaryl groups each containing 1 to 12 carbon atoms. Z³¹⁻ represents a monovalent anion which may be selected from a halogen ion, a perchlorate ion, a hexafluorophosphate ion, a tetrafluoroborate ion, a sulfonate ion, a sulfinate ion, a thiosulfonate ion and a sulfate ion. Z³¹⁻ preferably represents a perchlorate ion, a hexafluorophosphate ion, a tetrafluoroborate ion, a sulfonate ion, a sulfinate ion, or a carboxylate ion from the viewpoint of stability and reactivity. In an embodiment, Z³¹⁻ represents a carboxylate ion disclosed in JP-A 2001-343742, the disclosure of which is incorporated by reference herein. In another embodiment, Z³¹⁻ represents a carboxylate ion disclosed in JP-A 2002-148790, the disclosure of which is incorporated by reference herein.

Examples of the polymerization initiator usable in the invention are shown below. However, the examples should not be construed as limiting the invention.

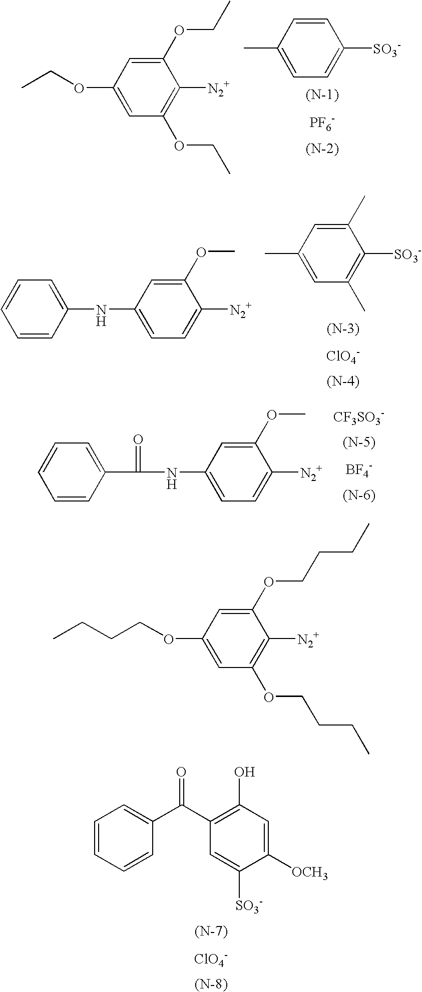

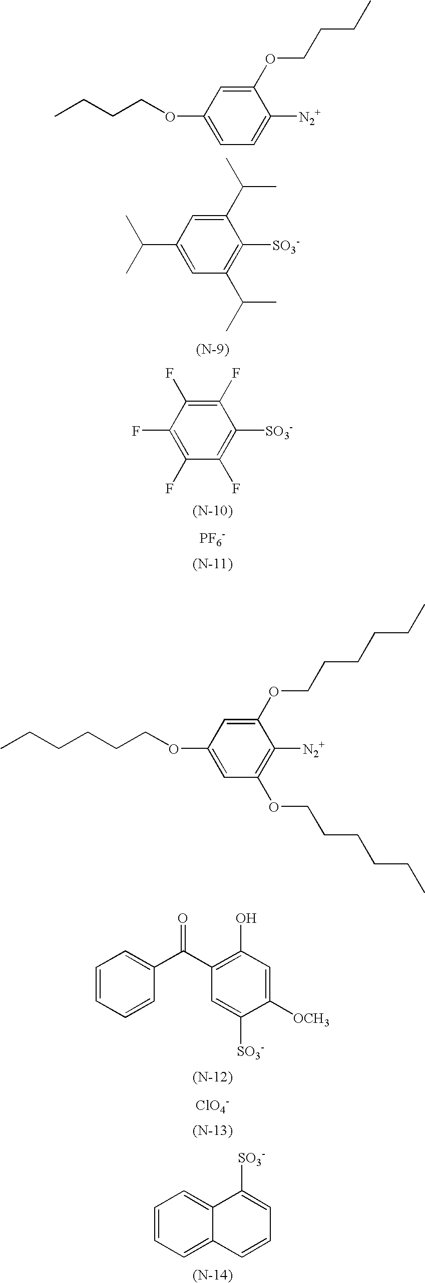

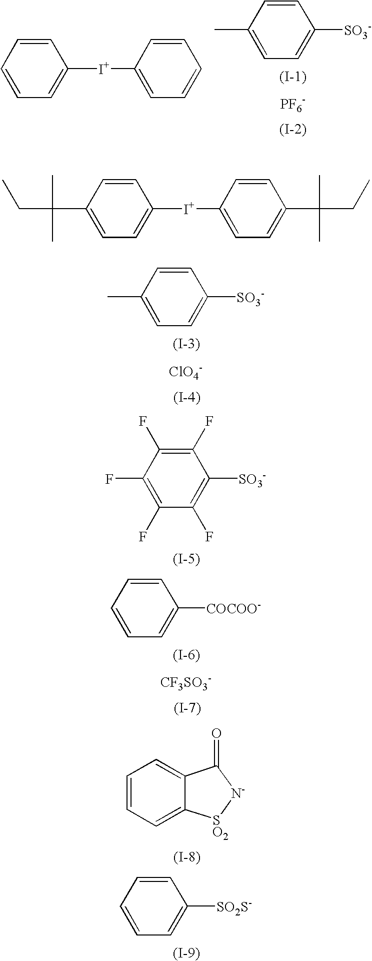

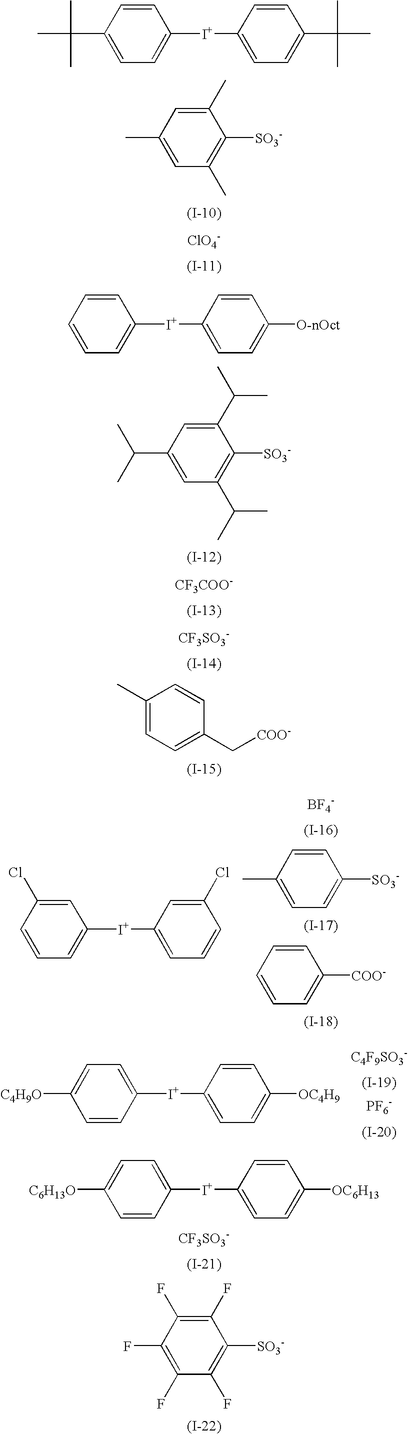

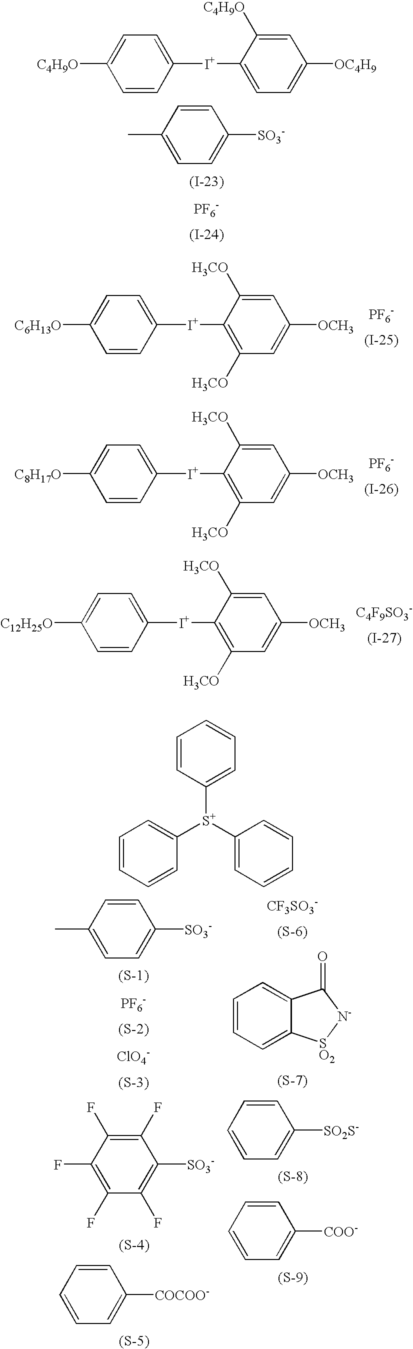

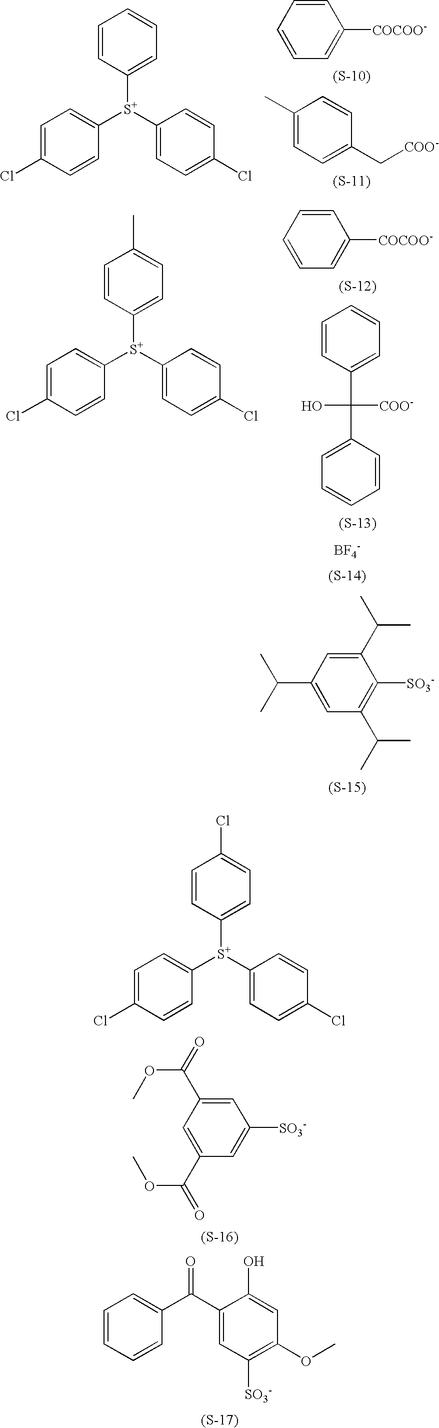

Among the above-described compounds, diazonium salts, iodonium salts, and sulfonium salts included in oxime ester compounds (j) or (k) onium chlorides are preferable as the polymerization initiator in the invention from the viewpoint of particularly the reactivity and stability. In the invention, the onium salt functions not as an acid generator, but an ionic radical polymerization initiator.

The polymerization initiator in the invention is particularly preferably an iodonium salt having an electron-donating group or sulfonium salt having an electron-withdrawing group from the viewpoint of the balance between the reactivity and stability, and in particular, an iodonium salt having two or more alkoxy groups in its skeleton with a cation portion is preferable, and an iodonium salt having three or more alkoxy groups is most preferable.

The polymerization initiator (C) is used in an amount of from 0.1 to 50% by mass, preferably from 0.5 to 30% by mass, most preferably from 1 to 20% by mass with respect to the total solid content composing the image recording layer. When the amount is within the range, favorable sensitivity and favorable stain resistance of the non-image region during printing are achieved. The polymerization initiator may be used alone, or in combination of two or more of them. The polymerization initiator may be added to the same layer together with other components, or may be added to an independently formed layer.

[Binder Polymer (A)]

This section describes the binder polymer used for developing treatment, more specifically for removal of the non-image region after light exposure by dissolving with a developer or the like according to the image recording layer.

For the purpose of improving the coating property of the recording layer to be formed, as necessary, a binder polymer may be used. The binder is preferably a linear organic polymer. The “linear organic polymer” may be freely selected from known ones. It is preferable to select a linear organic polymer which is soluble or swells in water or weak alkaline water for allowing water development or weak alkaline development. The linear organic polymer is selected and used not only as an agent for forming a coating film of the image recording material, but also as a water, weak alkaline water, or organic solvent developer.

In the invention, it is preferable to use a polymer having within the molecule thereof an alkali-soluble group to achieve favorable alkali developability.

For example, the use of a water-soluble organic polymer allows water development. Examples of the linear organic polymer include radical polymers having in the side chain thereof a carboxylic acid group described in, for example, JP-A No. 59-44615, JP-B No. 54-34327, JP-B No. 58-12577, and JP-B No. 54-25957, JP-A No. 54-92723, JP-A No. 59-53836, and JP-A No. 59-71048, and specific examples thereof include resins prepared by homopolymerizing or copolymerizing monomers having a carboxyl group, resins prepared by hydrolyzing, half-esterifying, or half-amidating an acid anhydride unit prepared by homopolymerizing or copolymerizing monomers having an acid anhydride, and epoxy acrylates prepared by modifying an epoxy resin with an unsaturated monocarboxylic acid and an acid anhydride. Examples of the monomers having a carboxyl group include acrylic acid, methacrylic acid, itaconic acid, crotonic acid, maleic acid, fumaric acid, and 4-carboxylstyrene, and examples of the monomers having an acid anhydride include maleic anhydride.

Other examples include acidic cellulose derivatives having in the side chain thereof a carboxylic acid group. An adduct of a hydroxy group-containing polymer and a cyclic acid anhydride is also useful.

In the case where a copolymer of an alkali soluble resin is used, the compound to be copolymerized with the resin may be a monomer other than the above-described monomers. Examples of the other monomers include the following compounds listed in (1) to (13):

(1) acrylic esters and methacrylic acid esters having an aliphatic hydroxy group such as 2-hydroxyethyl acrylate, 2-hydroxypropyl acrylate, 3-hydroxypropyl acrylate, 4-hydroxybutyl acrylate, 2-hydroxyethyl methacrylate, 2-hydroxypropyl methacrylate, 3-hydroxypropyl methacrylate, and 4-hydroxybutyl methacrylate;

(2) alkyl acrylates such as methyl acrylate, ethyl acrylate, acrylate propyl, butyl acrylate, isobutyl acrylate, amyl acrylate, hexyl acrylate, 2-ethylhexyl acrylate, octyl acrylate, benzyl acrylate, 2-chloroethyl acrylate, glycidyl acrylate, 3,4-epoxycyclohexylmethyl acrylate, vinyl acrylate, 2-phenylvinyl acrylate, 1-propenyl acrylate, allyl acrylate, 2-allyloxyethyl acrylate, and propargyl acrylate;

(3) alkyl methacrylates such as methyl methacrylate, ethyl methacrylate, propyl methacrylate, butyl methacrylate, isobutyl methacrylate, amyl methacrylate, hexyl methacrylate, 2-ethylhexyl methacrylate, cyclohexyl methacrylate, benzyl methacrylate, 2-chloroethyl methacrylate, glycidyl methacrylate, 3,4-epoxycyclohexylmethyl methacrylate, vinyl methacrylate, 2-phenylvinyl methacrylate, 1-propenyl methacrylate, allyl methacrylate, 2-allyloxyethyl methacrylate, and propargyl methacrylate;

(4) acrylamides or methacrylamides such as acrylamide, methacrylamide, N-methylolacrylamide, N-ethylacrylamide, N-hexylmethacrylamide, N-cyclohexylacrylamide, N-hydroxyethylacrylamide, N-phenylacrylamide, N-nitrophenylacrylamide, N-ethyl-N-phenylacrylamide, vinylacrylamide, vinylmethacrylamide, N,N-diallylacrylamide, N,N-diallylmethacrylamide, allylacrylamide, and allylmethacrylamide;

(5) vinyl ethers such as ethyl vinyl ether, 2-chloroethyl vinyl ether, hydroxyethyl vinyl ether, propyl vinyl ether, butyl vinyl ether, octyl vinyl ether, and phenyl vinyl ether;

(6) vinyl esters such as vinyl acetate, vinyl chloroacetate, vinyl butylate, and vinyl benzoate;

(7) styrenes such as styrene, α-methylstyrene, methylstyrene, chloromethylstyrene, and p-acetoxystyrene;

(8) vinyl ketones such as methyl vinyl ketone, ethyl vinyl ketone, propyl vinyl ketone, and phenyl vinyl ketone;

(9) olefins such as ethylene, propylene, isobutylene, butadiene, and isoprene;

(10) N-vinylpyrrolidone, acrylonitrile, methacrylonitrile, and the like;

(11) unsaturated imides such as maleimide, N-acryloylacrylamide, N-acetylmethacrylamide, N-propionylmethacrylamide, and N-(p-chlorobenzoyl)methacrylamide; and

(12) methacrylate monomers having a hetero atom in the a position, examples thereof include compounds described in Japanese Patent Application No. 2001-115595 and Japanese Patent Application No. 2001-115598.

Among them, preferable are (meth)acrylic resins having in the side chain thereof an allyl group or a vinyl ester group and a carboxyl group, alkali soluble resins having in the side chain thereof a double bond described in JP-A No. 2000-187322 and JP-A No. 2002-62698, and alkali soluble resins having in the side chain thereof an amide group described in JP-A No. 2001-242612, from the viewpoints of excellent balance between the film strength, sensitivity, and developability.

Urethane-containing binder polymers containing an acid group as described in JP-B No. 7-12004, JP-B No. 7-120041, JP-B No. 7-120042, JP-B No. 8-12424, JP-A No. 63-287944, JP-A No. 63-287947, JP-A No. 1-271741 and JP-A No. 10-116232 and urethane-containing binder polymers containing an acid group and a double bond as described in JP-A No. 2002-107918 are very excellent in strength and thus advantageous in respect of printing durability and low-exposure suitability.

Acetal-modified polyvinyl alcohol-containing binder polymers having an acid group as described in EP993966, EP1204000, and JP-A No. 2001-318463 are preferable because they are excellent in the balance between film strength and developability.

As other water-soluble linear organic compounds, polyvinyl pyrrolidone and polyethylene oxide are useful. To increase the strength of the cured film, alcohol-soluble nylon, polyethers of 2,2-bis-(4-hydroxyphenyl)-propane and epichlorohydrin, etc. are also useful.

The weight-average molecular weight of the polymer used in the invention is preferably from 5000 or more, more preferably in a range of from 10,000 to 300,000, and the number-average molecular weight thereof is preferably 1,000 or more, more preferably in a range of from 2,000 to 250,000. Polydispersity (weight-average molecular weight/number-average molecular weight) is preferably 1 or more, more preferably in a range of from 1.1 to 10.

The polymer may be a random polymer, a block polymer or a graft polymer.

The polymer used in the invention can be synthesized in a method known in the art. Examples of the solvent used in synthesis include tetrahydrofuran, ethylene dichloride, cyclohexanone, methyl ethyl ketone, acetone, methanol, ethanol, ethylene glycol monomethyl ether, ethylene glycol monoethyl ether, 2-methoxyethyl acetate, diethylene glycol dimethyl ether, 1-methoxy-2-propanol, 1-methoxy-2-propyl acetate, N,N-dimethyl formamide, N,N-dimethyl acetamide, toluene, ethyl acetate, methyl lactate, ethyl lactate, dimethyl sulfoxide, and water. Only one solvent may be used, or a mixture of two or more solvents may be used.

As the radical polymerization initiator used for synthesizing the polymer used in the invention, known compounds such as an azo initiator or a peroxide initiator can be used.

Among the binders described above, binder polymers having a repeating unit represented by the following Formula (I) shown in Japanese Patent Application No. 2002-287920, such as 2-methacryloyloxyethylsuccinic acid polymer and 2-methacryloyloxyethylhexahydrophthalic acid copolymer, are preferable from the viewpoint of preventing damage caused by a developer.

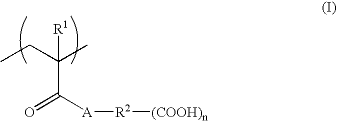

In Formula (I), R¹ represents a hydrogen atom or a methyl group; R² is a linking group composed of two or more atoms selected from the group consisting of carbon atoms, hydrogen atoms, oxygen atoms, nitrogen atoms and sulfur atoms wherein the number of atoms in the linking group is 2 to 82; A represents an oxygen atom or —NR³— wherein R³ represents a hydrogen atom or a C₁₋₁₀ monovalent hydrocarbon group; and n is an integer of 1 to 5.

In the Formula (I) above, the number of atoms in the main skeleton of the linking group represented by R² is preferably 1 to 30. R² preferably has an alkylene structure or a structure including alkylene structures linked via ester linkages.

Hereinafter, the repeating units represented by the Formula (I) will be described in detail.

R¹ in the Formula (I) represents a hydrogen atom or a methyl group, preferably a methyl group.

The linking group represented by R² in the Formula (I) is a linking group composed of two or more atoms selected from the group consisting of carbon atoms, hydrogen atoms, oxygen atoms, nitrogen atoms and sulfur atoms wherein the number of atoms in the linking group is 2 to 82, preferably 2 to 50, more preferably 2 to 30. When the linking group has substituent(s), the number of atoms refers to the number of atoms including the atoms in the substituent(s) on the linking group.

Specifically, the number of atoms in the main skeleton of the linking group represented by R² is preferably 1 to 30, more preferably 3 to 25, still more preferably 4 to 20, most preferably 5 to 10. The “main skeleton of the linking group” in the invention refers to an atom or an atomic group serving to link A to the terminal COOH in the Formula (I). When plural linking routes are present, the main skeleton refers to the atom or atomic group constituting the linking route having the smallest number of atoms. Accordingly, when the linking group has a cyclic structure, the number of atoms to be used for calculation varies depending on the linking site (for example, o-, m-, p- etc.).

The structure of the specific binder polymer according to the invention, and the number of atoms constituting the main skeleton of the linking group represented by R² in the structure and the method of calculating the number of atoms, are both shown below.

Numbers of Atoms Constituting Main Skeleton of Linking Group

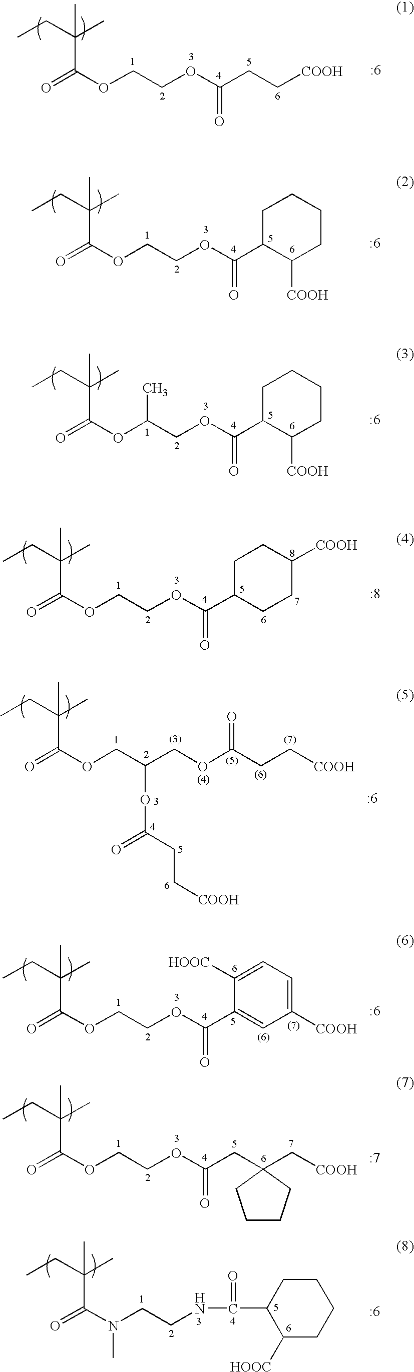

The linking group represented by R² in the Formula (I) is more specifically an alkylene, a substituted alkylene, an arylene, a substituted arylene, or a group in which plural divalent groups, such as those described above, are linked via amide or ester linkages.

A linking group in the chain structure may be ethylene, propylene etc. A structure including such alkylene groups linked via ester linkages is also preferable.

The linking group represented by R² in the Formula (I) is preferably a (n+1)-valent hydrocarbon group having a C₃₋₃₀ alicyclic structure. Examples thereof include (n+1)-valent hydrocarbon groups obtained by removing (n+1) hydrogen atoms on one or more arbitrary carbon atoms constituting a compound having an alicyclic structure such as cyclopropane, cyclopentane, cyclohexane, cycloheptane, cyclooctane, cyclodecane, dicyclohexyl, tertiary cyclohexyl or norbornane which may be substituted by one or more arbitrary substituents. R² preferably has 3 to 30 carbon atoms including the carbon atoms in the substituent(s) if any.

One or more arbitrary carbon atoms in the compound having an alicyclic structure may be substituted by one or more heteroatoms selected from the group consisting of nitrogen atoms, oxygen atoms and sulfur atoms. In respect of printing durability, R² is preferably a (n+1)-valent hydrocarbon group having an alicyclic structure which may have a substituent and which includes two or more rings and has 5 to 30 carbon atoms, such as a condensed polycyclic aliphatic hydrocarbon, a crosslinked alicyclic hydrocarbon, a spiroaliphatic hydrocarbon, and a combination of aliphatic hydrocarbon rings (a structure in which rings are combined by bonds or via linking groups). The number of carbon atoms refers to the number of carbon atoms including the carbon atoms in the substituent(s) if any.

Regarding linking groups represented by R², the number of atoms is further preferably 5 to 10. Linking groups having a chain structure in which includes a ester bond or a cyclic structure are preferable.

A substituent which can be introduced into the linking group represented by R² may be a monovalent non-metal atomic group excluding hydrogen, and examples thereof include a halogen atom (—F, —Br, —Cl, —I), a hydroxyl group, an alkoxy group, an aryloxy group, a mercapto group, an alkyl thio group, an aryl thio group, an alkyl dithio group, an aryl dithio group, an amino group, a N-alkyl amino group, a N,N-dialkyl amino group, a N-aryl amino group, a N,N-diaryl amino group, a N-alkyl-N-aryl amino group, an acyloxy group, a carbamoyloxy group, a N-alkylcarbamoyloxy group, a N-aryl carbamoyloxy group, a N,N-dialkyl carbamoyloxy group, a N,N-diaryl carbamoyloxy group, a N-alkyl-N-aryl carbamoyloxy group, an alkyl sulfoxy group, an aryl sulfoxy group, an acyl thio group, an acyl amino group, a N-alkyl acyl amino group, a N-aryl acyl amino group, a ureido group, a N′-alkyl ureido group, a N′,N′-dialkyl ureido group, a N′-aryl ureido group, a N′,N′-diaryl ureido group, a N′-alkyl-N′-aryl ureido group, a N-alkyl ureido group, a N-aryl ureido group, a N′-alkyl-N-alkyl ureido group, a N′-alkyl-N-aryl ureido group, a N′,N′-dialkyl-N-alkyl ureido group, a N′,N′-dialkyl-N-aryl ureido group, a N′-aryl-N-alkyl ureido group, a N′-aryl-N-aryl ureido group, a N′,N′-diaryl-N-alkyl ureido group, a N′,N′-diaryl-N-aryl ureido group, a N′-alkyl-N′-aryl-N-alkyl ureido group, a N′-alkyl-N′-aryl-N-aryl ureido group, an alkoxy carbonyl amino group, an aryloxy carbonyl amino group, a N-alkyl-N-alkoxycarbonyl amino group, a N-alkyl-N-aryloxy carbonyl amino group, a N-aryl-N-alkoxycarbonyl amino group, a N-aryl-N-aryloxycarbonyl amino group, a formyl group, an acyl group, a carboxyl group and its conjugate base group, an alkoxy carbonyl group, an aryloxy carbonyl group, a carbamoyl group, a N-alkyl carbamoyl group, a N,N-dialkyl carbamoyl group, a N-aryl carbamoyl group, a N,N-diaryl carbamoyl group, a N-alkyl-N-aryl carbamoyl group, an alkyl sulfinyl group, an aryl sulfinyl group, an alkyl sulfonyl group, an aryl sulfonyl group, a sulfo group (—SO₃H) and its conjugate base group, an alkoxy sulfonyl group, an aryloxy sulfonyl group, a sulfinamoyl group, a N-alkyl sulfinamoyl group, a N,N-dialkyl sulfinamoyl group, a N-aryl sulfinamoyl group, a N,N-diaryl sulfinamoyl group, a N-alkyl-N-aryl sulfinamoyl group, a sulfamoyl group, a N-alkyl sulfamoyl group, a N,N-dialkyl sulfamoyl group, a N-aryl sulfamoyl group, a N,N-diaryl sulfamoyl group, a N-alkyl-N-aryl sulfamoyl group, a N-acyl sulfamoyl group and its conjugate base group, a N-alkyl sulfonyl sulfamoyl group (—SO₂NHSO₂ (alkyl)) and its conjugate base group, a N-aryl sulfonyl sulfamoyl group (—SO₂NHSO₂ (allyl)) and its conjugate base group, a N-alkyl sulfonyl carbamoyl group (—CONHSO₂ (alkyl)) and its conjugate base group, a N-aryl sulfonyl carbamoyl group (—CONHSO₂ (aryl)) and its conjugate base group, an alkoxy silyl group (—Si(O-alkyl)₃), an aryloxy silyl group (—Si(O-aryl)₃), a hydroxysilyl group (—Si(OH)₃) and its conjugate base group, a phosphono group (—PO₃H₂) and is conjugate base group, a dialkyl phosphono group (—PO₃ (alkyl)₂), a diaryl phosphono group (—PO₃(aryl)₂), an alkyl aryl phosphono group (—PO₃(alkyl)(aryl)), a monoalkyl phosphono group (—PO₃H(alkyl)) and its conjugate base group, a monoaryl phosphono group (—PO₃H(aryl)) and its conjugate base group, a phosphonoxy group (—OPO₃H₂) and its conjugate base group, a dialkyl phosphonoxy group (—OPO₃(alkyl)₂), a diaryl phosphonoxy group (—OPO₃(aryl)₂), an alkyl aryl phosphonoxy group (—OPO₃(alkyl)(aryl)), a monoalkyl phosphonoxy group (—OPO₃H(alkyl)) and its conjugate base group, a monoaryl phosphonoxy group (—OPO₃H(aryl)) and its conjugate base group, a cyano group, a nitro group, a dialkyl boryl group (—B(alkyl)₂), a diaryl boryl group (—B(aryl)₂), an alkyl aryl boryl group (—B(alkyl)(aryl)), a dihydroxy boryl group (—B(OH)₂) and its conjugate base group, an alkyl hydroxy boryl group (—B(alkyl)(OH)) and its conjugate base group, an aryl hydroxy boryl group (—B(aryl)(OH)) and its conjugate base group, an aryl group, an alkenyl group and an alkynyl group.

According to the design of the recording layer, a substituent having a hydrogen atom capable of hydrogen bonding, particularly a substituent having acidity whose acid dissociation constant (pKa) is lower than that of carboxylic acid, may not be preferable because it tends to lower printing durability. On the other hand, a hydrophobic substituent such as a halogen atom, a hydrocarbon group (alkyl group, aryl group, alkenyl group, or alkynyl group), an alkoxy group and an aryloxy group is preferable because it tends to improve printing durability. In particular, when the cyclic structure is a six-membered or lower-membered monocyclic aliphatic hydrocarbon such as cyclopentane or cyclohexane, the hydrocarbon preferably has such hydrophobic substituents. If possible, these substituents may be bound to one another or to a substituted hydrocarbon group to form a ring. The substituents may themselves be substituted.

In the Formula (I), when A is NR₃—, R₃ represents a hydrogen atom or monovalent hydrocarbon group having 1 to 10 carbon atoms. Examples of the monovalent hydrocarbon group having 1 to 10 carbon atoms represented by R₃ include linear, branched, or cyclic alkyl groups having 1 to 10 carbon atoms such as an alkyl group, an aryl group, an alkenyl group, and an alkynyl group. Specific examples of the alkyl group include a methyl group, an ethyl group, a propyl group, a butyl group, a pentyl group, a hexyl group, a heptyl group, an octyl group, a nonyl group, a decyl group, an isopropyl group, an isobutyl group, a sec-butyl group, a tert-butyl group, an isopentyl group, a neopentyl group, a 1-methylbutyl group, an isohexyl group, a 2-ethylhexyl group, a 2-methylhexyl group, a cyclopentyl group, a cyclohexyl group, a 1-adamantyl group, and a 2-norbornyl group. Specific examples of the aryl group include aryl groups having 1 to 10 carbon atoms such as a phenyl group, a naphthyl group, and an indenyl group, heteroaryl groups having 1 to 10 carbon atoms and containing a heteroatom selected from the group consisting of a nitrogen atom, an oxygen atom, and a sulfur atom, for example, a furyl group, a thienyl group, a pyrrolyl group, a pyridyl group, and a quinolyl group.

Specific examples of the alkenyl group include linear, branched, or cyclic alkenyl groups having 1 to 10 carbon atoms such as a vinyl group, a 1-propenyl group, a 1-butenyl group, a 1-methyl-1-propenyl group, a 1-cyclopentenyl group, and a 1-cyclohexenyl group.

Specific examples of the alkynyl group include alkynyl groups having 1 to 10 carbon atoms such as an ethynyl group, a 1-propynyl group, a 1-butynyl group, and a 1-octynyl group. Examples of the substituent which may be introduced into R₃ are the same as those listed as the substituent which may be introduced into R². However, R³ has 1 to 10 carbon atoms including the carbon atoms in the substituent.

In the Formula (I), A is preferably an oxygen atom or —NH— from the viewpoint of easiness of synthesis.

In the Formula (I), n denotes an integer of 1 to 5, and is preferably 1 from the viewpoint of printing durability.

Specific examples of the repeating unit represented by the Formula (I) composing the binder polymer particularly suitable for the invention are listed below, however are not limited to them.

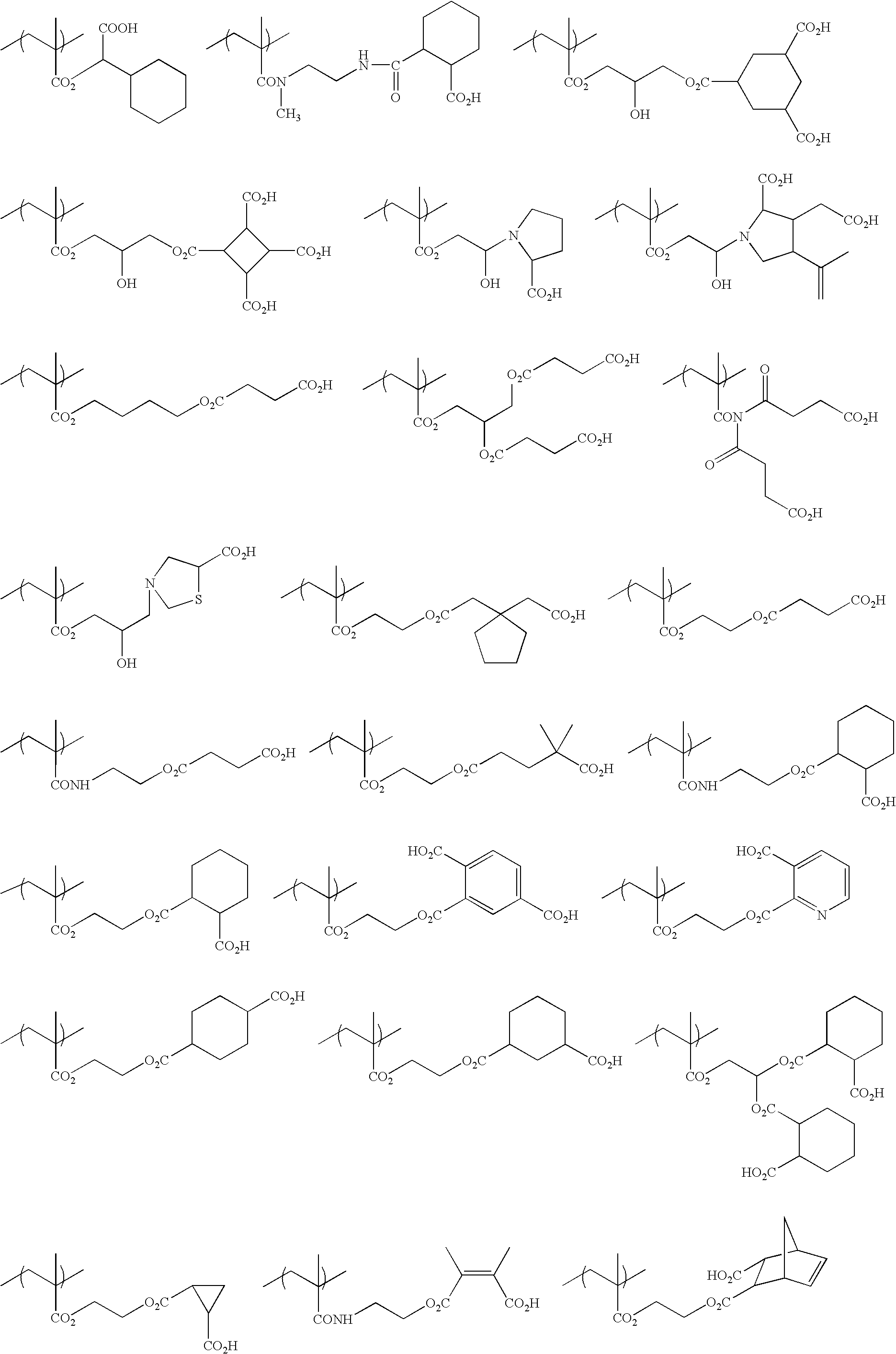

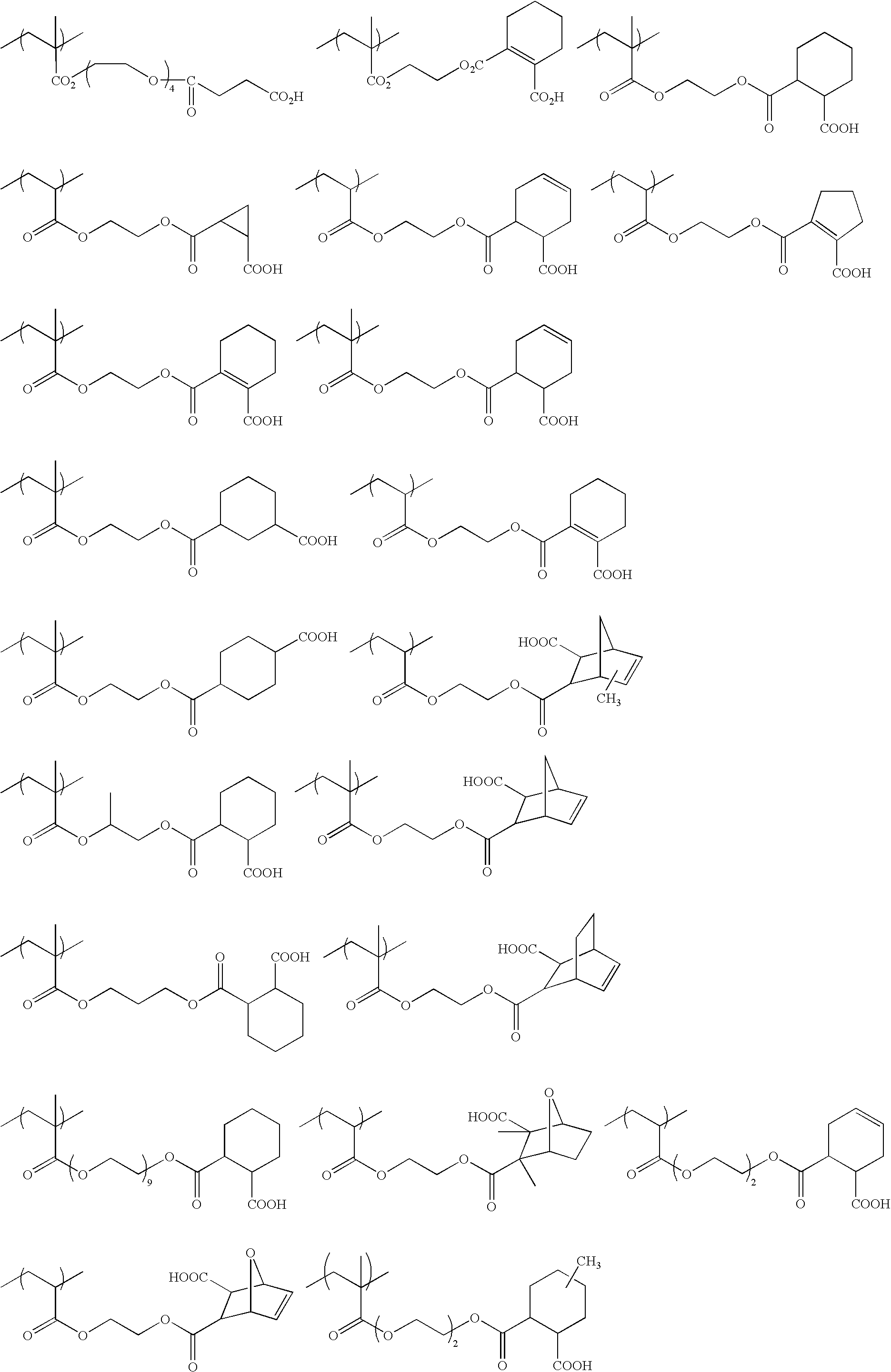

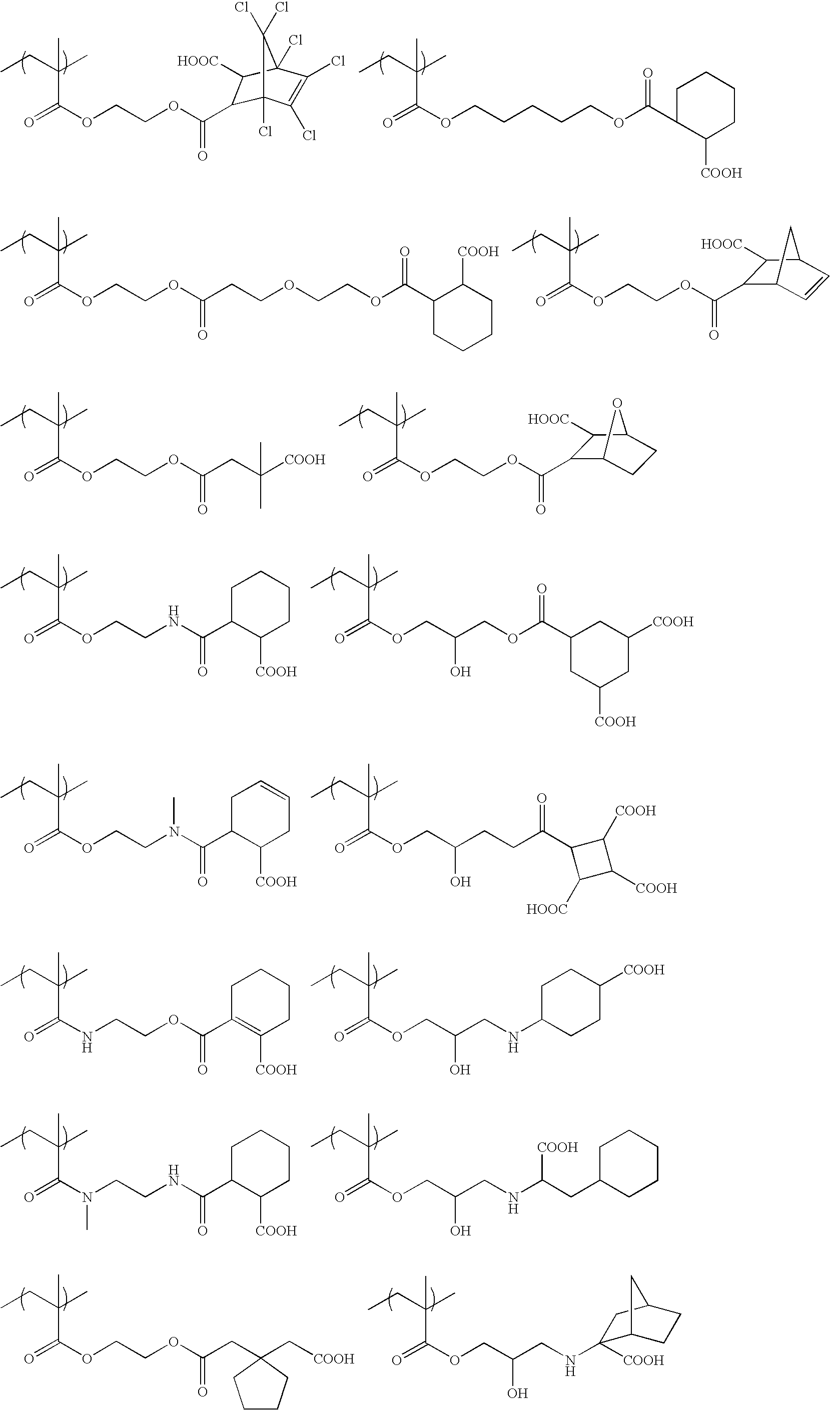

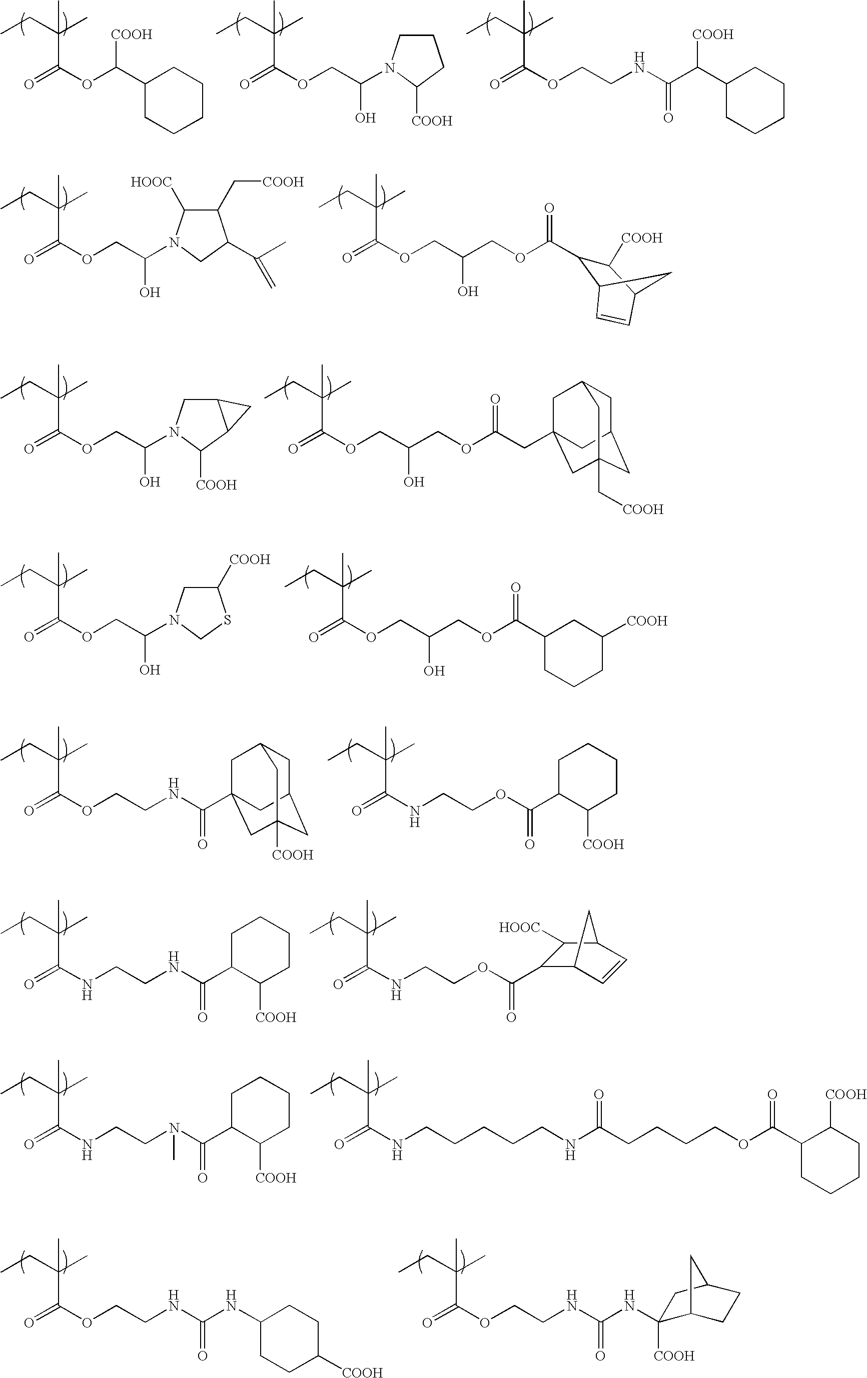

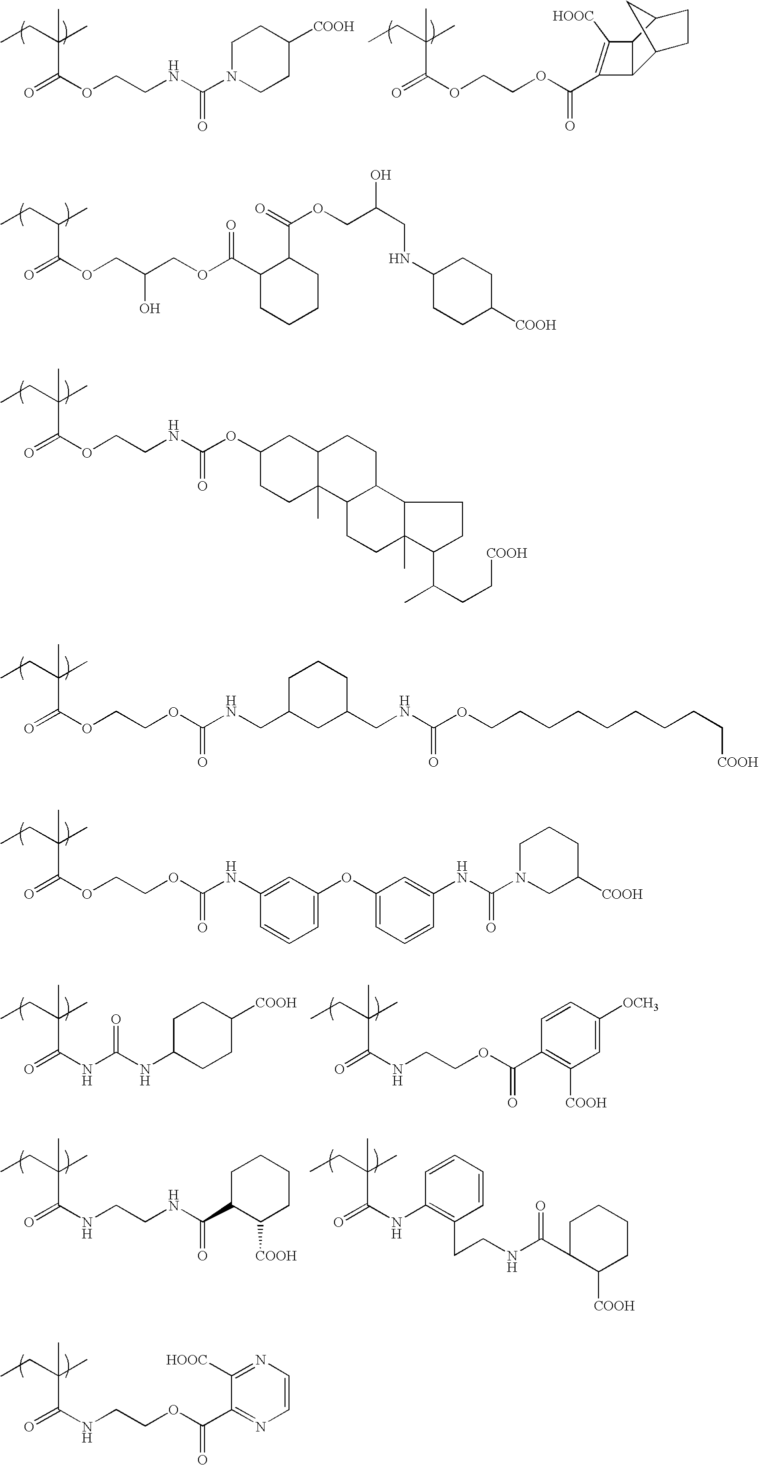

In an embodiment, one kind of repeating unit represented by Formula (I) is included in the binder polymer. In another embodiment, two or more kinds of repeating unit represented by the Formula (I) are contained in the binder polymer. The binder polymer preferred in the invention may be a polymer composed exclusively of the repeating unit represented by the Formula (I), but is generally used as a copolymer containing one or more other copolymerizable components. The total content of the repeating unit represented by the Formula (I) in the copolymer is determined suitably depending on the structure of the copolymer, the design of the polymerizable composition, etc., but is preferably from 1 to 99 mol-%, more preferably from 5 to 40 mol-%, still more preferably from 5 to 20 mol-%, based on the total molar amount of the polymer components.

Copolymer components used as a copolymer may be selected from radical polymerizable monomers known in the art without particular limitation. Specific examples include monomers described in Polymer Data Handbook—Fundamental Version—(in Japanese) compiled by the Society of Polymer Science, Japan and published by Baifukan, 1986. Such additional copolymerizable components may include only one copolymerization component, or a combination of two or more compolymerization components.

Among the above-described binder polymers, [allyl (meth)acrylate/(meth)acrylic acid/optionally together with other addition polymerizable vinyl monomer] copolymers, and polymers containing an acryl group, a methacryl group, and an allyl group as described in JP-A No. 2000-131837, JP-A No. 2002-62648, JP-A No. 2000-187322, and Japanese Patent Application No. 2002-287920 are particularly preferable from the viewpoint of the excellent balance between the film strength, sensitivity, and developability.

In particular, polymers having a repeating unit represented by the Formula (1) and a radical polymerizable group (carbon-carbon double bond) represented by any one of the Formulae (II) to (IV) structure are most preferable.

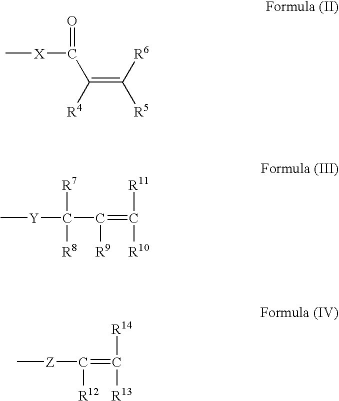

In the Formulae (II) to (IV), R⁴ to R¹⁴ each independently represent a hydrogen atom or a monovalent substituent; X and Y each independently represent an oxygen atom, a sulfur atom or N—R¹⁵; Z represents an oxygen atom, a sulfur atom, —N—R¹⁵ or a phenylene group wherein R¹⁵ represents a hydrogen atom or a monovalent organic group.

In the Formula (II) above, R⁴ to R⁶ each independently represent a hydrogen atom or a monovalent substituent. R⁴ may be a hydrogen atom or an optionally substituted organic group such as an alkyl group. In particular, specifically, a hydrogen atom, a methyl group, a methylalkoxy group or a methyl ester group is preferable. R⁵ and R⁶ each independently represent a hydrogen atom, a halogen atom, an amino group, a dialkylamino group, a carboxyl group, an alkoxycarbonyl group, a sulfo group, a nitro group, a cyano group, an optionally substituted alkyl group, an optionally substituted aryl group, an optionally substituted alkoxy group, an optionally substituted aryloxy group, an optionally substituted alkylamino group, an optionally substituted arylamino group, an optionally substituted alkylsulfonyl group and an optionally substituted arylsulfonyl group, among which a hydrogen atom, a carboxyl group, an alkoxycarbonyl group, an optionally substituted alkyl group and an optionally substituted aryl group are preferable.

Substituents which can be introduced into these groups include a methoxycarbonyl group, an ethoxycarbonyl group, an isopropioxycarbonyl group, a methyl group, an ethyl group, and a phenyl group.

X represents an oxygen atom, a sulfur atom or —N—R¹⁵ wherein R¹⁵ includes an optionally substituted alkyl group etc.

In the Formula (III), R⁷ to R¹¹ each independently represents a hydrogen atom or monovalent substituent. Specific examples of R⁷ to R¹¹ include a hydrogen atom, a halogen atom, an amino group, a dialkylamino group, a carboxyl group, an alkoxycarbonyl group, a sulfo group, a nitro group, a cyano group, an optionally substituted alkyl group, an optionally substituted aryl group, an optionally substituted alkoxy group, an optionally substituted aryloxy group, an optionally substituted alkylamino group, an optionally substituted arylamino group, an optionally substituted alkylsulfonyl group, and an optionally substituted arylsulfonyl group. Among them, a hydrogen atom, a carboxyl group, an alkoxycarbonyl group, an optionally substituted alkyl group, and an optionally substituted aryl group are preferable.

Examples of the substituent which may be introduced into these groups include those listed as the substituent which may be introduced into the Formula (II).

Y represents an oxygen atom, a sulfur atom, or —N—R¹⁵. Examples of R¹⁵ include the same groups those listed for the Formula (II).

In the Formula (IV), R¹² to R¹⁴ each independently represent a hydrogen atom or monovalent substituent. Specific examples thereof include a hydrogen atom, a halogen atom, an amino group, a dialkylamino group, a carboxyl group, an alkoxycarbonyl group, a sulfo group, a nitro group, a cyano group, an optionally substituted alkyl group, an optionally substituted aryl group, an optionally substituted alkoxy group, an optionally substituted aryloxy group, an optionally substituted alkylamino group, an optionally substituted arylamino group, an optionally substituted alkylsulfonyl group, and an optionally substituted arylsulfonyl group. Among them, a hydrogen atom, a carboxyl group, an alkoxycarbonyl group, an optionally substituted alkyl group, and an optionally substituted aryl group are preferable.

Examples of the substituent which may be introduced into these groups include those listed as the substituent which may be introduced into the Formula (II).

Z represents an oxygen atom, a sulfur atom, —NR¹⁵ or a phenylene group. Examples of —NR¹⁵ include those listed for the Formula (II).

Among these radical polymerizable groups, radical-polymerizable groups having a structure represented by the Formula (II) or (III) are preferable.

In an embodiment, only one of such binder polymers is used. In another embodiment, a mixture of two or more of such binder polymers is used.

The molecular weight of the binder polymer (A) in the invention can be suitably determined from the viewpoint of image-forming property and printing durability. Usually the molecular weight is preferably in a range of 2,000 to 1,000,000, more preferably 5,000 to 500,000, still more preferably 10,000 to 200,000.

The binder polymer (A) preferably used in the invention is a polymer substantially insoluble in water but soluble in an aqueous alkali solution. It follows that as the developer, an environmentally undesirable organic solvent is not used, or the amount of such an organic solvent can be limited to a very small amount. The acid value (i.e. acid content per g of the polymer, expressed in terms of chemical equivalence) and molecular weight of the binder polymer (A) are suitably selected from the viewpoint of image strength and developability. The acid value is preferably in a range of 0.4 to 3.0 meq/g, and the molecular weight is preferably 2,000 to 500,000, and more preferably, the acid value is in a range of 0.6 to 2.0, and the molecular weight is in a range of 10,000 to 300,000.

[Binder Polymer (A)]

The binder polymer used in the invention may be freely selected from known ones, and is preferably a polymer having film-forming property. Examples of the binder polymer include an acrylic resin, a polyvinyl acetal resin, a polyurethane resin, a polyurea resin, a polyimide resin, a polyamide resin, an epoxy resin, a methacrylic resin, a polystyrene-based resin, a novolac type phenolic resin, a polyester resin, a synthetic rubber, and a natural rubber.

The binder polymer may has crosslinking property for improving the coating strength on the image region. To impart crosslinking property to the binder polymer, a crosslinking functional group such as an ethylenically unsaturated bond may be introduced into the main chain or side chain of the polymer. The crosslinking functional group may be introduced by copolymerization.

Examples of the polymer having within the main chain of the molecule thereof include poly-1,4-butadiene and poly-1,4-isoprene having an ethylenically unsaturated bond.

Examples of the polymer having within the main chain of the molecule thereof an ethylenically unsaturated bond include (meth)acrylic acid ester or amide polymers having an ethylenically unsaturated bond within the ester or amide residue (R in —COOR or —CONHR).

Examples of the residue (the above-described R) having an ethylenically unsaturated bond include —(CH₂)ₙCR¹═CR²R³, —(CH₂O)ₙCH₂CR¹═CR²R³, —(CH₂CH₂O)ₙCH₂CR¹═CR²R³, —(CH₂)ₙNH—CO—O—CH₂CR¹═CR²R³, —(CH₂)ₙ—O—CO—CR¹═CR²R³, and —(CH₂CH₂O)₂—X (wherein R¹ to R³ each represents a hydrogen atom, a halogen atom, or an alkyl, aryl, alkoxy, or aryloxy group having 1 to 20 carbon atoms; R¹ may be combined with R² or R³ to form a ring; n denotes an integer of 1 to 10; and X represents a dicyclopentadienyl residue).

Specific examples of the ester residue include —CH₂CH═CH₂ (described in JP-B No. 7-21633), —CH₂CH₂O—CH₂CH═CH₂, —CH₂C(CH₃)═CH₂, —CH₂CH═CH—C₆H₅, —CH₂CH₂OCOCH═CH—C₆H₅, —CH₂CH₂—NHCOO—CH₂CH═CH₂, and —CH₂CH₂O—X (wherein X represents a dicyclopentadienyl residue). Specific examples of the amide residue include —CH₂CH═CH₂, —CH₂CH₂—Y (wherein Y represents a hexene residue), and —CH₂CH₂—OCO—CH═CH₂.

The crosslinking binder polymer is cured, for example, as follows: a free radical (a polymerization initiating radical or a growing radical of a polymerizable compound during polymerization) is added to the crosslinking functional group of the polymer, and the polymers are polymerized in a direct manner or through a polymerization chain of the polymerizable compound to form a crosslink between the polymer molecules. Alternately, an atom in the polymer (for example, a hydrogen atom on carbon atom adjacent to the functional crosslinking group) is extracted by a free radial to form a polymer radical, and the polymer radical combines with another polymer radical to form a crosslink between the polymer molecules.

The content of the crosslinking group in the binder polymer (content of the radical-polymerizable unsaturated double bond as determined by iodine titration) is preferably from 0.1 to 10.0 mmol, more preferably from 1.0 to 7.0 mmol, and most preferably from 2.0 to 5.5 mmol with respect to 1 g of the binder polymer. When the content is within the range, favorable sensitivity and favorable storage stability are achieved.

The binder polymer (A) preferably has high solubility or dispersibility in ink and/or dampening water from the viewpoint of improving in-machine developability of the photopolymerization layer in the light-unexposed portion.

The binder polymer (A) is preferably lipophilic for improving the solubility or dispersibility in ink, while preferably hydrophilic for improving the solubility or dispersibility in dampening water. Accordingly, it is also effective in the invention to combine a lipophilic binder polymer with a hydrophilic binder polymer.

Preferable examples of the hydrophilic binder polymer include those having a hydrophilic group such as a hydroxy group, a carboxyl group, a carboxylate group, a hydroxyethyl group, a polyoxyethyl group, a hydroxypropyl group, a polyoxypropyl group, an amino group, an aminoethyl group, an aminopropyl group, an ammonium group, an amide group, a carboxymethyl group, a sulfonate group, and a phosphate group.

Specific examples thereof include gum arabic, casein, gelatin, starch derivative, carboxymethyl cellulose and sodium salts thereof, cellulose acetate, sodium alginate, vinyl acetate-maleic acid copolymers, styrene-maleic acid copolymers, polyacrylic acids and salts thereof, polymethacrylic acids and salts thereof, homopolymers and copolymers of hydroxyethyl methacrylate, homopolymers and copolymers of hydroxyethyl acrylate, homopolymers and copolymers of hydroxypropyl methacrylate, homopolymers and copolymers of hydroxypropyl acrylate, homopolymers and copolymers of hydroxybutyl methacrylate, homopolymers and copolymers of hydroxybutyl acrylate, polyethylene glycols, hydroxypropylene polymers, polyvinyl alcohols, hydrolyzed polyvinyl acetate having a degree of hydrolysis of 60 mol % or more, preferably 80 mol % or more, polyvinyl formal, polyvinyl butyral, polyvinyl pyrrolidone, homopolymers and copolymers of acrylamide, homopolymers and copolymers of methacrylamide, homopolymers and copolymers of N-methylolacrylamide, polyvinyl pyrrolidone, alcohol-soluble nylon, and polyethers of 2,2-bis-(4-hydroxyphenyl)-propane and epichlorohydrin.

In the invention, a binder polymer having within the molecule thereof an ether group represented by —[CH₂—(CHR)ₘ—O]ₙ— may be used, wherein R represents a hydrogen atom or a methyl group, m is 1, 3, or 5, and n denotes an integer of 1 to 20. n is preferably an integer of 1 to 7, more preferably an integer of 1 to 4, and most preferably an integer of 1 to 2.

Specific examples thereof include a homopolymer or copolymer of an acrylate or methacrylate having within the side chain thereof the above-described ether group. Examples of the copolymerized monomer include a monomer having the above-described crosslinking group and other monomers listed in the description of the specific copolymer.

The hydrophilicity of the ether group is effective for achieving the favorable in-machine developability.

In the invention, the weight-average molecular weight of the binder polymer is preferably 5000 or more, and more preferably 10000 to 300000. The number-average molecular weight of the binder polymer is preferably 1000 or more, and more preferably 2000 to 250000. The polydispersity index (weight-average molecular weight/number-average molecular weight) of the binder polymer is preferably from 1.1 to 10.

The content of the binder polymer (A) is preferably from 5 to 90% by mass, more preferably from 5 to 80% by mass, and further preferably from 10 to 70% by mass with respect to the total solid content in the photopolymerization layer. When the content is within the range, favorable strength and image forming ability in the image region are achieved.

The mass ratio between the polymerizable compound (B) and the binder polymer (A) is preferably from 0.5/1 to 4/1.

[Compound Having a Polymerizable Unsaturated Group (B)]

A compound having an unsaturated group (hereinafter referred to sometimes as polymerizable compound) is contained in the polymerizable composition according to the invention or in the recording layer of the planographic printing plate precursor according to the invention.

The polymerizable compound used in the invention is preferably an addition-polymerizable compound having at least one ethylenically unsaturated double bond and is selected preferably from compounds each having at least one, preferably two or more, terminal ethylenically unsaturated bonds. A group of such compounds is well-known in this industrial field, and in the invention, these compounds can be used without any particular limitation. The scope of these compounds include those in chemical forms such as monomers, prepolymers (i.e., dimers, trimers and oligomers), as well as mixtures and copolymers thereof.

Examples of such monomers and copolymers include unsaturated carboxylic acids (e.g., acrylic acid, methacrylic acid, itaconic acid, crotonic acid, isocrotonic acid, maleic acid etc.) and esters and amides thereof, and preferably used among these compounds are esters between unsaturated carboxylic acids and aliphatic polyvalent alcohols and amides between unsaturated carboxylic acids and aliphatic polyvalent amines. Also preferably used among these compounds are unsaturated carboxylic esters having a nucleophilic substituent such as a hydroxyl group, an amino group or a mercapto group, addition-reaction products of amides with monofunctional or multifunctional isocyanates or epoxy compounds, and dehydration condensation reaction products of amides with monofunctional or multifunctional carboxylic acids.

Also preferably used among these compounds are unsaturated carboxylic esters having an electrophilic substituent such as an isocyanate group or an epoxy group, addition-reaction products of amides with monofunctional or multifunctional alcohols, amines or thiols, unsaturated carboxylic esters having an eliminating substituent such as a halogen group and a tosyloxy group, and substitution-reaction products of amides with monofunctional or multifunctional alcohols, amines or thiols. Compounds obtained by replacing the above-described carboxylic acids with unsaturated phosphonic acids, styrene, vinyl ethers etc.

Examples of the ester monomers between aliphatic polyvalent alcohols and unsaturated carboxylic acids include:

acrylic esters such as ethylene glycol diacrylate, triethylene glycol diacrylate, 1,3-butane diol diacrylate, tetramethylene glycol diacrylate, propylene glycol diacrylate, neopentyl glycol diacrylate, trimethylol propane triacrylate, trimethylol propane tri(acryloyloxypropyl)ether, trimethylol ethane triacrylate, hexane diol diacrylate, 1,4-cyclohexane diol diacrylate, tetraethylene glycol diacrylate, pentaerythritol diacrylate, pentaerythritol triacrylate, pentaerythritol tetracrylate, dipentaerythritol diacrylate, dipentaerythritol hexacrylate, sorbitol triacrylate, sorbitol tetracrylate, sorbitol pentacrylate, sorbitol hexacrylate, tri(acryloyloxyethyl)isocyanurate, and polyester acrylate oligomers;

methacrylic esters such as tetramethylene glycol dimethacrylate, triethylene glycol dimethacrylate, neopentyl glycol dimethacrylate, trimethylol propane trimethacrylate, trimethylol ethane trimethacrylate, ethylene glycol dimethacrylate, 1,3-butane diol dimethacrylate, hexane diol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethyl methane, and bis[p-(methacryloxyethoxy)phenyl]dimethyl methane;

itaconic esters such as ethylene glycol diitaconate, propylene glycol diitaconate, 1,3-butane diol diitaconate, 1,4-butane diol diitaconate, tetramethylene glycol diitaconate, pentaerythritol diitaconate, and sorbitol tetraitaconate;

crotonic esters such as ethylene glycol dicrotonate, tetramethylene glycol dicrotonate, pentaerythritol dicrotonate, sorbitol tetradicrotonate;

isocrotonic esters such as ethylene glycol diisocrotonate, pentaerythritol diisocrotonate, and sorbitol tetraisocrotonate; and

maleic esters such as ethylene glycol dimaleate, triethylene glycol dimaleate, pentaerythritol dimaleate, and sorbitol tetramaleate.

Other examples of preferable esters include aliphatic alcohol-based esters described in JP-B No. 46-27926, JP-B No. 51-47334 and JP-A No. 57-196231, those having an aromatic skeleton described in JP-A No. 59-5240, JP-A No. 59-5241 and JP-A No. 2-226149, and those having an amino group described in JP-A No. 1-165613.

In an embodiment, a mixture of such ester monomers is used.

Examples of monomers of the amides between aliphatic polyvalent amine compounds and unsaturated carboxylic acids include methylene bis-acrylamide, methylene bis-methacrylamide, 1,6-hexamethylene bis-acrylamide, 1,6-hexamethylene bis-methacrylamide, diethylene triamine trisacrylamide, xylylene bisacrylamide, and xylylene bismethacrylamide.

Preferable examples of other amide-containing monomers include those having a cyclohexylene structure described in JP-B No. 54-21726.

Urethane-containing addition-polymerizable compounds produced by addition reaction between isocyanates and hydroxyl groups are also preferable, and examples thereof include a vinyl urethane compound containing two or more polymerizable vinyl groups in one molecule which is prepared by adding a vinyl monomer containing a hydroxyl group shown in the Formula below to a polyisocyanate compound having two or more isocyanate groups in one molecule as described in JP-B No. 48-41708.

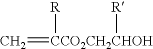

In the above Formula, R and R′ each independently represent H or CH₃.

Urethane acrylates described in JP-A No. 51-37193, JP-B No. 2-32293 and JP-B No. 2-16765 and urethane compounds having an ethylene oxide-based skeleton described in JP-B No. 58-49860, JP-B No. 56-17654, JP-B No. 62-39417 and JP-B No. 62-39418 are also preferable.

Addition-polymerizable compounds having an amino structure or sulfide structure in the molecule as described in JP-A No. 63-277653, JP-A No. 63-260909 and JP-A No. 1-05238 can be used to prepare heat-sensitive compositions excellent in curing speed.

As other examples, multifunctional acrylates and methacrylates such as polyester acrylates and epoxy acrylates obtained by reacting epoxy resin with (meth)acrylic acid, as described in JP-A No. 48-64183, JP-B No. 49-43191 and JP-B 52-30490, can be mentioned. Specific unsaturated compounds described in JP-B No. 46-43946, JP-B No. 1-40337 and JP-B No. 1-40336 and vinyl phosphonic acid-based compounds described in JP-A No. 2-25493 can also be mentioned. In some cases, a structure containing a perfluoroalkyl group described in JP-A No. 61-22048 is preferably used. Photosetting monomers and oligomers described in the Journal of Japanese Adhesive Society, vol. 20, No. 7, pp. 300-308 (1984) can also be used.

Details of the use of the polymerizable compounds—what structure is used, whether they are used singly or in combination, and the addition amount—can be arbitrarily determined in accordance with the performance and design of the final photosensitive material. For example, they are selected from the following viewpoints. In respect of photoresponse speed, their structure preferably has a high unsaturated group content per one molecule, and in many cases, they are preferably bifunctional or higher-functional. To increase the strength of an image portion i.e. the cured layer, they are preferably trifunctional or higher-functional. It is also effective to use a method of regulating both photosensitivity and strength by combined use of compounds (e.g. acrylic esters, methacrylic esters, styrene-containing compounds, and vinyl ether-containing compounds) having different functionalities and different polymerizable groups. Compounds having a higher molecular weight or compounds with higher hydrophobicity, though being excellent in photoresponse speed and layer strength, may be undesirable in some cases in respect of developing speed and precipitation in the developer.

A higher content of the polymerizable compound (B) is advantageous in respect of sensitivity. However, when the content is excessively high, there may be problems in undesirable phase separation, troubles in production process caused by the adhesiveness of the composition (e.g., defects in production process caused by transfer and adhesion of components in the photosensitive component), and separation from the developer when used in a planographic printing plate precursor. From these viewpoints, the content of the polymerizable compound (B) in the polymerizable composition according to the invention or in the recording layer of the planographic printing plate precursor is preferably in a range of 20 to 70% by weight, more preferably 25 to 50% by weight, based on the total solid content.

In an embodiment, only one polymerizable compound (B) is used. In another embodiment, two or more polymerizable compounds (B) are used.

The method of selecting and using the polymerizable compound is an important factor for compatibility and dispersibility with other components (e.g. a binder polymer, an initiator, a colorant etc.) in the recording layer used in the planographic printing plate precursor, and the compatibility may be improved by using e.g. a low-purity compound or a combination of two or more compounds.

[Dye Having the Absorption Maximum at the Wavelength from 300 to 1200 nm (D)]

The image recording layer in the invention may contain a dye having the absorption maximum at the wavelength from 300 to 1200 nm. The dye functions as a sensitizing dye, and preferably has the absorption maximum at the wavelength from 750 to 900 nm from the viewpoint of improving the performance such as image quality. Examples of the sensitizing dye include spectral sensitizing dyes, or dyes or pigments as listed below which absorb light from a light source to interact with a photopolymerization initiator.

Preferable examples of the spectral sensitizing dyes include polynuclear aromatics (e.g. pyrene, perylene, and triphenylene), xanthenes (e.g. fluorescein, eosin, erythrosine, rhodamine B, and rose bengal), cyanines (e.g. thiacarbocyanine, and oxacarbocyanine), melocyanines (e.g. melocyanine and carbomelocyanine), thiazines (e.g. thioene, methylene blue, and toluidine blue), acridines (e.g. acridine orange, chloroflavine, and acriflavine), phthalocyanines (e.g. phthalocyanine and metallophthalocyanine), porphyrins (e.g. tetraphenyl porphyrin, center metal substituted porphyrin), chlorophylls (e.g. chlorophyll, chlorophyllin, and center metal substituted chlorophyll), metal complexes, anthraquinones (e.g. anthraquinone), and squaryliums (e.g. squarylium).

More preferable examples of the spectral sensitizing dyes include styryl-based dyes described in JP-B No. 37-13034, cation dyes described in JP-A No. 62-143044, quinoxalinium salts described in JP-B No. 59-24147, novel methylene blue compounds described in JP-A No. 64-33104, anthraquinones described in JP-A No. 64-56767, benzoxanthene dyes described in JP-A No. 2-1714, acridines described in JP-A No. 2-226148 and JP-A No. 2-226149, pyrylium salts described in JP-B No. 40-28499, cyanines described in JP-B No. 46-42363, benzofuran dyes described in JP-A No. 2-63053, conjugate ketone dyes described in JP-A No. 2-85858 and JP-A No. 2-216154, dyes described in JP-A No. 57-10605, azocinnamylidene derivatives described in JP-B No. 2-30321, cyanine-based dyes described in JP-A No. 1-287105, xanthene-based dyes described in JP-A No. 62-31844, JP-A No. 62-31848, and JP-A No. 62-143043, aminostyryl ketones described in JP-B No. 59-28325, melocyanine dyes described in JP-B No. 61-9621, dyes described in JP-A No. 2-179643, melocyanine dyes described in JP-A No. 2-244050, melocyanine dyes described in JP-B No. 59-28326, melocyanine dyes described in JP-A No. 59-89803, melocyanine dyes described in JP-A No. 8-129257, and benzopyran-based dyes described in JP-A No. 8-334897.

The sensitizing dye used in the invention is more preferably represented by the following Formula (12).

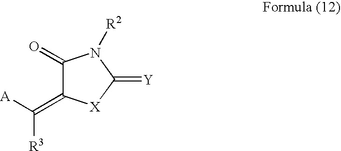

In the Formula (12), A represents an optionally substituted aromatic ring or heterocycle, X represents an oxygen atom, a sulfur atom, or —N(R¹)—, and Y represents an oxygen atom or —N(R¹)—. R¹, R², and R³ each independently represents a hydrogen atom or a monovalent group of nonmetal atoms. A, R¹, R², and R³ may be combined with each other to form an aliphatic or aromatic ring.

When R¹, R², and R³ each represents a monovalent group of nonmetal atoms, and preferably represents a substituted or unsubstituted alkyl group or aryl group.

Specific preferable examples of R¹, R², and R³ are described below. Preferable examples of the alkyl group include linear, branched, and cyclic alkyl groups having 1 to 20 carbon atoms, and specific examples thereof include a methyl group, an ethyl group, a propyl group, a butyl group, a pentyl group, a hexyl group, a heptyl group, an octyl group, a nonyl group, a decyl group, an undecyl group, a dodecyl group, a tridecyl group, a hexadecyl group, an octadecy group, an eicosyl group, an isopropyl group, an isobutyl group, a s-butyl group, a t-butyl group, an isopentyl group, a neopentyl group, a 1-methylbutyl group, an isohexyl group, a 2-ethylhexyl group, a 2-methylhexyl group, a cyclohexyl group, a cyclopentyl group, and a 2-norbornyl group. Among them, linear alkyl groups having 1 to 12 carbon atoms, branched alkyl groups having 3 to 12 carbon atoms, and cyclic alkyl groups having 5 to 10 carbon atoms are more preferable.

As the substituent of the substituted alkyl group, a monovalent group of nonmetal atoms excluding hydrogen atoms is used, preferable examples thereof include a halogen atom (—F, —Br, —Cl, or —I), a hydroxyl group, an alkoxy group, an aryloxy group, a mercapto group, an alkylthio group, an arylthio group, an alkyldithio group, an aryldithio group, an amino group, a N-alkylamino group, a N,N-dialkylamino group, a N-arylamino group, a N,N-diarylamino group, a N-alkyl-N-arylamino group, an acyloxy group, a carbamoyloxy group, a N-alkylcarbamoyloxy group, a N-arylcarbamoyloxy group, a N,N-dialkylcarbamoyloxy group, a N,N-diarylcarbamoyloxy group, a N-alkyl-N-arylcarbamoyloxy group, an alkylsulfoxy group, an arylsulfoxy group, an acyloxy group, an acylthio group, an acylamino group, a N-alkylacylamino group, a N-arylacylamino group, an ureido group, a N′-alkylureido group, a N′,N′-dialkylureido group, a N′-arylureido group, a N′,N′-diarylureido group, a N′-alkyl-N′-arylureido group, a N-alkylureido group, a N-arylureido group, a N′-alkyl-N-alkylureido group, a N′-alkyl-N-arylureido group, a N′,N′-dialkyl-N-alkylureido group, a N′,N′-dialkyl-N-arylureido group, a N′-aryl-N-alkylureido group, a N′-aryl-N-arylureido group, a N′,N′-diaryl-N-alkylureido group, a N′,N′-diaryl-N-arylureido group, a N′-alkyl-N′-aryl-N-alkylureido group, a N′-alkyl-N′-aryl-N-arylureido group, an alkoxycarbonylamino group, an aryloxycarbonylamino group, a N-alkyl-N-alkoxycarbonyl amino group, a N-alkyl-N-aryloxycarbonylamino group, a N-aryl-N-alkoxycarbonylamino group, a N-aryl-N-aryloxycarbonylamino group, a formyl group, an acyl group, a carboxyl group, an alkoxycarbonyl group, an aryloxycarbonyl group, a carbamoyl group, a N-alkylcarbamoyl group, a N,N-dialkylcarbamoyl group, a N-arylcarbamoyl group, a N,N-diarylcarbamoyl group, a N-alkyl-N-arylcarbamoyl group,

an alkylsulfinyl group, an arylsulfinyl group, an alkylsulfonyl group, an arylsulfonyl group, a sulfo group (—SO₃H) and conjugate base groups thereof (hereinafter, referred to as a sulfonate group), an alkoxysulfonyl group, an aryloxysulfonyl group, a sulfinamoyl group, a N-alkylsulfinamoyl group, a N,N-dialkylsulfinamoyl group, a N-arylsulfinamoyl group, a N,N-diarylsulfinamoyl group, a N-alkyl-N-arylsulfinamoyl group, a sulfamoyl group, a N-alkylsulfamoyl group, a N,N-dialkylsulfamoyl group, a N-arylsulfamoyl group, a N,N-diarylsulfamoyl group, a N-alkyl-N-arylsulfamoyl group, a phosphono group (—PO₃H₂) and conjugate base groups thereof (hereinafter, referred to as a phosphonate group), a dialkylphosphono group (—PO₃(alkyl)₂), diarylphosphono group (—PO₃(aryl)₂), an alkylarylphosphono group (—PO₃(alkyl)(aryl)), a monoalkylphosphono group (—PO₃H(alkyl)) and conjugate base groups thereof (hereinafter, referred to as an alkylphosphonate group), a monoarylphosphono group (—PO₃H(aryl)) and conjugate base groups thereof (hereinafter, referred to as an arylphosphonate group), phosphonooxy group (—OPO₃H₂) and conjugate base groups thereof (hereinafter, referred to as a phosphonateoxy group), a dialkyl phosphonooxy group (—OPO₃(alkyl)₂), diarylphosphonooxy group (—OPO₃(aryl)₂), alkylarylphosphonooxy group (—OPO₃(alkyl)(aryl)), monoalkylphosphonooxy group (—OPO₃H(alkyl)) and conjugate base groups thereof (hereinafter, referred to as an alkylphosphonateoxy group), monoarylphosphonooxy group (—OPO₃H(aryl)) and conjugate base groups thereof (hereinafter, referred to as an arylphosphonateoxy group), a cyano group, a nitro group, an aryl group, a heteroaryl group, an alkenyl group, an alkynyl group, and a silyl group.

Specific examples of the alkyl group in these substituents include the above-described alkyl groups, which may be further substituted.

Specific examples of the aryl group include a phenyl group, a biphenyl group, a naphthyl group, a tolyl group, a xylyl group, a mesityl group, a cumenyl group, a chlorophenyl group, a bromophenyl group, a chloromethylphenyl group, a hydroxyphenyl group, a methoxyphenyl group, an ethoxyphenyl group, a phenoxyphenyl group, an acetoxyphenyl group, a benzoyloxyphenyl group, a methylthiophenyl group, a phenylthiophenyl group, a methylaminophenyl group, a dimethylaminophenyl group, an acetylaminophenyl group, a carboxyphenyl group, a methoxycarbonylphenyl group, an ethoxyphenylcarbonyl group, a phenoxycarbonylphenyl group, a N-phenylcarbamoylphenyl group, a phenyl group, a cyanophenyl group, a sulfophenyl group, a sulfonatephenyl group, a phosphonophenyl group, and a phosphonatephenyl group.

The heteroaryl group is a group derived from a monocyclic or polycyclic aromatic ring containing at least one of a nitrogen atom, an oxygen atom, and a sulfur atom. Particularly preferable examples of the heteroaryl ring in the heteroaryl group include thiophene, thiathrene, furan, pyran, isobenzofuran, chromene, xanthene, phenoxazine, pyrrole, pyrazole, isothiazole, isoxazole, pyrazine, pyrimidine, pyridazine, indolysine, isoindolysine, indoyl, indazole, prine, quinolizine, isoquinoline, phthalazine, naphthyridine, quinazoline, cinnoline, pteridine, carbazole, carboline, phenanthroline, acridine, perimidine, phenanthroline, phthalazine, phenarsazine, phenoxazine, and furazan, which may be further benzo-condensed ring, or may be substituted.

Examples of the alkenyl group include a vinyl group, a 1-propenyl group, a 1-butenyl group, a cinnamyl group, and a 2-chloro-1-ethenyl group, and examples of the alkynyl group include an ethynyl group, a 1-propynyl group, a 1-butynyl group, and a trimethylsilylethynyl group. Examples of G¹ in the acyl group (G¹CO—) include a hydrogen atom, and the above-described alkyl group and aryl group. Among these substituents, more preferable examples include a halogen atom (—F, —Br, —Cl, and —I), an alkoxy group, an aryloxy group, an alkylthio group, an arylthio group, a N-alkylamino group, a N,N-dialkylamino group, an acyloxy group, a N-alkylcarbamoyloxy group, a N-arylcarbamoyloxy group, an acylamino group, a formyl group, an acyl group, a carboxyl group, an alkoxycarbonyl group, an aryloxycarbonyl group, a carbamoyl group, a N-alkylcarbamoyl group, a N,N-dialkylcarbamoyl group, a N-arylcarbamoyl group, a N-alkyl-N-arylcarbamoyl group, a sulfo group, a sulfonate group, a sulfamoyl group, a N-alkylsulfamoyl group, a N,N-dialkylsulfamoyl group, a N-arylsulfamoyl group, a N-alkyl-N-arylsulfamoyl group, a phosphono group, a phosphonate group, a dialkylphosphono group, a diarylphosphono group, a monoalkylphosphono group, an alkylphosphonate group, a monoarylphosphono group, an arylphosphonate group, a phosphonooxy group, a phosphonateoxy group, an aryl group, an alkenyl group, and an alkylidene group (e.g. methylene group).

Examples of the alkylene group in the substituted alkyl group include a divalent organic residue obtained by removing any one of the hydrogen atoms on the above-described alkyl group having 1 to 20 carbon atoms, and preferable examples thereof include a linear alkylene group having 1 to 12 carbon atoms, a branched alkylene group having 3 to 12 carbon atoms, and a cyclic alkylene group having 5 to 10 carbon atoms.

Specific examples of the substituted alkyl group which is obtained by combining the above-described substituent with an alkylene group and is preferable as R¹, R², or R³ include a chloromethyl group, a bromomethyl group, a 2-chloroethyl group, a trifluoromethyl group, a methoxymethyl group, a methoxyethoxyethyl group, an allyloxymethyl group, a phenoxymethyl group, a methylthiomethyl group, a tolylthiomethyl group, an ethylaminoethyl group, a diethylaminopropyl group, a morpholinopropyl group, an acetyloxymethyl group, a benzoyloxymethyl group, a N-cyclohexylcarbamoyloxyethyl group, a N-phenylcarbamoyloxyethyl group, an acetylaminoethyl group, a N-methylbenzoylaminopropyl group, a 2-oxoethyl group, a 2-oxopropyl group, a carboxypropyl group, a methoxycarbonylethyl group, an allyloxycarbonylbutyl group, a chlorophenoxycarbonylmethyl group, a carbamoylmethyl group, a N-methylcarbamoylethyl group, a N,N-dipropylcarbamoylmethyl group, a N-(methoxyphenyl)carbamoylethyl group, a N-methyl-N-(sulfophenyl)carbamoylmethyl group, a sulfobutyl group, a sulfonatepropyl group, a sulfonatebutyl group, a sulfamoylbutyl group, a N-ethylsulfamoylmethyl group, a N,N-dipropylsulfamoylpropyl group, a N-tolylsulfamoylpropyl group, a N-methyl-N-(phosphonophenyl)sulfamoyloctyl group, a phosphonobutyl group, a phosphonatehexyl group, a diethylphosphonobutyl group, a diphenylphosphonopropyl group, a methylphosphonobutyl group, a methylphosphonatebutyl group, a tolylphosphonohexyl group, a tolylphosphonatehexyl group, a phosphonooxypropyl group, a phosphonateoxybutyl group, a benzyl group, a phenethyl group, an α-methylbenzyl group, a 1-methyl-1-phenylethyl group, a p-methylbenzyl group, a cinnamyl group, an allyl group, a 1-propenylmethyl group, a 2-butenyl group, a 2-methylallyl group, a 2-methylpropenylmethyl group, a 2-propynyl group, a 2-butynyl group, and a 3-butynyl group.

Specific examples of the aryl group preferable as R¹, R², or R³ include a condensed ring formed by 1 to 3 benzene rings, and a condensed ring formed by a benzene ring and a 5-membered unsaturated ring, and specific examples thereof include a phenyl group, a naphthyl group, an anthryl group, a phenanthryl group, an indenyl group, an acenaphthenyl group, and a fluorenyl group. Among these groups, a phenyl group, and a naphthyl group are more preferable.

Specific examples of the substituted aryl group preferable as R¹, R², or R³ include a the above-described aryl group having a monovalent group of nonmetal atoms (excluding hydrogen atoms) as a substituent on the carbon atom forming the ring. Preferable examples of the substituent include the above-described alkyl group, substituted alkyl group, and examples of the substituents in the alkyl group. Specific preferable examples of the substituted aryl group include a biphenyl group, a tolyl group, a xylyl group, a mesityl group, a cumenyl group, a chlorophenyl group, a bromophenyl group, a fluorophenyl group, a chloromethylphenyl group, a trifluoromethylphenyl group, a hydroxyphenyl group, a methoxyphenyl group, a methoxyethoxyphenyl group, an allyloxyphenyl group, a phenoxyphenyl group, a methylthiophenyl group, a tolylthiophenyl group, an ethylaminophenyl group, a diethylaminophenyl group, a morpholinophenyl group, an acetyloxyphenyl group, a benzoyloxyphenyl group, a N-cyclohexylcarbamoyloxyphenyl group, a N-phenylcarbamoyloxyphenyl group, an acetylaminophenyl group, a N-methylbenzoylaminophenyl group, a carboxyphenyl group, a methoxycarbonylphenyl group, an allyloxycarbonylphenyl group, a chlorophenoxycarbonylphenyl group, a carbamoylphenyl group, a N-methylcarbamoylphenyl group, a N,N-dipropylcarbamoylphenyl group, a N-(methoxyphenyl)carbamoylphenyl group, a N-methyl-N-(sulfophenyl)carbamoylphenyl group, a sulfophenyl group, a sulfonatephenyl group, a sulfamoylphenyl group, a N-ethylsulfamoylphenyl group, a N,N-dipropylsulfamoylphenyl group, a N-tolylsulfamoylphenyl group, a N-methyl-N-(phosphonophenyl)sulfamoylphenyl group, a phosphonophenyl group, a phosphonatephenyl group, a diethylphosphonophenyl group, a diphenylphosphonophenyl group, a methylphosphonophenyl group, a methylphosphonatephenyl group, a tolylphosphonophenyl group, a tolylphosphonatephenyl group, an allylphenyl group, a 1-propenylmethylphenyl group, a 2-butenylphenyl group, a 2-methylallylphenyl group, a 2-methylpropenylphenyl group, a 2-propynylphenyl group, a 2-butynylphenyl group, and 3-butynylphenyl group.

Particularly preferable examples of R² and R³ include a substituted or unsubstituted alkyl group. More preferable examples of R¹ include a substituted or unsubstituted aryl group. The reason for this is not evident, but is considered that these substituents particularly strengthen the interaction between electrons excited upon light absorption and the initiator compound, which improves the efficiency of the initiator compound to generate a radical, acid, or base.

In the next place, A in the Formula (12) is further described. A represents an optionally substituted aromatic ring or heterocycle, and specific examples of the optionally substituted aromatic ring or heterocycle include the same examples as those listed in the above-described description of R¹, R², or R³ in the Formula (12).

Among them, preferable examples of A include an aryl group having an alkoxy group, a thioalkyl group, or an amino group, and particularly preferable examples of A include an aryl group having an amino group.

In the next place, Y in the Formula (12) is further described. Y represents a group of nonmetal atoms necessary for forming a heterocycle together with the above-described A and the adjacent carbon atom. Examples of the heterocycle include a 5-, 6-, or 7-membered nitrogen-containing or sulfur-containing heterocycle which may have a condensed ring. Among them, a 5- or 6-membered heterocycle is preferable.

Preferable examples of the nitrogen-containing heterocycle include those known as a component of basic nuclei in melocyanine dyes described in L. G. Brooker et al., J. Am, Chem. Soc., vol. 73 (1951), pp. 5326-5358 and reference documents cited therein. Specific examples thereof include, thiazoles (e.g. thiazole, 4-methylthiazole, 4-phenylthiazole, 5-methylthiazole, 5-phenylthiazole, 4,5-dimethylthiazole, 4,5-diphenylthiazole, 4,5-di(p-methoxyphenylthiazole), 4-(2-thienyl)thiazole, and 4,5-di(2-furyl)thiazole),

benzothiazoles (e.g. benzothiazole, 4-chlorobenzothiazole, 5-chlorobenzothiazole, 6-chlorobenzothiazole, 7-chlorobenzothiazole, 4-methylbenzothiazole, 5-methylbenzothiazole, 6-methylbenzothiazole, 5-bromobenzothiazole, 4-phenylbenzothiazole, 5-phenylbenzothiazole, 4-methoxybenzothiazole, 5-methoxybenzothiazole, 6-methoxybenzothiazole, 5-iodobenzothiazole, 6-iodobenzothiazole, 4-ethoxybenzothiazole, 5-ethoxybenzothiazole, tetrahydrobenzothiazole, 5,6-dimethoxybenzothiazole, 5,6-dioxymethylene benzothiazole, 5-hydroxybenzothiazole, 6-hydroxybenzothiazole, 6-dimethylaminobenzothiazole, and 5-ethoxycarbonylbenzothiazole),

naphthothiazoles (e.g. naphtho[1,2]thiazole, naphtho[2,1]thiazole, 5-methoxynaphtho[2,1]thiazole, 5-ethoxynaphtho[2,1]thiazole, 8-methoxynaphtho[1,2]thiazole, and 7-methoxynaphtho[1,2]thiazole), thianaphtheno-7′,6′,4,5-thiazoles (e.g. 4′-methoxythianaphtheno-7′,6′,4,5-thiazole), oxazoles (e.g. 4-methyloxazole, 5-methyloxazole, 4-phenyloxazole, 4,5-diphenyloxazole, 4-ethyloxazole, 4,5-dimethyloxazole, and 5-phenyloxazole), benzoxazoles (e.g. benzoxazole, 5-chlorobenzoxazole, 5-methyl benzoxazole, 5-phenylbenzooxazole, 6-methylbenzoxazole, 5,6-dimethylbenzoxazole, 4,6-dimethylbenzoxazole, 6-methoxybenzoxazole, 5-methoxybenzoxazole, 4-ethoxybenzoxazole, 5-chlorobenzoxazole, 6-methoxybenzoxazole, 5-hydroxybenzoxazole, and 6-hydroxybenzoxazole), naphthooxazoles (e.g. naphtho[1,2]oxazole and naphtho[2,1]oxazole), selenazoles (e.g. 4-methylselenazole and 4-phenylselenazole), benzoselenazoles (e.g. benzoselenazole, 5-chlorobenzoselenazole, 5-methoxybenzoselenazole, 5-hydroxybenzoselenazole, and tetrahydrobenzoselenazole), naphthoselenazoles (e.g. naphtho[1,2]selenazole, and naphtho[2,1]selenazole),

thiazolines (e.g. thiazoline, 4-methylthiazoline, 4,5-dimethylthiazoline, 4-phenylthiazoline, 4,5-di(2-furyl)thiazoline, 4,5-diphenylthiazoline, and 4,5-di(p-methoxyphenyl)thiazoline), 2-quinolines (e.g. quinoline, 3-methylquinoline, 5-methylquinoline, 7-methylquinoline, 8-methylquinoline, 6-chloroquinoline, 8-chloroquinoline, 6-methoxyquinoline, 6-ethoxyquinoline, 6-hydroxyquinoline, and 8-hydroxyquinoline), 4-quinolines (e.g. quinoline, 6-methoxyquinoline, 7-methylquinoline, and 8-methylquinoline), 1-isoquinolines (e.g. isoquinoline and 3,4-dihydroisoquinoline), 3-isoquinolines (e.g. isoquinoline), benzimidazoles (e.g. 1,3-dimethylbenzimidazole, 1,3-diethylbenzimidazole, and 1-ethyl-3-phenylbenzimidazole), 3,3-dialkylindolenines (e.g. 3,3-dimethylindolenine, 3,3,5-trimethylindolenine, and 3,3,7-trimethylindolenine), 2-pyridines (e.g. pyridine and 5-methylpyridine), and 4-pyridine (e.g. pyridine). These ring substituents may be combined with each other to form a ring.

Examples of the sulfur-containing heterocycle include dithiol partial structures in dyes described in JP-A No. 3-296759.

Specific examples thereof include benzodithiols (e.g. benzodithiol, 5-t-butylbenzodithiol, and 5-methylbenzodithiol), naphthodithiols (e.g. naphtho[1,2]dithiol and naphtho[2,1]dithiol), dithiols (e.g. 4,5-dimethyldithiols, 4-phenyldithiols, 4-methoxycarbonyldithiols, 4,5-dimethoxycarbonyldithiols, 4,5-diethoxycarbonyldithiols, 4,5-ditrifluoromethyldithiol, 4,5-dicyano dithiol, 4-methoxycarbonylmethyldithiol, and 4-carboxymethyldithiol).

In the Formula (12), among the examples of nitrogen-containing or sulfur-containing heterocycles formed by Y together with the above-described A and adjacent carbon atom, the dye having a structure represented by the partial structural Formula of the following Formula (13) is particularly preferable because it offers a photosensitive composition having high sensitizing capacity and very excellent storage stability.

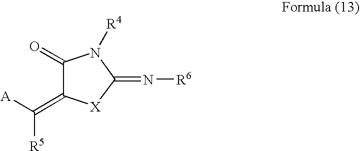

In the Formula (13), A represents an optionally substituted aromatic ring or heterocycle, and X represents an oxygen atom, a sulfur atom, or —N(R¹)—. R¹, R⁴, R⁵, and R⁶ each independently represents a hydrogen atom or a monovalent group of nonmetal atoms, and A, R¹, R⁴, R⁵, and R⁶ may be combined with each other to form an aliphatic or aromatic ring. In the Formula (13), A and R¹ are each equivalent to those in the Formula (12), R⁴ is equivalent to R² in the Formula (12), R⁵ is equivalent to R³ in the Formula (12), and R⁶ is equivalent to R¹ in the Formula (12).

The compound represented by the Formula (12) is further preferably a compound represented by the following Formula (14).

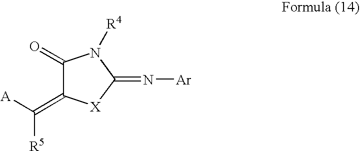

In the Formula (14), A represents an optionally substituted aromatic ring or heterocycle, and X represents an oxygen atom, a sulfur atom, or —N(R¹)—. R¹, R⁴, and R⁵ are each independently a hydrogen atom or a monovalent group of nonmetal atoms, and A, R¹, R⁴, and R⁵ may be combined with each other to form an aliphatic or aromatic ring. Ar represents a substituted aromatic ring or heterocycle. The sum total of the Hammett's values of the substituents on the Ar skeleton must be greater than 0. The “sum total of Hammett's values is larger than 0” as used herein may be that one substituent is present and the Hammett's value of the substituent is larger than 0 or that a plurality of substituents are present and the sum total of the Hammett's values of these substituents is larger than 0.

In the Formula (14), A and R¹ are equivalent to those in the Formula (12), R⁴ is equivalent to R² in the Formula (12), and R⁵ is equivalent to R³ in the Formula (12). Ar represents a substituted aromatic ring or heterocycle, and specific examples thereof include the same specific examples of the substituted aromatic ring or heterocycle as those listed for A in the description of the Formula (12). The total sum of the Hammett's values of the substituents to be introduced into Ar in the Formula (14) must be 0 or more. Examples of the substituents include a trifluoromethyl group, a carbonyl group, an ester group, a halogen atom, a nitro group, a cyano group, a sulfoxide group, an amide group, and a carboxyl group. The Hammett's value of these substituents are as follows: trifluoromethyl group (—CF₃, m: 0.43, p: 0.54); carbonyl group (e.g. —COH, m: 0.36, p: 0.43); ester group (—COOCH₃, m: 0.37, p: 0.45); halogen atom (e.g. Cl, m: 0.37, p: 0.23); cyano group (—CN, m: 0.56, p: 0.66); sulfoxide group (e.g. —SOCH₃, m: 0.52, p: 0.45); amide group (e.g. —NHCOCH₃, m: 0.21, p: 0.00); and carboxyl group (—COOH, m: 0.37, p: 0.45). The site of the substituent in the aryl skeleton and the Hammett's value of the substituent are listed inside the parentheses, and (m: 0.50) means that the Hammett's value of the substituent upon introduction into the meta position is 0.50. Preferable examples of Ar include a substituted phenyl group, and preferable examples of the substituent on the Ar skeleton include an ester group and a cyano group. The substituent is particularly preferably located in the ortho position on the Ar skeleton.

Preferable specific examples of the sensitizing dye represented by the Formula (12) (exemplary compounds D1 to D57) are shown below, however the invention is not limited to them. Among them, exemplary compounds D2, D6, D10, D18, D21, D28, D31, D33, D35, D38, D41, and D45 to D57 correspond to the compound represented by the Formula (13).

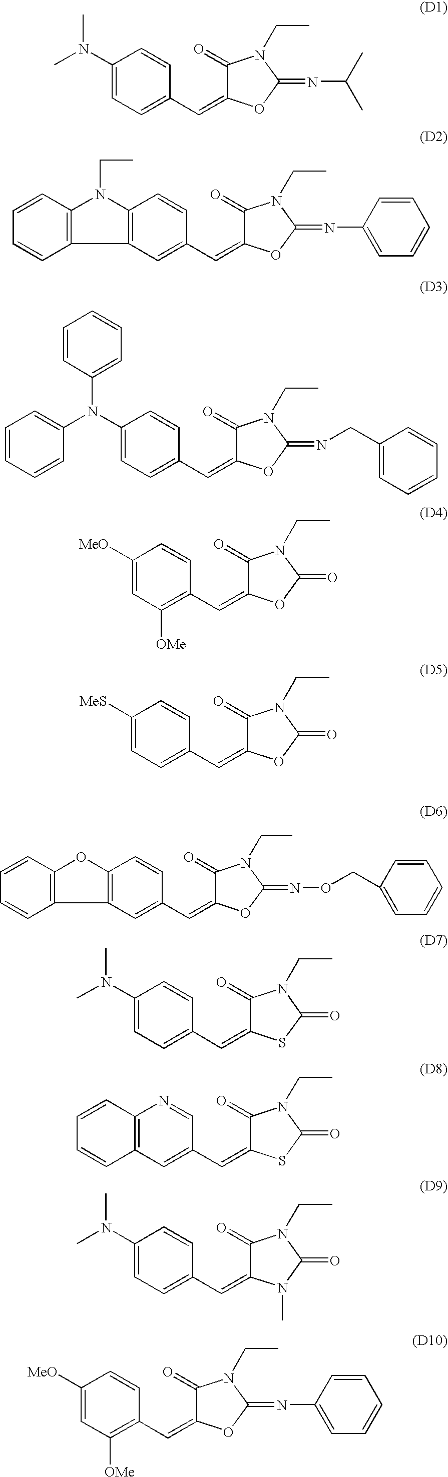

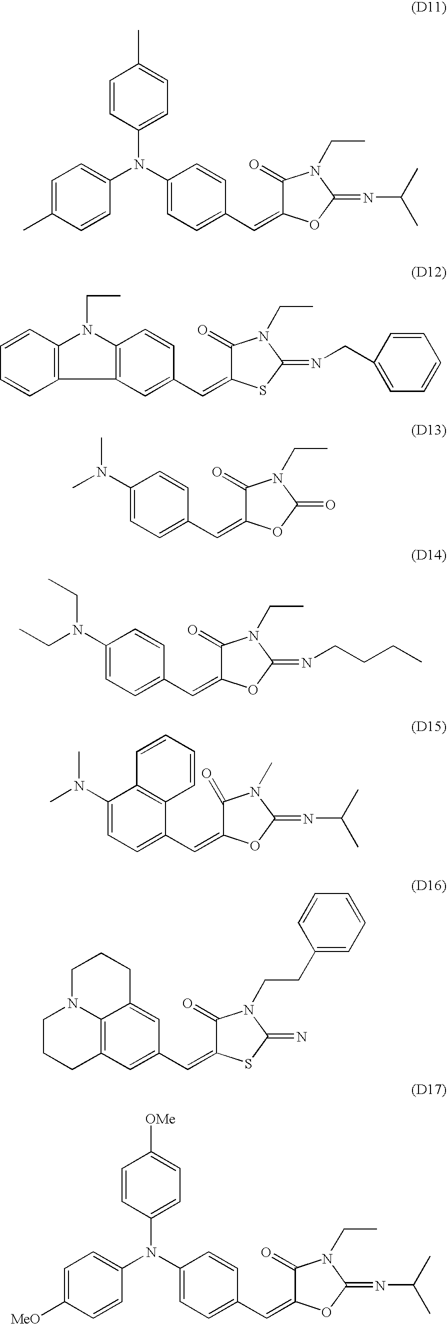

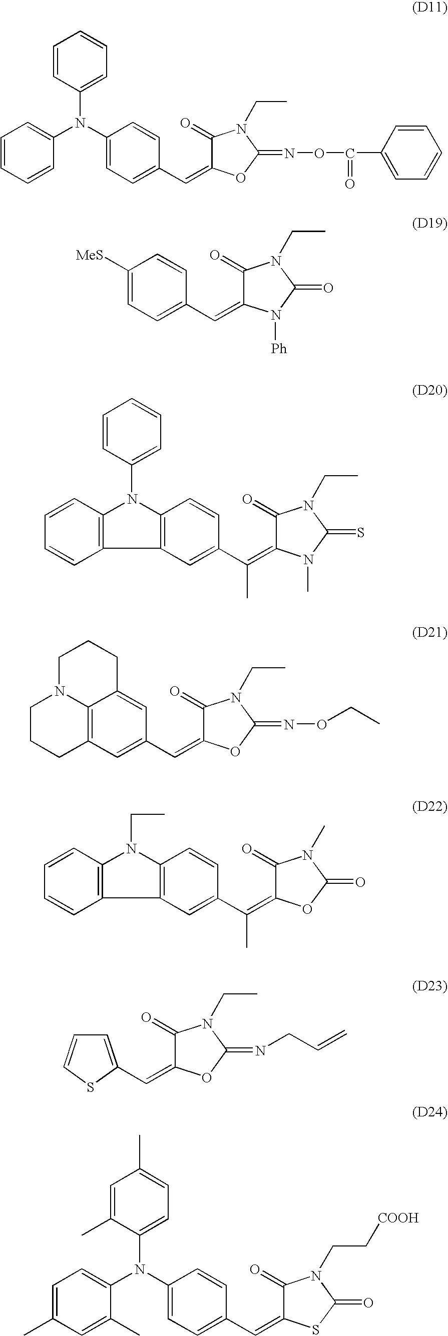

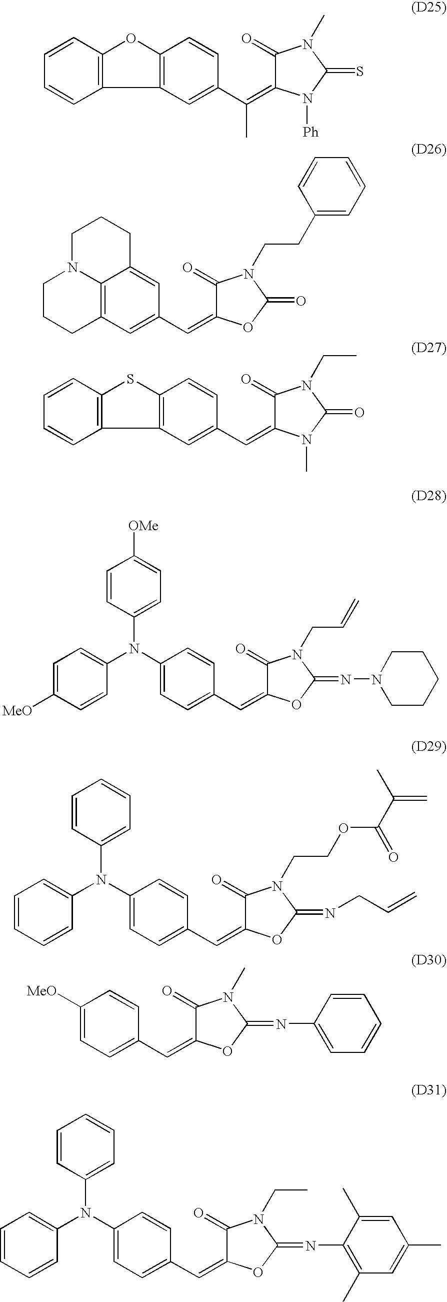

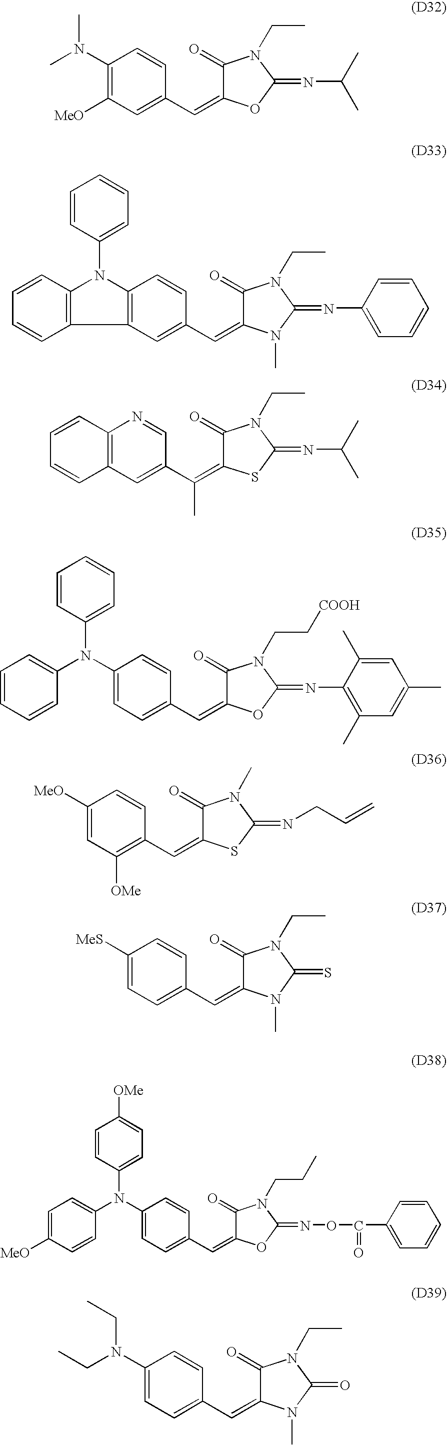

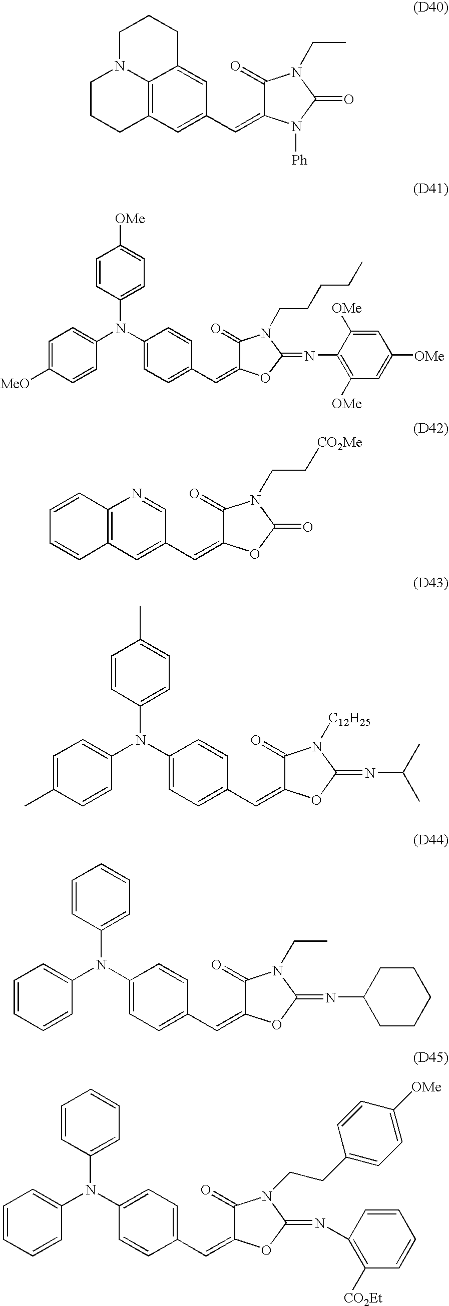

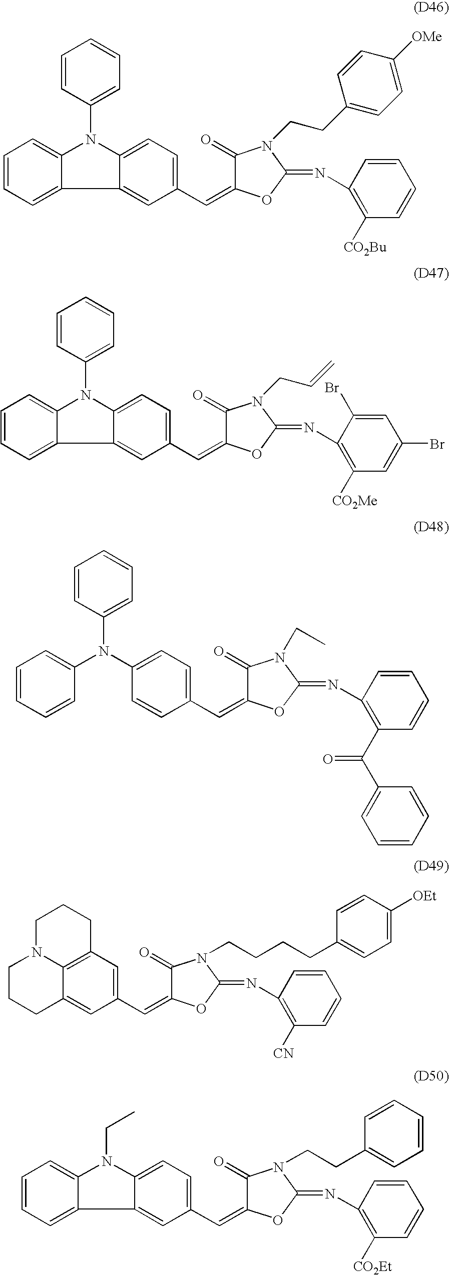

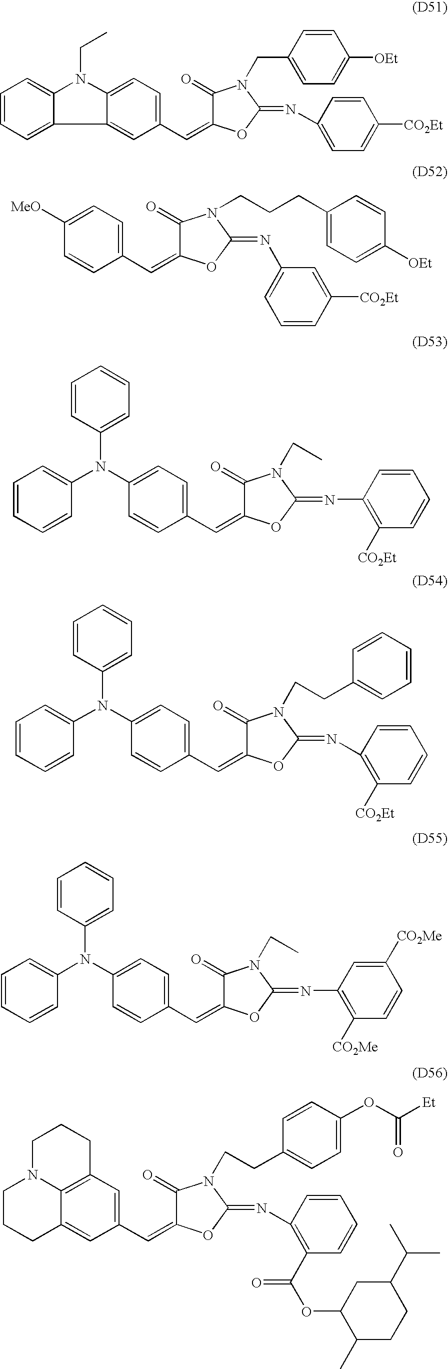

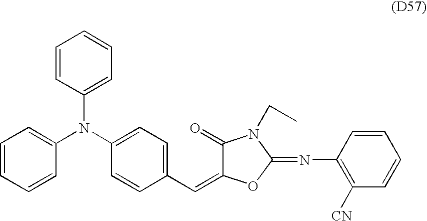

The method for synthesizing the compound represented by the Formula (12) is described below.

The compound represented by the Formula (12) is usually prepared by condensation reaction between an acidic nucleus having an active methylene group and a substituted or nonsubstituted aromatic ring or heterocycle, which can be synthesized with respect to JP-B No. 59-28329. Examples of the reaction method include condensation reaction between an acidic nuclear compound and a basic nuclear material having an aldehyde group or a carbonyl group on the heterocycle, as shown in the following reaction Formula (1). The condensation reaction is conducted, as necessary, in the presence of a base. The base may be freely selected from generally used bases such as amines, pyridines (e.g. trialkylamine, dimethylamino pyridine, and diazabicycloundecene DBU), metal amides (e.g. lithium diisopropylamide), metal alkoxides (e.g. sodium methoxide and potassium-t-butoxide), and metal hydrides (e.g. sodium hydride and potassium hydride).

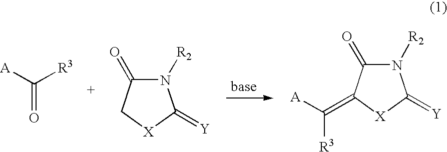

Examples of the other preferable synthesis method include a method according to the following reaction Formula (2). More specifically, an acidic nuclear compound in which Y is a sulfur atom is used as the starting material in the reaction Formula (1), and condensed with a basic nuclear material having an aldehyde group or a carbonyl group on the heterocycle to form a dye precursor in the same manner as the reaction Formula (1), thereafter the dye precursor is further reacted with a metal salt, which chemically interacts with a sulfur atom to form a metal sulfide, and water or a primary amine compound (R—NH₂, wherein R represents a monovalent group of nonmetal atoms).

Among them, the reaction represented by the reaction Formula (2) provides a high yield in each reaction, and particularly preferable from the viewpoint of synthesis efficiency. In particular, the reaction represented by the reaction Formula (2) is useful for the synthesis of the compound represented by the Formula (13).

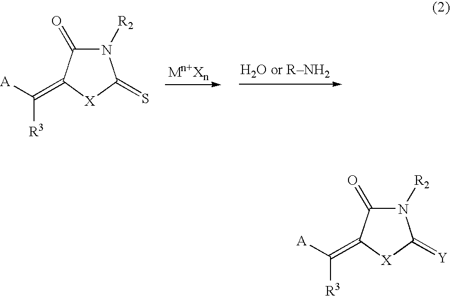

In the reaction Formula (2), Mⁿ+Xⁿ represents a metal salt which chemically interacts with a sulfur atom in the thiocarbonyl group to form a metal sulfide. Specific examples of the compound include AgBr, AgI, AgF, AgO, AgCl, Ag₂O, Ag(NO₃), AgSO₄, AgNO₂, Ag₂CrO₄, Ag₃PO₄, Hg₂(NO₃)₂, HgBr₂, Hg₂Br₂, HgO, HgI₂, Hg(NO₃)₂, Hg(NO₂)₂, HgBr₂, HgSO₄, Hg₂I₂, Hg₂SO₄, Hg(CH₃CO₂)₂, AuBr, AuBr₃, AuI, AuI₃, AuF₃, Au₂O₃, AuCl, AuCl₃, CuCl, CuI, CuI₂, CuF₂, CuO, CuO₂, Cu(NO₃)₂, CuSO₄, and Cu₃(PO₄)₂, in which M is Al, Au, Ag, Hg, Cu, Zn, Fe, Cd, Cr, Co, Ce, Bi, Mn, Mo, Ga, Ni, Pd, Pt, Ru, Rh, Sc, Sb, Sr, Mg, Ti, or the like, and X is F, Cl, Br, I, NO₃, SO₄, NO₂, PO₄, CH₃CO₂, or the like. Among them, a silver salt is a most preferable metal salt because it readily interacts with a sulfur atom.

The sensitizing dye represented by the Formula (12) used in the invention can be subjected to various chemical modification to improve the property of the image recording layer. For example, the sensitizing dye may be combined with an addition polymerizable compound structure (e.g. an acryloyl group or a methacryloyl group) through a covalent bond, an ionic bond, a hydrogen bond, or the like to increase the strength of the light-exposed film and suppress the unnecessary deposition of dyes from the light-exposed film.

Further, photosensitivity can be remarkably enhanced under particularly low concentration of an optical initiation system, by bonding the sensitizing dye with the above-described radical generating partial structure in the initiator compound (e.g. reduction decomposable sites such as alkyl halide, onium, peroxide, and biimidazole, and oxidation disintegrating sites such as borate, amine, trimethylsilylmethyl, carboxymethyl, carbonyl, and imine).

Further, in the case where the image recording material of the invention is used as a planographic printing plate precursor having a negative-working image recording layer, which is a preferable aspect of the invention, it is effective to introduce a hydrophilic site (acid groups or polar groups such as a carboxyl group and esters thereof, a sulfonic group and esters thereof, and an ethylene oxide group). Particularly, an ester type hydrophilic group exhibits excellent compatibility in the photosensitive layer due to its relatively hydrophobic structure, and generates an acid group upon hydrolysis to increase its hydrophilicity in a developer.

Additionally, for example, a substituent may be introduced as appropriate to improve compatibility in the photosensitive layer and to suppress crystal deposition. For example, in a certain kind of photosensitive system, an unsaturated bond such as an aryl group or an allyl group may be considerably effective at improving the compatibility. Besides, crystal deposition is remarkably suppressed by introducing steric hindrance between the π planes of the dye through introduction of a branched alkyl structure or other method. Further, adhesiveness of a metal, metal oxide and the like to an inorganic substance is improved by introducing a phosphonate group, an epoxy group, a trialkoxysilyl group, or the like. Alternatively, polymerization of the sensitizing dye or other methods may be used according to the intended use.

The sensitizing dye used the invention preferably includes at least one sensitizing dye represented by the Formula (12). Within the range represented by the Formula (12), details of the use-what structure is used (e.g. the above-described modification), whether they are used alone or in combination of two or more of them, and the addition amount—can be determined as appropriate in accordance with the performance and design of the final photosensitive material. For example, the combination of two or more kinds of sensitizing dyes improves the compatibility with the image recording layer.

The selection of the sensitizing dye largely depends on its photosensitivity and molar extinction coefficient at the luminescence wavelength of the light source to be used. The use of a dye having a large molar extinction coefficient can relatively decrease the addition amount of the dye, which is economical and beneficial to the physical property of the image recording layer.

In the invention, other general-purpose sensitizing dyes except for the sensitizing dye represented by the Formula (12) may be used within the range which does not impair the effect of the invention.

The addition amount of the sensitizing dye is selected as appropriate in consideration of the photosensitivity, resolution, and film physical properties of the image recording layer which are significantly influenced by the absorbance at the wavelength of the light source.

For example, in a region where the absorbance is 0.1 or lower, the sensitivity decreases, and the resolution decreases because of the influence of halation. However, such a low absorbance may be suitable for curing a thick film having a thickness of 5 μm or more. In a region where the absorbance is 3 or higher, a large part of the light is absorbed into the surface of the image recording layer, which inhibits inside curing, and resulting in, for example in the case where the image recording material of the invention is used as a planographic printing plate precursor, insufficient film strength and adhesiveness to the substrate.

For example, in the case where the image recording material of the invention is used in a planographic printing plate precursor having a relatively thin image recording layer, the addition amount of the sensitizing dye is preferably determined in such a manner that the absorbance of the image recording layer is in a range of from 0.1 to 1.5, preferably in a range of from 0.25 to 1. The absorbance is determined by the addition amount of the sensitizing dye and the thickness of the image recording layer, hence the predetermined absorbance is achieved by controlling these factors. The absorbance of the image recording layer may be measured by ordinary methods. Examples of the measurement method include a method of forming an image recording layer on a transparent or white support in an appropriately determined thickness such that the coating amount after drying is within the range necessary for a planographic printing plate, and measuring the absorbance with a transmission optical densitometer, and a method of forming a recording layer on a reflective support such as an aluminum support, and measuring the reflection density.

In the case where the image recording layer in the invention is used as a recording layer of a planographic printing plate precursor, the addition amount of the sensitizing dye is usually in a range of from 0.05 to 30 parts by mass, preferably from 0.1 to 20 parts by mass, and further preferably from 0.2 to 10 parts by mass with respect to 100 parts by mass of the total solid content in the image recording layer.

(Infrared Ray Absorbing Agent)

In the invention, when light exposure is performed using a laser light source emitting infrared rays having wavelengths of from 760 to 1,200 nm, an infrared ray absorbing agent having the absorption maximum in the wavelength range is usually used as a sensitizing dye. The infrared ray absorbing agent is capable of absorbing infrared rays and converting them into heat. A radical generator (polymerization initiator) is heat-decomposed by the heat generated upon light exposure, and generates radicals. The infrared ray absorbing agent used in the invention is a dye or pigment having an absorption maximum at wavelengths of from 750 nm to 850 nm.

The dye may be a commercially available dye or a known dye as described in reference documents such as “Senryo Binran (Dye Handbook) (edited by The Society of Synthetic Organic Chemistry, Japan 1970). Specific examples thereof include azo dyes, metal complex salt azo dyes, pyrazolone azo dyes, naphthoquinone dyes, anthraquinone dyes, phthalocyanine dyes, carbonium dyes, quinoneimine dyes, methine dyes, cyanine dyes, squarylium dyes, pyrylium salt, and metal thiolate complex dyes.

Preferable examples of dyes include cyanine dyes described in JP-A No. 58-125246, JP-A No. 59-84356, JP-A No. 59-202829, and JP-A No. 60-78787, methine dyes described in JP-A No. 58-173696, JP-A No. 58-181690, and JP-A No. 58-194595, naphthoquinone dyes described in JP-A No. 58-112793, JP-A No. 58-224793, JP-A No. 59-48187, JP-A No. 59-73996, JP-A No. 60-52940, and JP-A No. 60-63744, squarylium dyes described in JP-A No. 58-112792, and cyanine dyes described in U.K. Patent No. 434,875.

Near-infrared absorbing sensitizers described in U.S. Pat. No. 5,156,938 are also preferably used. A substituted arylbenzo(thio)pyrylium salt described in U.S. Pat. No. 3,881,924, a trimethinethiapyrylium salt described in JP-A No. 57-142645 (U.S. Pat. No. 4,327,169), pyrylium type compounds described in JP-A Nos. 58-181051, 58-220143, 59-41363, 59-84248, 59-84249, 59-146063 and 59-146061, cyanine dyes described in JP-A No. 59-216146, pentamethinethiopyrylium salts and the like described in U.S. Pat. No. 4,283,475 and pyrylium compounds disclosed in JP-B Nos. 5-13514 and 5-19702 are also preferably used.

Other preferable examples of the infrared absorbing dye may include near-infrared absorbing dyes described as Formulae (I) and (II) in U.S. Pat. No. 4,756,993.

Other preferable examples of the infrared radiation absorption dye in the invention include specific indolenine cyanine dyes described in Japanese Patent Application No. 2001-6326, and Japanese Patent Application No. 2001-237840, which are shown below.

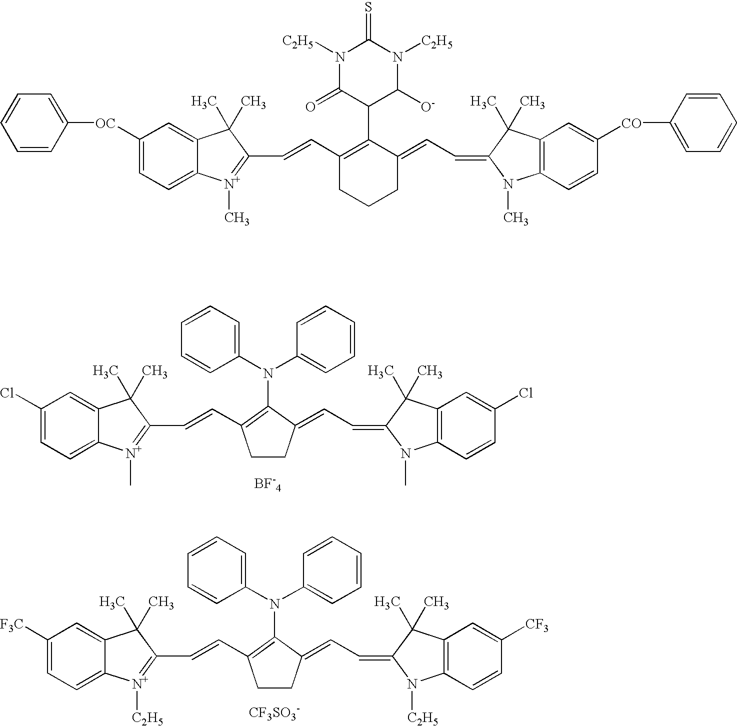

Particularly preferable among these dyes are cyanine colorants, phthalocyanine dyes, oxonol dyes, squarylium colorants, pyrylium salts, thiopyrylium dyes, and nickel thiolate complexes. From the viewpoint of sensitivity, preferable among these dyes are those represented by Formulae (a) to (e) below, and cyanine colorants represented by Formula (a) below are most preferable because they give high polymerization activity and are excellent in stability and economical efficiency when used in the recording layer in the invention.

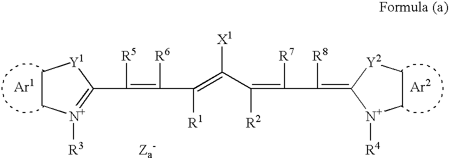

In the Formula (a), X¹ represents a hydrogen atom, halogen atom, —NAr^{x}₂, X²-L¹ or the group shown below. Ar^{x} represents a C₆ to C₁₄ aromatic hydrocarbon group which may have one or more substituents selected from the group consisting of halogen atoms, alkyl groups, allyl groups, alkenyl groups, alkynyl groups, cyano groups, carboxy groups, nitro groups, amide groups, ester groups, alkoxy groups, amino groups and heterocyclic groups, and these substituents may themselves be substituted by such a substituent as those described above. X² represents an oxygen atom, a sulfur atom or —N(R^{x})— wherein R^{x} represents a hydrogen atom or a C₁ to C₁₀ hydrocarbon group. L¹ represents a C₁ to C₁₂ hydrocarbon group, an aromatic ring having a heteroatom, or a C₁ to C₁₂ hydrocarbon group containing a heteroatom. The term “heteroatom” used herein refers to an atom selected from N, S, O, a halogen atom or Se.

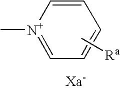

In the above Formula, Xₐ⁻ has the same definition as that of Zₐ⁻ defined later, and R^{a} represents a hydrogen atom or a substituent selected from an alkyl group, an aryl group, a substituted or unsubstituted amino group, or a halogen atom.

R¹ and R² each independently represent a C₁₋₁₂ hydrocarbon group. For the storage stability of the recording layer coating liquid, each of R¹ and R² is preferably a hydrocarbon group containing two or more carbon atoms, and more preferably R¹ and R² are bound to each other to form a 5- or 6-membered ring.

Ar¹ and Ar² may be the same or different, and each independently represent an aromatic hydrocarbon group which may have a substituent. The aromatic hydrocarbon group is preferably a benzene ring or a naphthalene ring. The substituent is preferably a hydrocarbon group containing 12 or less carbon atoms, a halogen atom or an alkoxy group containing 12 or less carbon atoms. Y¹ and Y² may be the same or different, and each independently represent a sulfur atom or a dialkyl methylene group containing 12 or less carbon atoms. R³ and R⁴ may be the same or different, and each independently represent a hydrocarbon group containing 20 or less carbon atoms which may have a substituent. The substituent is preferably an alkoxy group containing 12 or less carbon atoms, a carboxyl group or a sulfo group. R⁵, R⁶, R⁷ and R⁸ may be the same or different, and each independently represent a hydrogen atom or a hydrocarbon group containing 12 or less carbon atoms. Each of R⁵, R⁶, R⁷ and R⁸ is preferably a hydrogen atom because the starting material is easily available. Zₐ⁻ represents a counter anion. However, when the cyanine colorant represented by the Formula (a) has an anionic substituent in its structure and does not necessitate neutralization of the charge, Zₐ⁻ is not necessary. Because of the storage stability of the recording layer coating liquid, Zₐ⁻ is preferably a halogen ion, a perchlorate ion, a tetrafluoroborate ion, a hexafluorophosphate ion or a sulfonate ion, particularly preferably a perchlorate ion, a hexafluorophosphate ion or an aryl sulfonate ion.

Specific examples of the cyanine colorants represented by the Formula (a), which can be used preferably in the invention, include not only those illustrated below, but also those described in paragraph numbers (0017) to (0019) in JP-A No. 2001-133969, paragraph numbers (0012) to (0038) in JP-A No. 2002-40638, and paragraph numbers (0012) to (0023) in JP-A No. 2002-23360.

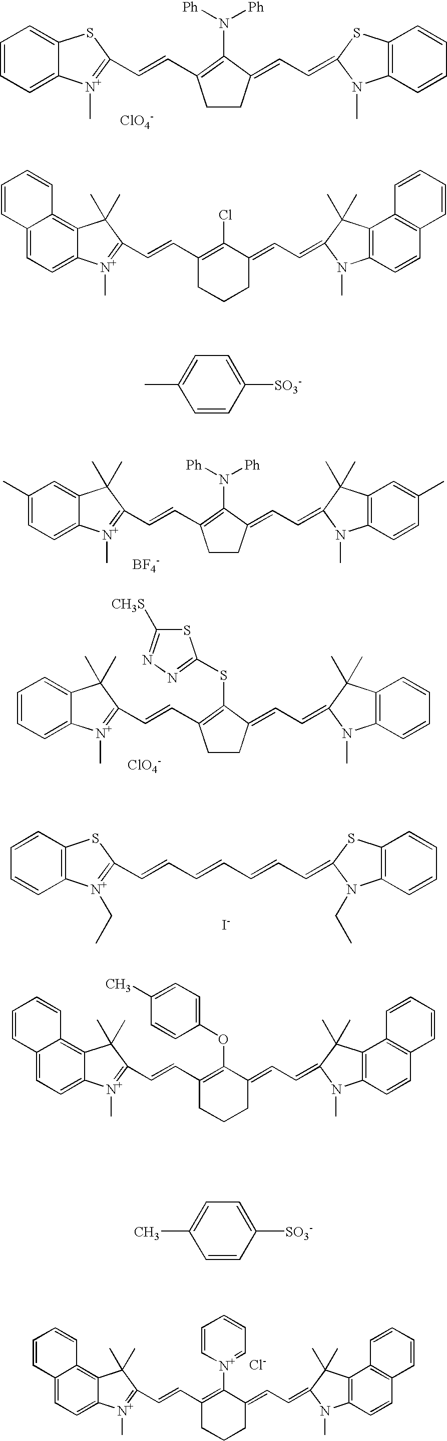

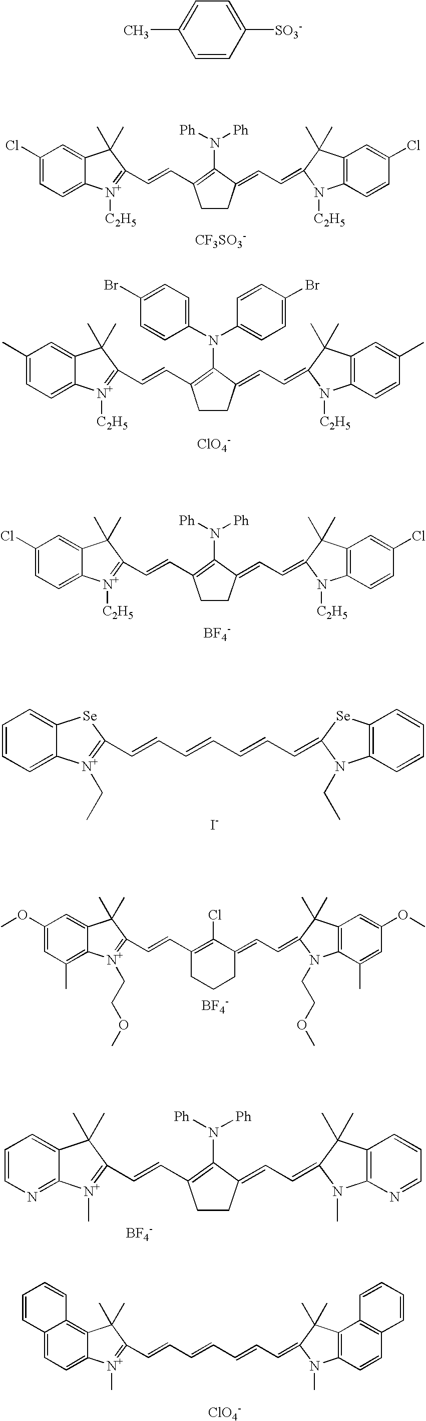

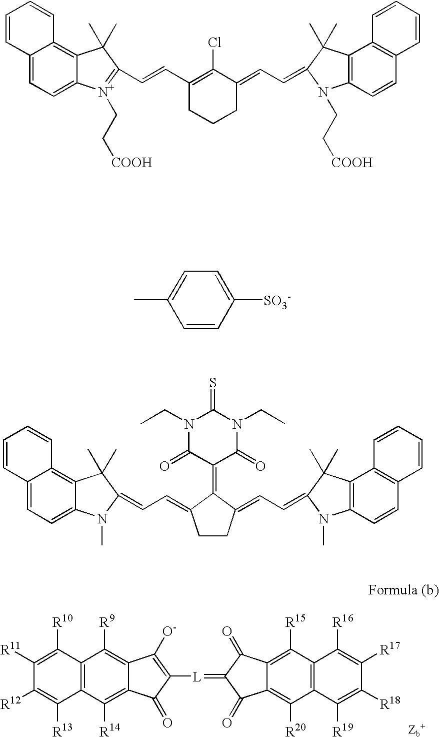

In the Formula (b), L represents a methine chain containing 7 or more conjugated carbon atoms, and the methine chain may have a substituent, and the substituents may be bound to each other to form a ring structure. Z_{b}⁺ represents a counter cation. The counter cation is preferably ammonium, iodonium, sulfonium, phosphonium, pyridinium or an alkali metal cation (Ni⁺, K⁺, Li⁺). R⁹ to R¹⁴ and R¹⁵ to R²⁰ each independently represent a hydrogen atom or a substituent selected from a halogen atom, a cyano group, an alkyl group, an aryl group, an alkenyl group, an alkynyl group, a carbonyl group, a thio group, a sulfonyl group, a sulfinyl group, an oxy group or an amino group, or a substituent composed of a combination of two or three such substituents which may be bound to each other to form a ring structure. Among the compounds of the Formula (b), those having a methine chain containing 7 conjugated carbon atoms as L, and those in which each of R⁹ to R¹⁴ and R¹⁵ to R²⁰ represents a hydrogen atom, are preferable from the viewpoint of easy availability and effects.

Examples of the dyes represented by the Formula (b), which can be used preferably in the invention, include those illustrated below:

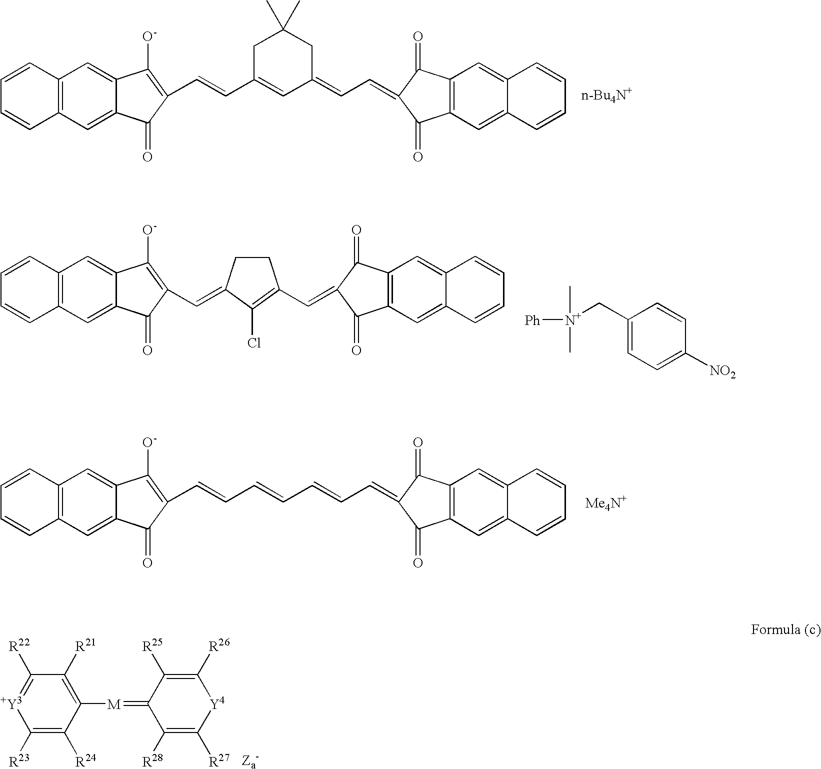

In the Formula (c), Y³ and Y⁴ each independently represent an oxygen atom, a sulfur atom, a selenium atom or a tellurium atom; M represents a methine chain containing 5 or more conjugated carbon atoms; R²¹ to R²⁴ and R²⁵ to R²⁸ may be the same as or different from one another, and each independently represent a hydrogen atom, a halogen atom, a cyano group, an alkyl group, an aryl group, an alkenyl group, an alkynyl group, a carbonyl group, a thio group, a sulfonyl group, a sulfinyl group, an oxy group or an amino group; and Zₐ⁻ represents a counter anion and has the same definition as that of Zₐ⁻ in the Formula (a) above.

Examples of the dyes represented by the Formula (c), which can be used preferably in the invention, include those illustrated below:

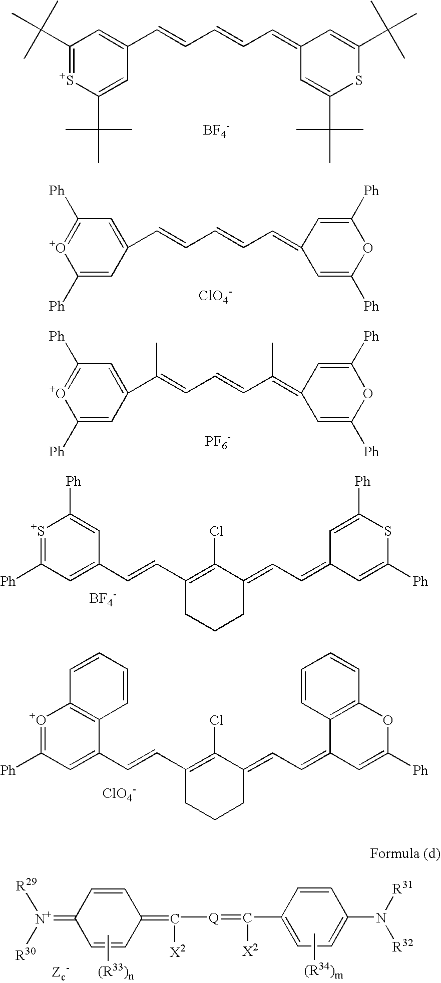

In the Formula (d), R²⁹ to R³¹ each independently represent a hydrogen atom, an alkyl group or an aryl group; R³³ and R³⁴ each independently represent an alkyl group, a substituted oxy group or a halogen atom; n and m each independently represent an integer of 0 to 4; R²⁹ and R³⁰, or R³¹ and R³², may be bound to each other to form a ring; R²⁹ and/or R³⁰ may be bound to R³³ to form a ring; R³¹ and/or R³² may be bound to R³⁴ to form a ring; when plural R³³s are present, some of R³³s may be mutually bound to form a ring; when plural R³⁴s are present, some of R³⁴s may be mutually bound to form a ring; X² and X³ each independently represent a hydrogen atom, an alkyl group or an aryl group, and at least one of X² and X³ represents a hydrogen atom or an alkyl group; Q is an optionally substituted trimethine group or pentamethine group which may form a ring structure with a divalent organic group; and Zc⁻ represents a counter anion and has the same definition as that of Zₐ⁻ in the Formula (A) above.

Examples of the dyes represented by the Formula (d), which can be used preferably in the invention, include those illustrated below:

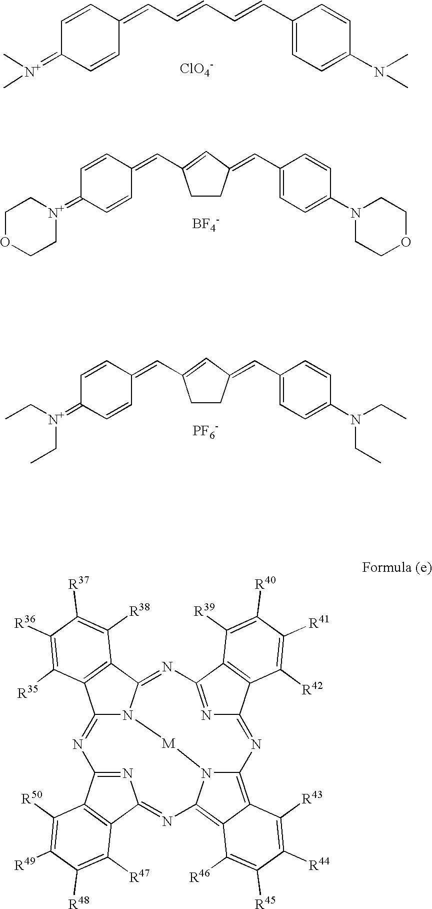

In the Formula (e), R³⁵ to R⁵⁰ each independently represent a hydrogen atom, halogen atom, cyano group, alkyl group, aryl group, alkenyl group, alkynyl group, hydroxyl group, carbonyl group, thio group, sulfonyl group, sulfinyl group, oxy group, amino group, and onium salt structure, each of which may have a substituent; and M represents two hydrogen atoms, a metal atom, a halometal group or an oxymetal group, and examples of the metal atom contained therein include the groups IA, IIA, IIIB and IVB atoms in the periodic table, the transition metals in the first, second and third periods, and lanthanoid elements, among which copper, magnesium, iron, zinc, cobalt, aluminum, titanium and vanadium are preferable.

Examples of the dyes represented by the Formula (e), which can be used preferably in the invention, include those illustrated below:

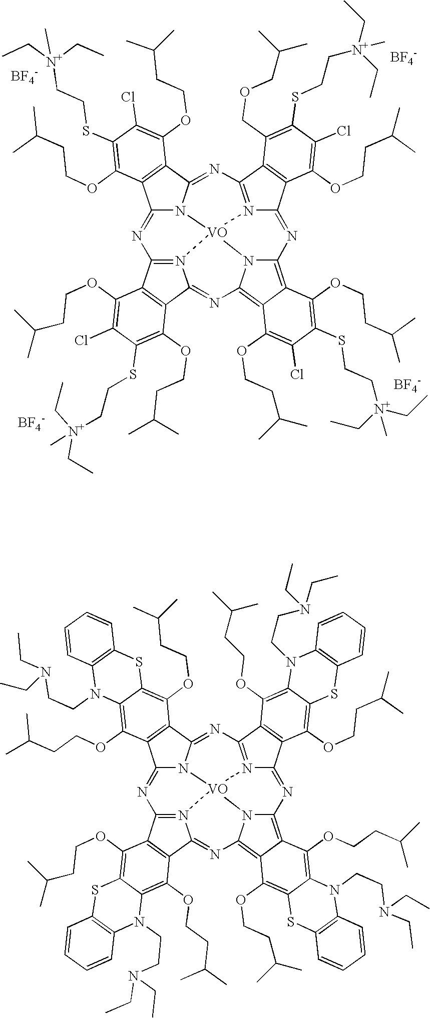

Examples of the pigment used in the invention include commercial pigments and those described in Color Index (C. I.) Handbook, “Saishin Ganryo Binran” (Newest Dye Handbook) (published in 1977 and compiled by Japanese Society of Pigment Technology), “Saishin Ganryho Oyo Gijyutsu” (Newest Pigment Applied Technology) (published in 1986 by CMC), and “Insatsu Inki Gijyutsu” (Printing Ink Technology) (published in 1984 by CMC).

As to the type of the pigment, examples of usable pigments include black pigments, yellow pigments, orange pigments, brown pigments, red pigments, violet pigments, blue pigments, green pigments, fluorescent pigments, metallic powder pigments, and other pigments such as polymer-binding colorants. Specific examples thereof include insoluble azo pigments, azo lake pigments, condensed azo pigments, chelate azo pigments, phthalocyanine pigments, anthraquinone pigments, perylene pigments, perinone pigments, thioindigo pigments, quinacridone pigments, dioxazine pigments, isoindolinone pigments, quinophthalone pigments, dyed lake pigments, azine pigments, nitroso pigments, nitro pigments, natural pigments, fluorescent pigments, inorganic pigments, and carbon black. A preferable pigment among those described above is carbon black.

Such pigments may be used with or without being subjected to surface treatment. Examples of the method of surface treatment include a method of coating the surface with a resin or a wax, a method of allowing a surfactant to adhere to the surface, and a method of bonding a reactive substance (e.g., a silane coupling agent, an epoxy compound, a polyisocyanate etc.) onto the surface of the pigment. These methods of surface treatment are described in “Kinzoku Sekken No Seishitsu To Oyo” (Properties and Application of Metallic Soap) (Sachi Shobo), “Insatsu Inki Gijyutsu” (Printing Ink Technology) (published in 1984 by CMC Shuppan) and “Saishin Ganryho Oyo Gijyutsu” (Newest Pigment Applied Technology) (published in 1986 by CMC Shuppan).

The particle diameter of the pigment is preferably in a range of from 0.01 to 10 μm, more preferably from 0.05 to 1 μm, still more preferably from 0.1 to 1 μm. A pigment particle diameter of less than 0.01 μm is not preferable in respect of the stability of a pigment dispersion in the image recording layer coating liquid, whereas a particle diameter of more than 10 μm is not preferable in respect of the uniformity of the image recording layer.

As the method of dispersing the pigments, any known dispersion techniques used in production of inks or toners can be used. Examples of the dispersing machine include a supersonic dispersing device, a sand mill, an attritor, a pearl mill, a super mill, a ball mill, an impeller, a disperser, a KD mill, a colloid mill, a dynatron, a triple roll mill, and a press kneader. Details thereof are described in “Saishin Ganryho Oyo Gijyutsu” (Newest Pigment Applied Technology) (published in 1986 by CMC Shuppan).

The components (D) in the invention may include only one substance or a combination of two or more substances.

The component (D) in the invention is preferably a cyanine colorant.

From the viewpoint of sensitivity, the component (D) is more preferably a cyanine colorant represented by the Formula (A). Among colorants represented by the Formula (A), cyanine colorants in which X¹ is a diarylamino group or X²-L¹ is preferable, and those having a diaryl amino group are more preferable.

A cyanine colorant having an electron-withdrawing group or a heavy atom-containing substituent at each of indolenine sites at both terminals is also preferable, and for example, the one described in Japanese Patent Application No. 2001-6323 is preferably used. A cyanine colorant which has an electron-withdrawing group at each of indolenine sites at both terminals, and which has a diarylamino group as X¹ is most preferable.

In the case where the image recording material of the invention is used as a negative-working planographic printing plate precursor, the sensitizing dye (D) such as the above-described infrared ray absorbing agent, which is added to promote curing of the polymerizable compositions, may be added to the image recording layer, or an independently provided other layer, for example, a topcoat layer or an undercoat layer. In particular, when the image recording material of the invention is used as an image recording layer of a negative-working photosensitive planographic printing plate, the sensitizing dye (D) preferably has an optical density of from 0.1 to 3.0 in the image recording layer at the absorption maximum in a wavelength range of from 760 nm to 1200 nm from the viewpoint of sensitivity. The optical density is determined according to the addition amount of the infrared ray absorbing agent and the thickness of the image recording layer, hence the predetermined optical density is achieved by controlling these factors.

The optical density of the image recording layer can be measured by an ordinary method. Examples of the measurement method include a method of forming an image recording layer on a transparent or white support in an appropriately determined thickness such that the coating amount after drying is within the range necessary for a planographic printing plate, and measuring the absorbance with a transmission optical densitometer, and a method of forming a recording layer on a reflective support such as an aluminum support, and measuring the reflection density.

The addition amount of the sensitizing dye to the image recording layer is preferably from 0.5 to 20% by mass with respect to the total solid content in the image recording layer. Within the range, property changes are highly sensitive to light exposure, thereby high sensitivity is achieved with no deleterious influences on the uniformity and strength of the film.

The image recording material of the invention is usable in various fields as long as it is cured by light exposure and the light-unexposed portion is removed by alkali developing treatment to form an image. Examples of the application include a planographic printing plate precursor, a resist, and a coating. Preferably, the image recording material is used as a planographic printing plate precursor having a negative-working image recording layer because it is capable of forming images with high sensitivity, and has excellent alkali developability.

An example of a planographic printing plate precursor, which is a preferable aspect of the invention, is described below, however the application of the image recording material of the invention is not limited to them.

(Layer Structure of Planographic Printing Plate Precursor)

The layer structure of a planographic printing plate precursor including the image recording material of the invention is described below.

The planographic printing plate precursor is composed of a support having provided thereon an image recording layer containing at least each of the above-described components (A) to (C), the above-described specific protective layer, and as necessary other layers such as an intermediate layer, an undercoat layer, and a back coat layer.

(Recording Layer)

In the planographic printing plate precursor according to the invention, the recording layer having a function of forming an image will be described. The recording layer of the planographic printing plate precursor according to the invention contains the components (A) to (C) and preferably contains a compound (D) having absorption maximum at 700 to 1200 nm from the viewpoint of improving sensitivity.

The component (C) in the recording layer of the planographic printing plate precursor according to the invention functions particularly as a polymerization initiator for initiating and accelerating the polymerization of the polymerizable compound that is the component (B).

Details of the compound used as the polymerizable compound (B) used in the recording layer of the planographic printing plate precursor are described in detail above. The selection of the compound to be used may depend on the requirements described above. In addition, a compound having a specific structure may be selected for the purpose of improving the adhesiveness to the support, the overcoat layer, or the like described later.

The usage of the polymerizable compound may be arbitrarily selected as to its appropriate structure, Formulation, and addition amount in consideration of the polymerization degree of inhibition by oxygen, resolution, fogging property, refractive index variation, and surface tackiness. According to circumstances, a layer structure and a coating method containing an undercoat and a topcoat are possible.

(E) Other Components

Other components suitable for the intended use, the production method etc. can further be added if necessary to the polymerizable composition according to the invention or to the composition constituting the recording layer of the planographic printing plate precursor. Hereinafter, preferable additives will be described.

(E-1) Co-Sensitizer

By use of a certain additive in the polymerizable composition, the sensitivity can be further improved. Such a compound will be referred to as a co-sensitizer hereinafter. Its working mechanism is not clear, but is considered to be based mainly on the following chemical process. That is, it is estimated that various intermediate active species (radials, cations) generated in the photo-reaction initiated by the heat-polymerization initiator and in the subsequent addition-polymerization reaction react with the co-sensitizer to form new active radicals. Such co-sensitizers can be roughly classified into (i) those capable of forming active radicals when reduced, (ii) those capable of forming active radicals when oxidized, and (iii) those converted into highly active radicals through reaction with radicals with low activity or those acting as chain transfer agents. There are many compounds whose classification is not commonly understood.

(i) Compound Forming Active Radicals when Reduced Reduction

Compounds having a carbon-halogen bond: It is considered that the carbon-halogen bond is reductively cleaved to generate active radicals. Specifically, for example, trihalomethyl-s-triazines and trihalomethyl oxadiazoles can be preferably used.

Compounds having a nitrogen-nitrogen bond: It is considered that the nitrogen-nitrogen bond is reductively cleaved to form active radicals. Specifically, hexaryl biimidazoles can be preferably used.

Compounds having an oxygen-oxygen bond: It is considered that the oxygen-oxygen bond is reductively cleaved to generate active radicals. Specifically, organic peroxides can be preferably used.

Onium compounds: It is considered that a carbon-heteroatom bond or an oxygen-nitrogen bond is reductively cleaved to generate active radicals. Specifically, diaryl iodonium salts, triaryl sulfonium salts, and N-alkoxy pyridinium (azinium) salts can be preferably used.

Ferrocene, iron arene complexes: Capable of forming active radicals reductively.

(ii) Compounds Forming Active Radicals when Oxidized

Alkylate complexes: It is considered that a carbon-heteroatom bond is oxidatively cleaved to generate active radicals. Specifically, for example, triaryl alkyl borates can be preferably used.

Alkyl amine compounds: It is considered that a C—X bond on a carbon adjacent to the nitrogen is cleaved by oxidation to form active radicals. X is preferably a hydrogen atom, a carboxyl group, a trimethylsilyl group, or a benzyl group. Specifically, ethanol amines, N-phenyl glycines, N-phenyliminodiacetic acid and its derivatives, and N-trimethylsilylmethyl anilines can be mentioned.

Sulfur- or tin-containing compounds: A compound obtained by replacing the nitrogen atom in any of the above-described amines with a sulfur atom or a tin atom can form active radicals in a similar mechanism. Further, compounds having S—S bonds are known to act as sensitizers by cleavage of the S—S bonds.

α-Substituted methyl carbonyl compounds: Capable of forming active radicals through the cleavage of the carbonyl-α carbon bond upon oxidation. Further, compounds obtained by replacing the carbonyl in such a compound with an oxime ether exhibit the same action. Specifically, examples include 2-alkyl-1-[4-(alkylthio)phenyl]-2-morpholinopronone-1 and derivatives thereof, as well as oxime ethers prepared by reacting such compounds with hydroxy amines and then etherifying N—OH.

Sulfinates: Capable of forming active radicals reductively. Specifically, sodium aryl sulfinates can be mentioned.

(iii) Compounds converted into highly active radicals through reaction with radicals, or compounds acting as chain transfer agents: For example, compounds having SH, PH, SiH or GeH in the molecule are usable. These compounds can form radials by donating hydrogen to radicals having low-activity or by undergoing oxidization and subsequent deprotonation. Specifically, for example, 2-mercaptobenzimidazoles can be mentioned.

In a preferable embodiment, a polycarboxylic acid compound containing an aromatic ring or heterocyclic aromatic ring structure to which at least two carboxyl groups are bonded directly or via a divalent linking group is contained for the purpose of improving sensitivity and/or developability. Specific examples of the polycarboxylic acid compound include (p-acetamidophenylimido) diacetic acid, 3-(bis(carboxymethyl)amino)benzoic acid, 4-(bis(carboxymethyl)amino)benzoic acid, 2-[(carboxymethyl)phenylamino]benzoic acid, 2-[(carboxymethyl)phenylamino]-5-methoxybenzoic acid, 3-[bis(carboxymethyl)amino]-2-naphthalene carboxylic acid, N-(4-aminophenyl)-N-(carboxymethyl)glycine, N,N′-1,3-phenylene-bis-glycine, N,N′-1,3-phenylenebis[N-(carboxymethyl)]glycine, N,N′-1,2-phenylenebis[N-(carboxymethyl)]glycine, N-(carboxymethyl)-N-(4-methoxyphenyl)glycine, N-(carboxymethyl)-N-(3-methoxyphenyl)glycine, N-(carboxymethyl)-N-(3-hydroxyphenyl)glycine, N-(carboxymethyl)-N-(3-chlorophenyl)glycine, N-(carboxymethyl)-N-(4-bromophenyl)glycine, N-(carboxymethyl)-N-(4-chlorophenyl)glycine, N-(carboxymethyl)-N-(2-chlorophenyl)glycine, N-(carboxymethyl)-N-(4-ethylphenyl)glycine, N-(carboxymethyl)-N-(2,3-dimethylphenyl)glycine, N-(carboxymethyl)-N-(3,4-dimethylphenyl)glycine, N-(carboxymethyl)-N-(3,5-dimethylphenyl)glycine, N-(carboxymethyl)-N-(2,4-dimethylphenyl)glycine, N-(carboxymethyl)-N-(2,6-dimethylphenyl)glycine, N-(carboxymethyl)-N-(4-formylphenyl)glycine, N-(carboxymethyl)-N-ethylanthranilic acid, N-(carboxymethyl)-N-propylanthranilic acid, 5-bromo-N-(carboxymethyl)anthranilic acid, N-(2-carboxyphenyl)glycine, o-dianisidine-N,N,N′,N′-tetraacetic acid, N,N′-[1,2-ethanediylbis(oxy-2,1-phenylene)]bis[N-(carboxymethyl)glycine], 4-carboxyphenoxy acetic acid, cathecol-O,O′-diacetic acid, 4-methylcatechol-O,O′-diacetic acid, resorcinol-O,O′-diacetic acid, hydroquinone-O,O′-diacetic acid, α-carboxy-o-anisic acid, 4,4′-isopropylidene diphenoxy acetic acid, 2,2′-(dibenzofuran-2,8-diyldioxy)diacetic acid, 2-(carboxymethylthio)benzoic acid, 5-amino-2-(carboxymethylthio)benzoic acid, and 3-[(carboxymethyl)thio]-2-naphthalene carboxylic acid.

In particular, N-arylpolycarboxylic acids represented by the following Formula (VI) or compounds represented by the following Formula (VII) are preferable.

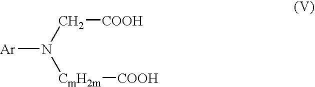

In Formula (V), Ar represents a monosubstituted, polysubstituted or unsubstituted aryl group, and m is an integer from 1 to 5.

Examples of a substituent which can be introduced into the aryl group include a C₁ to C₃ alkyl group, a C₁ to C₃ alkoxy group, a C₁ to C₃ thioalkyl group and a halogen atom. This aryl group preferably has 1 to 3 identical or different substituents. m is preferably 1, and Ar preferably represents a phenyl group.

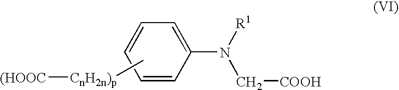

In Formula (VI), R¹ represents a hydrogen atom or a C₁ to C₆ alkyl group, and each of n and p is an integer from 1 to 5.

n is preferably 1, and R¹ is preferably a hydrogen atom. The most preferable polycarboxylic acid is anilinodiacetic acid.

Another compound preferable for improving sensitivity and/or developability is a compound having two or more groups selected from carboxylic acid groups and sulfonic acid groups, and specific examples thereof include 5-aminoisophthalic acid, 5-nitroisophthalic acid, 4-methylphthalic acid, terephthalic acid, 2-bromoterephthalic acid, 2,3-naphthalenedicarboxylic acid, diphenic acid, 1,4,5,8-naphthalenetetracarboxylic acid, N-benzyliminodiacetic acid, N-(2-carboxyphenylglycine), N-phenyliminodiacetic acid, 1,3,5-benzenetricarboxylic acid, 1,2,4,5-benzenetetracarboxylic acid, 5-sulfosalicylic acid, 2-sulfobenzoic acid, 1,5-naphthalenedisulfonic acid, and 4-sulfophthalic acid. The above compound can be further substituted by an alkyl group, an alkenyl group, an alkynyl group, a cyano group, a halogen atom, a hydroxyl group, a carboxyl group, a carbonyl group, an alkoxy group, an amino group, an amide group, a thiol group, a thioalkoxy group, or a sulfonyl group.

Among those described above, the most preferable compound is a compound represented by the Formula (V) or (VI).

The amount of such poly(carboxylic acid/sulfonic acid) compound to be added is preferably 0.5 to 15 mass %, more preferably 1 to 10 mass %, still more preferably 3 to 8 mass %, based on the solid content of the polymerizable composition.

A large number of more specific examples of these co-sensitizers are described, for example, in JP-A No. 9-236913 as additives for improving sensitivity, and such compounds can also be used in the invention.

Only one co-sensitizer, or a combination of two or more co-sensitizers, may be used. The amount of the co-sensitizer to be used may be in a range of 0.05 to 100 parts by mass, preferably 1 to 80 parts by mass, more preferably 3 to 50 parts by mass, relative to 100 parts by mass of the polymerizable compound (B).

(E-2) Polymerization Inhibitor

In the invention, in addition to the basic components described above, a small amount of a heat-polymerization inhibitor is preferably added so as to inhibit unnecessary heat polymerization of the polymerizable compound during production or storage of the composition used in the recording layer. Suitable examples of the heat-polymerization inhibitor include hydroquinone, p-methoxyphenol, di-t-butyl-p-cresol, pyrogallol, t-butyl catechol, benzoquinone, 4,4′-thiobis(3-methyl-6-t-butyl phenol), 2,2′-methylene bis(4-methyl-6-t-butyl phenol), and N-nitrosophenyl hydroxylamine primary cerium salts. The amount of the heat-polymerization inhibitor to be added is preferably about 0.01 mass % to about 5 mass % relative to the mass of the entire composition. To prevent the polymerization inhibition by oxygen, a higher fatty acid derivative such as behenic acid or behenic amide may be added as necessary so that the higher fatty acid derivative localizes on the surface of the recording layer in the drying process after application onto a support etc. during the production process of the planographic printing plate precursor. The amount of the higher fatty acid derivative to be added is preferably about 0.5 mass % to about 10 mass % based on the entire composition.

(E-3) Colorant etc.

A dye or pigment may be added to the planographic printing plate precursor according to the invention, for the purpose of coloring its recording layer. The plate-checking property of the printing plate, such as visibility after plate-making and compatibility with an image densitometer, can thereby be improved. The colorant is preferably a pigment since many dyes lower the sensitivity of the photopolymerizable recording layer. Examples of the colorant include pigments such as phthalocyanine pigments, azo pigments, carbon black and titanium oxide, and dyes such as Ethyl Violet, Crystal Violet, azo dyes, anthraquinone dyes and cyanine dyes. The amount of the dyes and pigments to be added is preferably about 0.5 mass % to about 5 mass % based on the entire composition.

<Microcapsule and Microgel>

In the invention, some aspects may be used for including the image recording layer constituents in the image recording layer. An aspect is a molecule dispersion type image recording layer as described in JP-A No. 2002-287334, which is formed by dissolving the constituents in an appropriate solvent and applying the solution. Another aspect is a microcapsule type image recording layer as described in, for example, JP-A No. 2001-277740, and JP-A No. 2001-277742, in which microcapsules containing all or some constituents are contained in the image recording layer. In the microcapsule type image recording layer, the constituents may be present outside the microcapsules. The microcapsule type image recording layer according to a preferable aspect is composed of a hydrophobic constituent contained in microcapsules, and a hydrophilic constituent outside the microcapsules. Another aspect is an image recording layer containing crosslinking resin particles, more specifically a microgel. The microgel may contain some constituents in the gel and/or on the surface of the gel. The microgel is particularly preferably a reactive microgel having a polymerizable compound on the surface thereof from the viewpoint of image formation sensitivity and printing durability. particularly preferable.

In order to achieve more favorable in-machine developability, the image recording layer is preferably a microcapsule type or microgel type image recording layer.

Known methods may be used for microencapsulation or microgelation of the image recording layer constituents.

Examples of the method for producing the microcapsules include, however not limited to, a method using coacervation as described in U.S. Pat. Nos. 280,0457, and 280,0458, a method using interfacial polymerization as described in U.S. Pat. No. 3,287,154, JP-B Nos. 38-19574, and 42-446, a method using polymer deposition as described in U.S. Pat. Nos. 3,418,250 and 3,660,304, a method using an isocyanate polyol wall material as described in U.S. Pat. No. 3,796,669, a method using an isocyanate wall material as described in U.S. Pat. No. 3,914,511, a method using a urea-formaldehyde-based or urea formaldehyde-resorcinol-based wall forming material as described in U.S. Pat. Nos. 4,001,140, 4,087,376, and 4,089,802, a method of using a wall material such as a melamine-formaldehyde resin or hydroxy cellulose as described in U.S. Pat. No. 4,025,445, a in situ method by monomer polymerization as described in JP-B Nos. 36-9163 and 51-9079, a spray drying method as described in U.K. Patent No. 930422 and U.S. Pat. No. 3,111,407, and an electrolysis dispersion cooling method as described in U.K. Patent Nos. 952807 and 967074.

The wall of microcapsules used in the invention preferably has a three-dimensional crosslink, and swells in a solvent. From these viewpoints, the wall material of the microcapsules is preferably polyurea, polyurethane, polyester, polycarbonate, polyamide, or a mixture thereof, and is particularly preferably polyurea or polyurethane. The microcapsule wall may contain a compound having a crosslinking functional group such as an ethylenically unsaturated bond which allows the introduction of a binder polymer.

Examples of the method for preparing a microgel include, however not limited to, granulation through interfacial polymerization as described in JP-B Nos. 38-19574 and 42-446, or granulation through nonaqueous dispersion polymerization as described in JP-A No. 5-61214.

The above-described known method for producing microcapsules is applicable to the method using interfacial polymerization.

The microgel preferably used in the invention is preferably prepared by granulation through interfacial polymerization and preferably has a three-dimensional crosslinking. From these viewpoints, the raw material or the microgel is preferably polyurea, polyurethane, polyester, polycarbonate, polyamide, or a mixture thereof, and particularly preferably polyurea or polyurethane.

The average particle diameter of the microcapsules and microgel is preferably from 0.01 to 3.0 μm, more preferably from 0.05 to 2.0 μm, and particularly preferably 0.10 to 1.0 μm. When the diameter is within the range, favorable resolution which is stable over time is achieved.

<Surfactant>

In the invention, the image recording layer preferably contains a surfactant for promoting the in-machine developability at the beginning of printing, and for improving the property of the coated surface. Examples of the surfactant include a nonionic surfactant, an anionic surfactant, a cationic surfactant, an amphoteric surfactant, a fluorine-based surfactant. These surfactants may be used alone or in combination of two or more of them.

The nonionic surfactant used in the image recording layer of the invention is not particularly limited, and may be a conventionally known nonionic surfactant. Examples thereof include polyoxyethylene alkyl ethers, polyoxyethylene alkyl phenyl ethers, polyoxyethylene polystyryl phenyl ethers, polyoxyethylene polyoxypropylene alkyl ethers, glycerin fatty acid partial esters, sorbitan fatty acid partial esters, pentaerythritol fatty acid partial esters, propylene glycol monofatty acid esters, sucrose fatty acid partial esters, polyoxyethylene sorbitan fatty acid partial esters, polyoxyethylene sorbitol fatty acid partial esters, polyethylene glycol fatty acid esters, polyglycerin fatty acid partial esters, polyoxyethylene castor oils, polyoxyethylene glycerin fatty acid partial esters, fatty acid diethanol amides, N,N-bis-2-hydroxyalkyl amines, polyoxyethylene alkyl amine, triethanol amine fatty acid esters, trialkyl amine oxides, polyethylene glycol, and polyethylene glycol-polypropylene glycol copolymers.

The anionic surfactant used in the invention is not particularly limited, and may be a conventionally known anionic surfactant. Examples thereof include fatty acid salts, abietates, hydroxyalkane sulfonates, alkane sulfonates, dialkylsulfosuccinic ester salts, linear alkyl benzene sulfonates, branched alkyl benzene sulfonates, alkyl naphthalene sulfonates, alkyl phenoxy polyoxyethylene propyl sulfonates, polyoxyethylene alkyl sulfophenyl ether salts, N-methyl-N-oleyl taurine sodium salt, N-alkyl sulfosuccinic monoamide disodium salt, petroleum sulfonates, sulfated tallow oil, sulfuric ester salts of alkyl esters of fatty acids, alkyl sulfuric ester salts, polyoxyethylene alkyl ether sulfuric ester salts, fatty acid monoglyceride sulfuric ester salts, polyoxyethylene alkyl phenyl ether sulfuric ester salts, polyoxyethylene styryl phenyl ether sulfuric ester salts, alkyl phosphoric ester salts, polyoxyethylene alkyl ether phosphoric ester salts, polyoxyethylene alkyl phenyl ether phosphoric ester salts, partially saponified styrene-maleic anhydride copolymers, partially saponified olefin-maleic anhydride copolymers and naphthalene sulfonate formalin condensates.

The cationic surfactant used in the invention is not particularly limited, and may be a conventionally known cationic surfactant. Examples thereof include alkyl amine salts, quaternary ammonium salts, polyoxyethylene alkyl amine salts and polyethylene polyamine derivatives.

The amphoteric surfactant used in the invention is not particularly limited, and may be a conventionally known amphoteric surfactant. Examples thereof include carboxy betaines, aminocarboxylic acids, sulfobetaines, aminosulfates and imidazolines.

Examples of the surfactant further includes the surfactants obtained by replacing the polyoxyethylene in the above surfactants by a polyoxyalkylene such as a polyoxymethylene, a polyoxypropylene, or a polyoxybutylene.

Fluorine-based surfactants containing perfluoroalkyl groups are further preferable. Examples of the fluorine-based surfactants include: anionic surfactants such as perfluoroalkyl carboxylates, perfluoroalkyl sulfonates and perfluoroalkyl phosphates; amphoteric surfactants such as perfluoroalkyl betaine; cationic surfactants such as perfluoroalkyl trimethyl ammonium salts; and nonionic surfactants such as perfluoroalkyl amine oxides, perfluoroalkyl ethylene oxide adducts, oligomers each having a perfluoroalkyl group and a hydrophilic group, oligomers each having a perfluoroalkyl group and a lipophilic group, oligomers each having a perfluoroalkyl group, a hydrophilic group, and a lipophilic group, and urethanes each having a perfluoroalkyl group and a lipophilic group. The fluorine-based surfactants described in JP-A Nos. 62-170950, 62-226143 and 60-168144 are also preferable.

Only a single surfactant may be used or two or more surfactants may be used.

The content of the surfactant is preferably 0.001 to 10% by mass, more preferably 0.01 to 5% by mass, based on the total solid content of the image recoding layer.

[Other Additives]

<Printing-Out Agent>

A compound whose color can be changed by an acid or by a radical may be added to the image recording layer in order to form a printout image. Such a compound may be, for example, a colorant such as a diphenyl methane colorant, a triphenyl methane colorant, a thiazine colorant, an oxazine colorant, a xanthene colorant, an anthraquinone colorant, an iminoquinone colorant, an azo colorant, or an azomethine colorant.

Specific examples thereof include dyes such as Brilliant Green, Ethyl Violet, Methyl Green; Crystal Violet, Basic Fuchsin, Methyl Violet 2B, Quinaldine Red, Rose Bengal, Metanil Yellow, Thymol Sulfophthalein, Xylenol Blue, Methyl Orange, Paramethyl Red, Congo Red, Benzopurprin 4B, α-Naphthyl Red, Nile Blue 2B, Nile Blue A, Methyl Violet, Malachite Green, Parafuchsin, Victoria Pure Blue BOH (manufactured by Hodogaya Kagaku Co., Ltd.), Oil Blue #603 (manufactured by Orient Chemical Industries, Ltd.), Oil Pink #312 (manufactured by Orient Chemical Industries, Ltd.), Oil Red 5B (manufactured by Orient Chemical Industries, Ltd.), Oil Scarlet #308 (manufactured by Orient Chemical Industries, Ltd.), Oil Red OG (manufactured by Orient Chemical Industries, Ltd.), Oil Red RR (manufactured by Orient Chemical Industries, Ltd.), Oil Green #502 (manufactured by Orient Chemical Industries, Ltd.), Spirone Red BEH Special (manufactured by Hodogaya Kagaku Co., Ltd.), m-Cresol Purple, Cresol Red, Rhodamine B, Rhodamine 6G, Sulforhodamine B, Auramine, 4-p-diethylaminophenyl iminonaphthoquinone, 2-carboxyanilino-4-p-diethylaminophenyl iminonaphthoquinone, 2-carboxystearylamino-4-p-N,N-bis(hydroxyethyl)amino-phenyliminonaphthoquinone, 1-phenyl-3-methyl-4-p-diethylaminophenylimino-5-pyrazolone and 1-β-naphthyl-4-p-diethylaminophenylimino-5-pyrazolone, and leuco dyes such as p,p′,p″-hexamethyl triaminophenyl methane (Leuco Crystal Violet) and Pergascript Blue SRB (manufactured by Ciba-Geigy).

In addition to those described above, preferable examples of the printout agent further include leuco dyes known as materials for thermal sensitive paper and pressure sensitive paper. Specific examples thereof include crystal violet lactone, malachite green lactone, benzoyl leucomethylene blue, 2-(N-phenyl-N-methylamino)-6-(N-p-tolyl-N-ethyl)amino-fluoran, 2-anilino-3-methyl-6-(N-ethyl-p-toluidino)fluoran, 3,6-dimethoxy fluoran, 3-(N,N-diethylamino)-5-methyl-7-(N,N-dibenzylamino)-fluoran, 3-(N-cyclohexyl-N-methylamino)-6-methyl-7-anilinofluoran, 3-(N,N-diethylamino)-6-methyl-7-anilinofluoran, 3-(N,N-diethylamino)-6-methyl-7-xylidinofluoran, 3-(N,N-diethylamino)-6-methyl-7-chlorofluoran, 3-(N,N-diethylamino)-6-methoxy-7-aminofluoran, 3-(N,N-diethylamino)-7-(4-chloroanilino) fluoran, 3-(N,N-diethylamino)-7-chlorofluoran, 3-(N,N-diethylamino)-7-benzyl aminofluoran, 3-(N,N-diethylamino)-7,8-benzofluoran, 3-(N,N-dibutylamino)-6-methyl-7-anilinofluoran, 3-(N,N-dibutylamino)-6-methyl-7-xylidinofluoran, 3-piperidino-6-methyl-7-anilinofluoran, 3-pyrrolidino-6-methyl-7-anilinofluoran, 3,3-bis(1-ethyl-2-methylindol-3-yl)phthalide, 3,3-bis(1-n-butyl-2-methylindol-3-yl)phthalide, 3,3-bis(p-dimethylaminophenyl)-6-dimethyl amino phthalide, 3-(4-diethylamino-2-ethoxyphenyl)-3-(1-ethyl-2-methylindol-3-yl)-4-phthalide, and 3-(4-diethylaminophenyl)-3-(1-ethyl-2-methylindol-3-yl)phthalide.

The amount of the dye whose color is changed by an acid or by a radical is from 0.01 to 10% by mass based on the total solid content in the hydrophilic film.

(Borate Compound)

In the invention, a borate compound may be used for improving the color development property of the light-exposed portion. The borate compound may be freely selected from compounds having a borate anion structure, and is preferably a borate compound having the following structure.

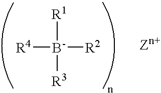

In the Formula, R¹ to R⁴ each independently represent a monovalent organic group, and Zⁿ⁺ represents an n-valent cation. n denotes an integer of 1 to 6.

Examples of the monovalent organic group represented by R¹ to R⁴ include an alkyl group, an alkenyl group, an aryl group, an alkynyl group, and a cycloalkyl group, which may be substituted by an alkyl group, an alkenyl group, an alkynyl group, an aryl group, a halogen atom, an alkoxy group, an alkoxycarbonyl group, an amino group, a cyano group, an amide group, an urethane group, a sulfo group, a thioalkoxy group, or a carboxyl group.

R¹ to R⁴ preferably each independently represent an aryl group, and are more preferably an aryl group having an electron-withdrawing group. The electron-withdrawing group is preferably a halogen atom or a fluoroalkyl group, and most preferably a fluorine atom or a trifluoromethyl group.

Zⁿ⁺ may be freely selected from cations, and is preferably an alkali metal ion, an alkaline earth metal ion, or an onium salt such as a sulfonium salt, an iodonium salt, an azinium salt, an ammonium salt, a phosphonium salt, or a diazonium salt.

(Polymerization Inhibitor)

To prevent unnecessary heat polymerization of the radical polymerizable compound (C), the image recording layer of the invention preferably contains a small amount of heat polymerization inhibitor, which is added during making or storage of the image recording layer.

Preferable examples of the heat polymerization inhibitor include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), and aluminum N-nitroso-N-phenylhydroxylamine. The addition amount of the heat polymerization inhibitor is preferably about 0.01 to about 5% by mass with respect to the total solid content in the image recording layer.

(Higher Fatty Acid Derivative)

To prevent polymerization inhibition by oxygen, the image recording layer of the invention may contain a higher fatty acid derivative such as behenic acid or behenic acid amide, which is localized on the surface of the image recording layer during the drying process after applying the layer. The addition amount of the higher fatty acid derivative is preferably about 0.1 to about 10% by mass with respect to the total solid content in the image recording layer.

(Plasticizing Agent)

The image recording layer of the invention may contain a plasticizing agent for improving the in-machine developability. Preferable examples of the plasticizing agent include phthalate esters such as dimethyl phthalate, diethyl phthalate, dibutyl phthalate, diisobutyl phthalate, dioctyl phthalate, octylcapryl phthalate, dicyclohexyl phthalate, ditridecyl phthalate, butylbenzyl phthalate, diisodecyl phthalate, and diallyl phthalate; glycolates such as dimethylglycol phthalate, ethylphthalylethyl glycolate, methylphthalylethyl glycolate, butylphthalylbutyl glycolate, and triethyleneglycoldicaprylic acid ester; phosphates such as tricresyl phosphate and triphenylphosphate; aliphatic dibasic acid esters such as diisobutyl adipate, dioctyl adipate, dimethyl sebacate, dibutyl sebacate, dioctyl azelate, and dibutyl maleate; and polyglycidyl methacrylate, triethyl citrate, glyceroltriacetyl ester, and butyl laurate. The content of the plasticizing agent is preferably about 30% by mass or lower with respect to the total solid content in the image recording layer.

<Inorganic Fine Particles>

In the invention, the image recording layer may further include inorganic fine particles in order to improve the strength of the cured film, hydrophilicity and water holding property of the hydrophilic film.

Examples of the inorganic fine particles include, for example, silica, alumina, magnesium oxide, titanium oxide, magnesium carbonate, calcium alginate and mixtures thereof. Even if an inorganic fine particle cannot convert light to heat, the inorganic fine particle may be used for reinforcement of the coating film and improvement of the interfacial adhesiveness by surface roughening.

The average particle size of the inorganic fine particle is preferably 5 nm to 10 μm, more preferably 0.5 μm to 3 μm. When the average particle diameter is in the above range, the inorganic fine particles can be dispersed stably in the image recording layer, whereby excellent film strength of the image recording layer is obtained and a highly hydrophilic non-image area which is hardly blemished during printing is obtained.

The inorganic fine particles described above are easily available as commercially available products such as colloidal silica dispersions.

The content of the inorganic fine particles is preferably 20% by mass or lower, more preferably 10% by mass or lower, based on the total solid content of the image recording layer.

(Low Molecular Hydrophilic Compound)

The image recording layer of the invention may contain a low molecule weight compound for improving the in-machine developability. Examples of the hydrophilic low molecular weight compound include water-soluble organic compounds such as glycols and ether or ester derivatives thereof such as ethylene glycol, diethylene glycol, triethylene glycol, propylene glycol, dipropylene glycol, and tripropylene glycol, polyhydroxys such as glycerol and pentaerythritol, organic amines and salts thereof such as triethanolamine, diethanolamine, and monoethanolamine, organic sulfonic acids and salts thereof such as toluenesulfonic acid and benzenesulfonic acid, organic phosphonic acids and salts thereof such as phenylphosphonic acid, and organic carboxylic acids and salts thereof such as tartaric acid, oxalic acid, citric acid, malic acid, lactic acid, gluconic acid, and amino acids.

(E-4) Other Additives

The planographic printing plate precursor of the invention may further contain other known additives such as an inorganic filler in order to improve the physical property of the cured film, a plasticizer, and an oil-sensitizing agent for improving the ink settlement on the surface of the recording layer.

Examples of the plasticizer include dioctyl phthalate, didodecyl phthalate, triethyleneglycol dicaprylate, dimethylglycol phthalate, tricresyl phosphate, dioxtyl adipate, dibutyl sebacate, and triacetylglycerol. In the case where a binder is used, the plasticizer may be added in an amount of 10% by mass or lower with respect to the total mass of a compound having an ethylenically unsaturated bond and the binder.

Further, the below-described additives such as a UV initiator and a heat crosslinking agent may be added for enhancing the effect of heating and light exposure after development to improve the film strength (printing durability).

In addition, other additives or an intermediate layer may be used to improve the adhesiveness between the recording layer and support, and enhance the development removability of the light-unexposed recording layer. For example, the adhesiveness and printing durability can be improved by adding or undercoating with a compound which relatively strongly interacts with a substrate, such as a compound having a diazonium structure or a phosphonate compound, and the developability in the non-image region and stain resistance can be improved by adding or undercoating with a hydrophilic polymer such as polyacrylic acid or polysulfone acid.

The planographic printing plate precursor is produced by dissolving coating solution components for forming intended layers such as a recording layer and a protective layer in appropriate solvents, and applying the coating solutions on an appropriate support.

Examples of the solvent to be used include acetone, methylethylketone, cyclohexane, ethylacetate, ethylene dichloride, tetrahydrofuran, toluene, ethylene glycol monomethylether, ethylene glycol monoethylether, ethylene glycol dimethylether, propylene glycol monomethylether, propylene glycol monoethylether, acetylacetone, cyclohexanone, diacetone alcohol, ethylene glycol monomethylether acetate, ethylene glycol ethylether acetate, ethylene glycol monoisopropylether, ethylene glycol monobutylether acetate, 3-methoxypropanol, methoxymethoxyethanol, diethylene glycol monomethylether, diethylene glycol monoethylether, diethylene glycol dimethylether, diethylene glycol diethylether, propylene glycol monomethylether acetate, propylene glycol monoethylether acetate, 3-methoxypropyl acetate, N,N-dimethylformamide, dimethylsulfoxide, γ-butyrolactone, methyl lactate, and ethyl lactate. These solvents may be used alone or as a mixture. The concentration of the solid content in a coating solution is preferably from 2 to 50% by mass.

It is preferable that the coating amount of the recording layer on the support be selected as appropriate according to the intended use in consideration of the sensitivity and developability of the recording layer, strength of the light-exposed film, printing durability, and other influences. If the coating amount is too small, the printing durability is insufficient, and if excessive, the sensitivity decreases, which results in prolongation of the time necessary for light exposure and developing treatment. The coating amount on the planographic printing plate precursor of the invention is preferably in a range of from about 0.1 to about 10 g/m², and more preferably from 0.5 to 5 g/m² at a mass after drying.

(Resin Intermediate Layer)

In the planographic printing plate precursor according to the invention, a resin intermediate layer including an alkali-soluble polymer can be arranged as necessary between the recording layer and the support.

When the recording layer that is an infrared light-sensitive layer whose solubility in an alkali developer is decreased upon exposure to light is disposed as a light exposure surface or in the vicinity thereof, the sensitivity to an infrared laser light is improved. Further, the resin intermediate layer between the support and the infrared light-sensitive recording layer acts as a heat insulating layer, thereby preventing heat generated upon exposure to infrared laser light from diffusing in the support. Therefore, the heat is used effectively, and the sensitivity can be heightened.

It is estimated that in a light-exposed portion, the photosensitive layer (recording layer) made impermeable to an alkali developer functions as a protective layer for the resin intermediate layer, thus improving development stability, forming an image excellent in discrimination and securing stability with time, while in a light-unexposed portion, an unhardened binder component is rapidly dissolved and dispersed in a developer. Since the resin intermediate layer provided adjacent to the support is made of an alkali-soluble polymer, the resin intermediate layer is excellent in solubility in a developer, and is rapidly dissolved to attain excellent developability without generating a remaining layer even if, for example, a developer having lowered activity is used.

<Substrate (Support)>

The support used in the invention may be paper, a polyester film or an aluminum plate, among which an aluminum plate is particularly preferable because it is excellent in dimensional stability, is relatively inexpensive, can provide a surface excellent in hydrophilicity and strength by performing surface treatment as necessary. A composite sheet having an aluminum sheet bonded to a polyethylene terephthalate film, as described in JP-B No. 48-18327, is also preferable.

The aluminum plate as used herein is a dimensionally stable metal plate including aluminum as a major component, and the scope of the aluminum plate includes not only a pure aluminum plate but also an alloy plate including aluminum as a major component and a very small amount of hetero elements, and a plastic film or paper having aluminum (alloy) laminated or vapor-deposited thereon. In the following description, supports made of aluminum or aluminum alloys are referred to collectively as aluminum supports. Examples of the hetero elements contained in the aluminum alloy include silicon, iron, manganese, copper, magnesium, chromium, zinc, bismuth, nickel, and titanium. The content of the hetero elements in the alloy is 10 mass % or less. A pure aluminum plate is particularly preferable, but because production of completely pure aluminum is difficult from the viewpoint of refining techniques, aluminum may contain a very small amount of hetero elements. The composition of the aluminum plate is not limited, and any aluminum plates made of known and conventionally used aluminum materials such as JIS A 1050, JIS A 1100, JIS A 3103 and JIS A 3005 can be used as necessary.

The thickness of the aluminum support is from about 0.1 to about 0.6 mm. This thickness can be suitably changed depending on the size of a printing machine, the size of a printing plate, and user's requests.

The aluminum support may be subjected to the following surface treatment to make it hydrophilic.

(Surface Roughening Treatment)

Examples of the surface roughening treatment include mechanical roughening, chemical etching and electrolytic grain as disclosed in JP-A No. 56-28893. Other examples include an electrochemical surface roughening method of electrochemically roughening the surface in a hydrochloric acid or nitric acid electrolytic solution, and mechanical surface roughening methods such as a wire brush grain method of scratching an aluminum surface with a metallic wire, a pole grain method of graining an aluminum surface with abrasive grains and an abrasive, or a brush grain method of roughening the surface with a nylon brush and an abrasive. Only one of these surface roughening methods may be used, or a combination of two or more of these surface roughening methods may be used. Among these methods, the electrochemical method of roughening the surface chemically in a hydrochloric acid or nitric acid electrolytic solution is particularly useful in surface roughening. The anode time electricity is preferably in a range of 50 to 400 C/dm². Specifically, it is preferable to conduct alternating current and/or direct current electrolysis at a temperature of 20 to 80° C., for 1 second to 30 minutes with a current density of 100 to 400 C/dm² in an electrolytic solution containing 0.1 to 50% hydrochloric acid or nitric acid.

The aluminum support thus surface-roughened may be etched chemically with acid or alkali. Preferable examples of the etching agent to be used include sodium hydroxide, sodium carbonate, sodium aluminate, sodium metasilicate, sodium phosphate, potassium hydroxide, lithium hydroxide etc., and the concentration and temperature are preferably in a range of from 1 to 50% and from 20 to 100° C., respectively. After etching, washing with acid may be carried out to remove blemish (smuts) remaining on the surface. Examples of the acid to be used include nitric acid, sulfuric acid, phosphoric acid, chromic acid, fluoric acid and hydrofluoboric acid. The method of removing smuts after electrochemical surface roughening treatment is preferably a method of contacting with from 15 to 65% by mass sulfuric acid at a temperature of from 50 to 90° C. as described in JP-A No. 53-12739 or a method of alkali etching as described in JP-B No. 48-28123. The method and conditions are not particularly limited as long as the surface roughness Ra of the treated surface is about 0.2 to 0.5 μm after the treatment.

(Anodizing Treatment)

The thus treated aluminum support having an oxide layer formed thereon is then subjected to anodizing treatment.

In the anodizing treatment, an aqueous solution of sulfuric acid, phosphoric acid, oxalic acid or boric acid-sodium borate, or an aqueous solution of a combination of two or more of such substances, can be used as the major component in an electrolytic bath. In this case, the electrolytic solution may naturally contain at least components usually contained in the Al alloy plate, the electrodes, tap water and underground water. Second and third components may also be contained. The range of the second and third components include, for example, cations of metals such as Na, K, Mg, Li, Ca, Ti, Al, V, Cr, Mn, Fe, Co, Ni, Cu and Zn, ammonium ions, and anions such as nitrate ion, carbonate ion, chlorine ion, phosphate ion, fluorine ion, sulfite ion, titanate ion, silicate ion and borate ion, and the concentration thereof may be from about 0 to 10000 ppm. Although the conditions for the anodizing treatment are not particularly limited, the plate is preferably treated with 30 to 500 g/L solution at a temperature of 10 to 70° C. by direct current or alternating current electrolysis in a range of a current density of 0.1 to 40 A/m². The thickness of the anodized layer formed may be in a range of 0.5 to 1.5 μm. Preferably, the thickness is in a range of 0.5 to 1.0 μm. The treatment conditions are preferably selected such that the pore diameter of micropores present in the anodized layer formed on the support by the treatment described above is 5 to 10 nm and such that the pore density is 8×10¹⁵ to 2×10¹⁶ pores/m².

The treatment for imparting hydrophilicity to the surface of the support may be selected from various known methods. The treatment is particularly preferably hydrophilicity-imparting treatment with a silicate, polyvinylphosphonic acid, or the like. The obtained layer may have a Si or P element content of 2 to 40 mg/m², preferably 4 to 30 mg/m². The coating amount can be measured by fluorescence X ray analysis.

In the hydrophilicity-imparting treatment, the aluminum support having an anodized layer formed thereon is dipped in an aqueous solution at pH 10 to 13 (determined at 25° C.) containing an alkali metal silicate or polyvinylphosphonic acid in an amount of 1 to 30 mass %, more preferably 2 to 15 mass %, for example at 15 to 80° C. for 0.5 to 120 seconds.

As the alkali metal silicate used in the treatment for imparting hydrophilicity, sodium silicate, potassium silicate, lithium silicate, or the like is used. The hydroxide used for raising the pH value of the aqueous alkali metal silicate solution may be sodium hydroxide, potassium hydroxide, lithium hydroxide, or the like. Alkaline earth metal salts or the group IVB metal salts may be incorporated into the treating solution described above. Examples of the alkaline earth metal salts include nitrates such as calcium nitrate, strontium nitrate, magnesium nitrate and barium nitrate, and water-soluble salts such as sulfate, hydrochloride, phosphate, acetate, oxalate and borate. Examples of the group IVB metal salts include titanium tetrachloride, titanium trichloride, titanium potassium fluoride, titanium potassium oxalate, titanium sulfate, titanium tetraiodide, zirconium chloride oxide, zirconium dioxide, zirconium oxychloride, and zirconium tetrachloride.

In an embodiment, only one selected from alkaline earth metal salts and group IVB metal salts is used. In another embodiment, a combination of two or more selected from alkaline earth metal salts and group IVB metal salts is used. The amount of these metal salts is preferably in a range of from 0.01 to 10% by mass, more preferably from 0.05 to 5.0% by mass. Electrodeposition with silicate as described in U.S. Pat. No. 3,658,662 is also effective. A surface treatment which is a combination of a support which has been subjected to electrolytic graining as disclosed in JP-B No. 46-27481, JP-A No. 52-58602 and JP-A No. 52-30503, and the anodizing treatment and the hydrophilicity-imparting treatment described above, is also useful.

[Production of the Planographic Printing Plate Precursor]

The planographic printing plate precursor according to the invention may have the recording layer and the specific protective layer described above on this order on a support and may be provided if necessary with an intermediate layer (undercoat layer) etc. Such a planographic printing plate precursor can be produced by applying coating liquids containing the respective components sequentially onto a support.

When the recording layer is formed by coating, the recording layer components are dissolved in an organic solvent, which may be selected from various organic solvents, to form a recording layer coating liquid. The recording layer coating liquid is then applied onto the support or the undercoat layer.

Examples of the solvent to be used for the recording layer coating liquid include acetone, methyl ethyl ketone, cyclohexane, ethyl acetate, ethylene dichloride, tetrahydrofuran, toluene, ethylene glycol monomethyl ether, ethylene glycol monoethyl ether, ethylene glycol dimethyl ether, propylene glycol monomethyl ether, propylene glycol monoethyl ether, acetyl acetone, cyclohexanone, diacetone alcohol, ethylene glycol monomethyl ether acetate, ethylene glycol ethyl ether acetate, ethylene glycol monoisopropyl ether, ethylene glycol monobutyl ether acetate, 3-methoxy propanol, methoxy methoxy ethanol, diethylene glycol monomethyl ether, diethylene glycol monoethyl ether, diethylene glycol dimethyl ether, diethylene glycol diethyl ether, propylene glycol monomethyl ether acetate, propylene glycol monoethyl ether acetate, 3-methoxy propyl acetate, N,N-dimethyl formamide, dimethyl sulfoxide, γ-butyrolactone, methyl lactate and ethyl lactate. The solvent to be used may include only one of these solvents or a mixture of two or more of these solvents. A suitable solids content of the recording layer coating liquid is from 2 to 50 mass %.

The coating amount of the recording layer can mainly influence the sensitivity of the recording layer, the strength of the light-exposed layer, developability, and the printing durability of the resultant printing plate, and is desirably selected in accordance with the application. In the case of the planographic printing plate precursor for scanning exposure, the coating amount in terms of the mass of the recording layer after drying is preferably in a range of from about 0.1 g/m² to about 10 g/m², more preferably from 0.5 to 5 g/m².

[Intermediate Layer (Undercoat Layer)]

For the purpose of improving the adhesiveness between the recording layer and the support and stain resistance, the planographic printing plate precursor may have an intermediate layer (undercoat layer). Specific examples of the intermediate layer include those described in JP-B No. 50-7481, JP-A No. 54-72104, JP-A No. 59-101651, JP-A No. 60-149491, JP-A No. 60-232998, JP-A 3-56177, JP-A No. 4-282637, JP-A No. 5-16558, JP-A No. 5-246171, JP-A No. 7-159983, JP-A No. 7-314937, JP-A No. 8-202025, JP-A No. 8-320551, JP-A No. 9-34104, JP-A No. 9-236911, JP-A No. 9-269593, JP-A No. 10-69092, JP-A No. 10-115931, JP-A No. 10-161317, JP-A No. 10-260536, JP-A No. 10-282682, JP-A No. 11-84674, JP-A No. 10-69092, JP-A No. 10-115931, JP-A No. 11-38635, JP-A No. 11-38629, JP-A No. 10-282645, JP-A No. 10-301262, JP-A No. 11-24277, JP-A No. 11-109641, JP-A No. 10-319600, JP-A No. 11-84674, JP-A No. 11-327152, JP-A No. 2000-10292, JP-A No. 2000-235254, JP-A No. 2000-352854, JP-A No. 2001-209170, JP-A No. 2001-175001 etc.

<Plate-Making Method>

Hereinafter, the method of making a plate from the planographic printing plate precursor according to the invention will be described.

In an embodiment of the method of making a plate from the planographic printing plate precursor, a plurality of the planographic printing plate precursors described above are stacked such that the protective layer directly contacts with the back surface of the support; the stack of the planographic printing plate precursors is then set in a plate setter and the planographic printing plate precursors are automatically conveyed one by one; each precursor is imagewise exposed to light having a wavelengths of 750 to 1400 nm; and then the precursor is developed to remove the non-image portion so that the plate-making process is completed. Even when the planographic printing plate precursors according to the invention are stacked without inserting interleaf paper between the precursors, the adhesion between the planographic printing plate precursors and flaws on the protective layer can be suppressed, and therefore, the planographic printing plate precursor can be applied to the plate-making method described above. According to this plate-making method, since the stack of the planographic printing plate precursors in which the precursors are stacked without using interleaf paper between the precursors is used, the process of removing interleaf paper is unnecessary, and thus the productivity in the plate-making process is improved.

As a matter of course, plate-making can be conducted using a stack in which the planographic printing plate precursors according to the invention and sheets of interleaf paper are stacked alternately.

[Light Exposure]

The method for light-exposing the planographic printing plate precursor composed of the image recording material of the invention may be freely selected from known methods.

The light source for light-exposing the image recording layer of the image recording material of the invention may be freely selected from known ones. Light sources having a wavelength of from 300 nm to 1200 nm may be used. Specifically various lasers may be used as the light source, and in particular a semiconductor laser emitting infrared rays having a wavelength of from 760 nm to 1200 nm is useful.

The light source is preferably a laser, and examples available laser beam sources having a wavelength of from 350 nm to 450 nm include the followings: gas lasers such as an Ar ion laser (364 nm, 351 nm, 10 mW to 1 W), a Kr ion laser (356 nm, 351 nm, 10 mW to 1 W), a He—Cd laser (441 nm, 325 nm, 1 mW to 100 mW); solid lasers such as a combination of Nd:YAG (YVO₄) and SHG crystal×2 (355 nm, 5 mW to 1 W), and a combination of Cr:LiSAF and SHG crystal (430 nm, 10 mW); semiconductor lasers such as a KnbO₃ ring resonator (430 nm, 30 mW), a combination of a waveguide type wavelength converting element and AlGaAs and InGaAs semiconductors (380 nm to 450 nm, 5 mW to 100 mW), a combination of a waveguide type wavelength converting element and AlGaInP and AlGaAs semiconductors (300 nm to 350 nm, 5 mW to 100 mW) and AlGaInN (350 nm to 450 nm, 5 mW to 30 mW); and pulse lasers such as a N₂ laser (337 nm, pulse 0.1 to 10 mJ), and a XeF laser (351 nm, pulse 10 to 250 mJ).

Among them, particularly an AlGaInN semiconductor laser (commercially available InGaN semiconductor laser from 400 to 410 nm, 5 to 30 mW) is preferable from the viewpoints of wavelength property and cost.

Other examples of available light sources having a wavelength of 450 nm to 700 nm include an Ar⁺ laser (488 nm), YAG-SHG laser (532 nm), a He—Ne laser (633 nm), a He—Cd laser, a red semiconductor laser (650 to 690 nm), and preferable examples of available light sources having a wavelength of 700 nm to 1200 nm include a semiconductor laser (800 to 850 nm), and a Nd-YAG laser (1064 nm).

Other examples of useful light sources include mercury lamps of ultrahigh pressure, high pressure, middle pressure, or low pressure, chemical lamps, carbon arc lamp, xenon lamps, metal halide lamps, ultraviolet laser lamps (e.g. an ArF excimer laser, a KrF excimer laser), various visible laser lamps, fluorescent lamps, tungsten lamps, solar light, and radiations such as electron beams, X rays, ion beams, and far infrared rays.

Among them, the light source of the rays used for the imagewise exposure of the image recording material according to the invention is preferably a light source having a luminescence wavelength in the near-infrared region to infrared region, and is particularly preferably a solid laser or a semiconductor laser.

The light exposure device may be any of internal drum system, external drum system, and flatbed system.

In particular, in the case where a light source having a wavelength of from 750 nm to 1400 nm is used for light exposure, the light source may be freely selected from those emitting rays having the wavelength. However, the imagewise exposure is preferably conducted by a solid laser or a semiconductor laser emitting infrared rays having a wavelength of from 750 nm to 1400 nm.

The laser preferably has an output of 100 mW or more, and preferably includes a multi-beam laser device for reducing the light exposure time. The light exposure time for one pixel is preferably 20μ seconds or shorter. The amount of radiation energy radiated per unit area of the planographic printing plate precursor is preferably from 10 to 300 mJ/cm².

The light exposure can be carried out by overlapping beams from a light source. The term “overlapping” means that exposure is conducted under such a condition that the sub-scanning pitch is smaller than the beam diameter. For example, when the beam diameter is expressed in terms of full-width at half-maximum (FWHM) of the beam intensity, overlapping can be quantitatively expressed in FWHM/sub-scanning pitch (overlapping coefficient). In the invention, the overlapping coefficient is preferably 0.1 or more.

The scanning system for a light source in the light exposure device is not particularly limited, and a drum outer surface scanning method, a drum inner surface scanning method, a flatbed scanning method, or the like can be used. The channel of the light source may be a single channel or a multi-channel, but in the case of the drum outer surface scanning method, a multi-channel is preferably used.

In plate-making, the planographic printing plate precursor according to the invention can be subjected to development treatment without carrying out special thermal treatment and/or water washing treatment usually conducted after exposure treatment. Because the thermal treatment is not carried out, image unevenness attributable to the thermal treatment can be prevented. Because the thermal treatment and/or water washing treatment is not carried out, stable high-speed treatment is possible in development treatment.

[Development]

The developer used for the developing treatment conducted after the light exposure treatment is further described below.

<Developer>

The developer used in the invention is not particularly limited, and is usually an aqueous alkali solution containing an alkaline chemical and having a pH of 14 or lower, preferably a pH from 9.0 to 13.0.

(Alkali Agent)

Examples of the alkali agent used in the developer include inorganic alkali agents such as tertiary sodium phosphate, tertiary potassium phosphate, tertiary ammonium phosphate, sodium borate, potassium borate, ammonium borate, sodium hydroxide, potassium hydroxide, ammonium hydroxide and lithium hydroxide, and organic alkali agents such as monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethylene imine, ethylene diamine, pyridine and tetramethyl ammonium hydroxide. Only one alkali agent may be used, or a combination of two or more alkali agents may be used.

Alkali agents other than those described above include alkali silicates. Alkali silicates may used in combination with a base. The alkali silicates to be used may be those showing alkalinity when dissolved in water, and examples thereof include sodium silicate, potassium silicate, lithium silicate and ammonium silicate. In an embodiment, only one alkali silicate is used. In another embodiment, a mixture of two or more alkali silicates is used.

When a silicate is used, the characteristics of the developer can be adjusted easily to the optimum range by controlling the mixing ratio and concentration of silicon oxide SiO₂ as silicate component and alkali oxide M₂O (M is an alkali metal or an ammonium group) as alkali component. From the viewpoint of suppressing blemish attributable to excess dissolution (etching) of the anodized film on a support and inhibiting generation of insoluble gas attributable to formation of a complex of dissolved aluminum and a silicate, the mixing ratio of silicon oxide SiO₂ to alkali metal oxide M₂O (SiO₂/M₂O molar ratio) is preferably in a range of from 0.75 to 4.0, more preferably in a range of from 0.75 to 3.5.

Regarding the concentration of the alkali silicate salt in the developer, the amount of SiO₂ relative to the mass of the developer is preferably in a range of from 0.01 to 1 mol/L, more preferably from 0.05 to 0.8 mol/L from the viewpoint of inhibitory effects on dissolution (etching) of the anodized film on a support, developability, inhibitory effects on precipitation and crystallization, and inhibitory effects on gelling upon neutralization at the time of waste liquid treatment.

(Aromatic Anionic Surfactant)

The developer preferably contains an aromatic anionic surfactant from the viewpoint of the development accelerating effect, stabilization of a dispersion of the negative-working polymerizable recording layer components and protective layer components in the developer, and stabilization of development treatment.

The aromatic anionic surfactant is not particularly limited, but is preferably a compound represented by the following Formula (A) or (B):

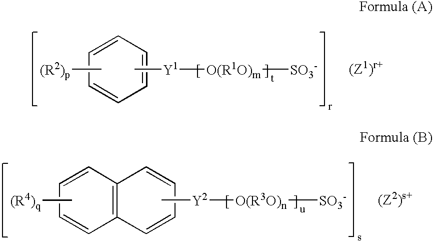

In the Formula (A) or (B) above, R¹ and R³ each independently represent a linear or branched C₁ to C₅ alkylene group, and specific examples include an ethylene group, a propylene group, a butylene group and a pentylene group, among which an ethylene group and a propylene group are particularly preferable.

m and d each independently represent an integer from 1 to 100, and is preferably from 1 to 30, more preferably from 2 to 20. When m is 2 or greater, there are plural R¹s which may be the same as or different from each other. When n is 2 or greater, there are plural R³s which may be the same as or different from each other.

t and u each independently represent 0 or 1.

R² and R⁴ each independently represent a linear or branched C₁ to C₂₀ alkyl group, and specific examples include a methyl group, an ethyl group, a propyl group, a butyl group, a hexyl group and a dodecyl group, among which a methyl group, an ethyl group, an iso-propyl group, an n-propyl group, an n-butyl group, an iso-butyl group and a tert-butyl group are particularly preferable.

Each of p and q represents an integer from 0 to 2. Each of Y¹ and Y² represents a single bond or a C₁ to C₁₀ alkylene group and is preferably a single bond, a methylene group or an ethylene group, particularly preferably a single bond.

(Z¹)^{r+} and (Z²)ₛ₊ each independently represent an alkali metal ion, an alkaline earth metal ion, unsubstituted ammonium ion or an ammonium ion substituted by an alkyl group. Specific examples include a lithium ion, a sodium ion, a potassium ion, a magnesium ion, a calcium ion, an ammonium ion, a secondary to quaternary ammonium ion substituted by an alkyl, aryl or aralkyl group having 20 or less carbon atoms. (Z¹)^{r+} and (Z²)^{s+} each is particularly preferably a sodium ion. r and s each independently represent 1 or 2.

Specific examples of the aromatic anionic surfactant are shown below. However, the examples should not be construed as limiting the invention.

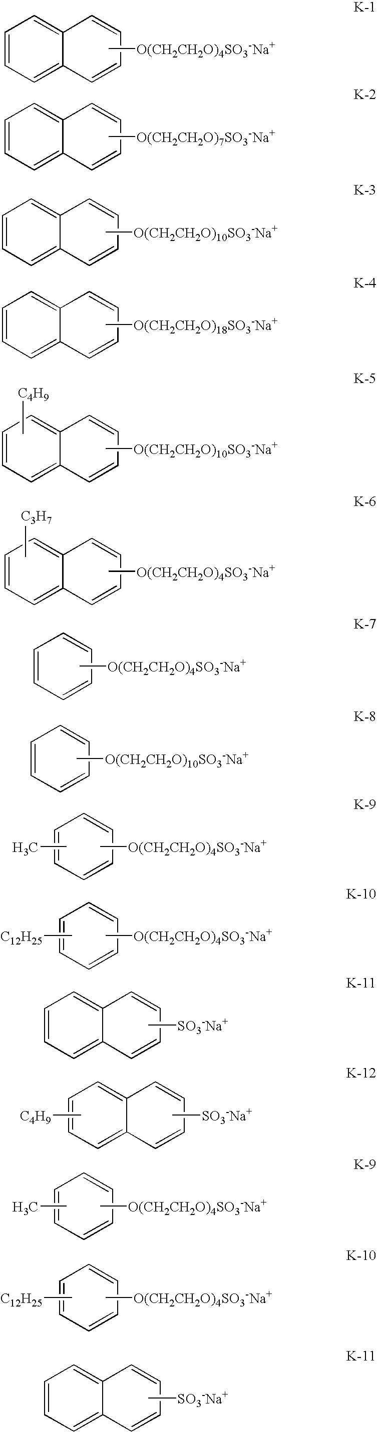

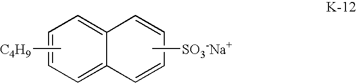

In an embodiment, only one aromatic anionic surfactant is used. In another embodiment, an arbitrary combination of two or more aromatic anionic surfactants is used. The amount of aromatic anionic surfactant to be added is not particularly limited. From the viewpoint of developability, the solubility of the recording layer components and the protective layer components, and the printing durability of the resultant printing plate, the concentration of the aromatic anionic surfactant in the developer is preferably in a range of from 1.0 to 10 mass %, more preferably in a range of from 2 to 10 mass %.

In the developer, the aromatic anionic surfactant may be used in combination with one or more other surfactants. Such other surfactants may be nonionic surfactants, and examples thereof include polyoxyethylene alkyl ethers such as polyoxyethylene naphthyl ether, polyoxyethylene alkyl phenyl ether, polyoxyethylene lauryl ether, polyoxyethylene cetyl ether, and polyoxyethylene stearyl ether, polyoxyethylene alkyl esters such as polyoxyethylene stearate, sorbitan alkyl esters such as sorbitan monolaurate, sorbitan monostearate, sorbitan distearate, sorbitan monooleate, sorbitan sesquioleate and sorbitan triooleate, and monoglyceride alkyl esters such as glycerol monostearate and glycerol monooleate.

The content of such additional surfactant in the developer is preferably from 0.1 to 10 mass %.

(Chelate Agent)

For the purpose of preventing the influence from calcium ions etc. contained in hard water, for example, a chelate agent for divalent metals is preferably contained in the developer. Examples of the chelate agent for divalent metals include polyphosphates such as Na₂P₂O₇, Na₅P₃O₃, Na₃P₃O₉, Na₂O₄P(NaO₃P)PO₃Na₂, and Calgon (sodium polymetaphosphate), aminopolycarboxylic acids (for example, ethylenediaminetetraacetic acid, potassium salts thereof, and sodium salts thereof, amine salt thereof; diethylenetriaminepentaacetic acid, potassium salt thereof, sodium salt thereof; triethylenetetraminehexaacetic acid, potassium salt thereof, sodium salt thereof; hydroxyethylenediaminetriacetic acid, potassium salt thereof, sodium salt thereof; nitrilotriacetic acid, potassium salt thereof, sodium salt thereof; 1,2-diaminocyclohexanetetraacetic acid, potassium salt thereof, sodium salt thereof; 1,3-diamino-2-propanol tetraacetic acid, potassium salt thereof, sodium salt thereof); other polycarboxylic acids (for example, 2-phosphonobutanetricarboxylic acid-1,2,4, potassium salt thereof, sodium salt thereof; 2-phosphonobutanonetricarboxylic acid-2,3,4, potassium salt thereof, sodium salt thereof), organic phosphonic acids (for example, 1-phosphonoethanetricarboxylic acid-1,2,2, potassium salt thereof, sodium salt thereof; 1-hydroxyethane-1,1-diphosphonic acid, potassium salt thereof, sodium salt thereof; and aminotri(methylene phosphonic acid), potassium salt thereof, and sodium salt thereof, among which ethylenediaminetetraacetic acid, potassium salt thereof, sodium salt thereof, amine salt thereof; ethylenediaminetetra(methylenephosphonic acid), ammonium salt thereof, potassium salt thereof; hexamethylenediaminetetra(methylenephosphonic acid), ammonium salt thereof, and potassium salt thereof are particularly preferable.

The optimum amount of the chelate agent varies depending on the hardness and amount of hard water used. In general, the chelate agent is contained in a range of 0.01 to 5 mass %, more preferably from 0.01 to 0.5 mass %, in the developer at use.

In addition, an alkali metal salt of an organic acid and/or an alkali metal salt of an inorganic acid may be added as the development regulating agent to the developer. For example, sodium carbonate, potassium carbonate, ammonium carbonate, sodium citrate, potassium citrate or ammonium citrate, or a combination of two or more of such salts may be used.

In addition to the components described above, components such as the following can be simultaneously used if necessary in the developer: organic carboxylic acids such as benzoic acid, phthalic acid, p-ethylbenzoic acid, p-n-propylbenzoic acid, p-isopropylbenzoic acid, p-n-butylbenzoic acid, p-t-butylbenzoic acid, p-t-butylbenzoic acid, p-2-hydroxyethylbenzoic acid, decanoic acid, salicylic acid and 3-hydroxy-2-naphthoic acid, organic solvents such as propylene glycol, and other components such as a reducing agent, a dye, a pigment and a preservative.

From the viewpoint of developability of the non-image portion during development, reduction of damage to the image portion, and handling property of the developer, the pH of the developer at 25° C. is preferably in a range of pH 10 to 12.5, more preferably in a range of pH 11 to 12.5.

The electric conductivity x of the developer is preferably within the range: 2<x<30 mS/cm, and is more preferably from 5 to 25 mS/cm. For regulating the electric conductivity, an alkali metal salt of an organic acid and/or an alkali metal salt of an inorganic acid are added preferably as the electric conductivity regulating agent.

The developer can be used as a developer and a replenisher for the light-exposed planographic printing plate precursor, and is preferably applied to an automatic developing machine. When the planographic printing plate precursor is developed with an automatic developing machine, the developer is exhausted depending on throughput. Therefore, processing power may be recovered by using a replenisher or a fresh developer. This replenishing system can be preferably used also in the plate-making method in the invention.

To restore the processing power of the developer in an automatic developing machine, replenishing can be conducted by a method described in U.S. Pat. No. 4,882,246. Developers described in JP-A No. 50-26601, JP-A No. 58-54341, JP-B No. 56-39464, JP-B No. 56-42860 and JP-B No. 57-7427 are also preferable.

The planographic printing plate precursor which was subjected to development treatment in this manner is post-treated with washing water, a surfactant-containing rinse, or a desensitizing gum solution containing gum arabic or a starch derivative, as described in JP-A No. 54-8002, JP-A No. 55-115045 and JP-A No. 59-58431. Various combinations of these treatments can be used.

For the purpose of improving strength of image portion and printing durability, the whole surface of the image after development can be heated or exposed to light. Very severe conditions can be utilized for the heating after development, and the heating temperature is usually in a range of 200 to 500° C.

The planographic printing plate obtained by these treatments is loaded onto an offset printing machine, and used for printing on a large number of sheets.

At the time of printing, a plate cleaner used for removing dirt from the plate may be a PS plate cleaner conventionally known in the art, such as Multi-cleaners CL-1, CL-2, CP, CN-4, CN, CG-1, PC-1, SR or IC (Fuji Film Corporation).

<Formation of Image Recording Layer>

The image recording layer of the invention is formed by applying a coating solution prepared by dispersing or dissolving the above-described necessary components in a solvent. Examples of the solvent include, however not limited to, ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propyl acetate, dimethoxyethane, methyl lactate, ethyl lactate, N,N-dimethylformamide, N,N-dimethylformamide, tetramethyl urea, N-methylpyrrolidone, dimethylsulfoxide, sulfolane, γ-butyl lactone, toluene, and water. These solvents are used alone or as a mixture. The concentration of the solid content in a coating solution is preferably from 1 to 50% by mass.

The image recording layer of the invention may be formed by preparing a plurality of coating solutions by dispersing or dissolving one or a plurality of the above-described components in one or a plurality of solvents, and repeatedly applying and drying the solutions a plurality of times.

The coating amount (solid content) of the image recording layer on the support after the application and drying processs differs according to the intended use, but, in usual cases, is preferably from 0.3 to 3.0 g/m². When the coating amount is within the range, favorable sensitivity and favorable coating property of the image recording layer are achieved.

The method for coating may be selected from various methods, such as bar coater coating, rotary coating, spray coating, curtain coating, dip coating, air knife coating, blade coating, and roll coating.

<Support>

The support used in the planographic printing plate precursor of the invention may be freely selected from dimensionally stable plate materials, such as paper, paper laminated with a plastic (e.g. polyethylene, polypropylene, and polystyrene), a metal plate (e.g. aluminum, zinc, or copper), a plastic film (e.g. cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate, and polyvinyl acetal), and paper or a plastic film laminated or vapor deposited with the above-described metal. Preferable examples of the support include a polyester film and an aluminum plate. Among them, an aluminum plate is most preferable because it is dimensionally stable and relatively inexpensive.

The scope of the aluminum plate includes not only a pure aluminum plate but also an alloy plate including aluminum as a major component and a very small amount of hetero elements, and a thin film of aluminum or an aluminum alloy laminated with a plastic. Examples of the hetero elements contained in the aluminum alloy include silicon, iron, manganese, copper, magnesium, chromium, zinc, bismuth, nickel, and titanium. The content of the hetero elements in the alloy is preferably 10% by mass or less. The aluminum plate used in the invention is preferable a pure aluminum plate, however because production of completely pure aluminum is difficult from the viewpoint of refining techniques, aluminum may contain a very small amount of hetero elements. The composition of the aluminum plate is not limited, and any aluminum plates made of known and conventionally used aluminum materials can be used as necessary.

The thickness of the support is preferably from 0.1 to 0.6 mm, more preferably from 0.15 to 0.4 mm, and further preferably from 0.2 to 0.3 mm.

The aluminum plate is preferably subjected to surface treatment such as surface roughening treatment and anodizing treatment before use. The surface treatment improves the hydrophilicity and facilitates providing adhesiveness between the image recording layer and the support. Before the surface roughening treatment, the aluminum plate is, if desired, subjected to degreasing treatment with a surfactant, an organic solvent, or an alkaline aqueous solution to remove the rolling oil on the surface.

The surface roughening treatment of the aluminum plate is conducted by various methods such as mechanical surface roughening treatment, electrochemical surface roughening treatment (surface roughening treatment by electrochemically dissolving the surface), and chemical surface roughening treatment (surface roughening treatment by chemically and selectively dissolving the surface).

The mechanical surface roughening treatment may be conducted by a known method such as a ball polishing method, a brush polishing method, a blast polishing method, or a buff polishing method.

The electrochemical surface roughening treatment is conducted, for example, with an alternating current or direct current in an electrolytic solution containing an acid such as hydrochloric acid or nitric acid. Another example is a method using a mixed acid as described in JP-A No. 54-63902.

The surface roughened aluminum plate is as necessary subjected to alkali etching treatment using an aqueous solution of potassium hydroxide, sodium hydroxide, or the like, and neutralized, and if desired, subjected to anodizing treatment to improve the abrasion resistance.

The electrolyte used for the anodizing treatment of the aluminum plate may be selected from various electrolytes which form a porous oxide film. In general cases, sulfuric acid, hydrochloric acid, oxalic acid, chromic acid or a mixed acid thereof is used. The concentration of the electrolyte is determined as appropriate according to the kind of the electrolyte.

The conditions of the anodizing treatment vary with the electrolyte to be used and cannot be specified. In general, however, it is preferable that the concentration of the electrolyte be from 1% to 80% by mass, the solution temperature be from 5 to 70° C., the current density be from 5 to 60 A/dm², the voltage be from 1 V to 100 V, and the electrolytic time be from 10 seconds to 5 minutes. Under the conditions, favorable printing durability and flaw resistance in the non-image region of the planographic printing plate are achieved.

After the anodizing treatment the surface of the aluminum plate is, as necessary, subjected to hydrophilizing treatment. Examples of the method for hydrophilizing treatment include an alkali metal silicate method described in U.S. Pat. Nos. 2,714,066, 3,181,461, 3,280,734, and 3,902,734. In the method, the support is immersed or electrolyzed in an aqueous solution of sodium silicate or the like. Other examples of the method include a method of treating with potassium fluorozirconate described in JP-B No. 36-22063, and a method of treating with polyvinylphosphonic acid as described in U.S. Pat. Nos. 3,276,868, 4,153,461, and 4,689,272.

The center line average roughness of the support is preferably from 0.10 to 1.2 μm. When the roughness is within the range, favorable adhesiveness to the image recording layer, favorable printing durability, and favorable stain resistance are achieved.

The color density of the support is preferably from 0.15 to 0.65 as a reflection density value. When the color density is within the range, halation is prevented during the image exposure, hence favorable image forming ability and favorable plate check property after development are achieved.

<Back Coat Layer>

After the surface treatment of or formation of an undercoat layer on the support, as necessary, a back coat layer may be provided on the backface of the support. Preferable examples of the back coat layer include a coating layer composed of a metal oxide prepared by hydrolysis and polycondensation of an organic polymer compound described in JP-A No. 5-45885, an organic metal compound, or an inorganic metal compound described in JP-A No. 6-35174. Among them, alkoxy compounds of silicon such as Si(OCH₃)₄, Si(OC₂H₅)₄, Si(OC₃H₇)₄, and Si(OC₄H₉)₄ are preferable from the viewpoints of the low cost and ready availability of the raw materials.

<Undercoat Layer>

The planographic printing plate precursor of the invention used for the planographic printing method of the invention may include, as necessary, an undercoat layer between the image recording layer and the support. The undercoat layer functions as a heat insulating layer, hence heat generated by light exposure with an infrared laser is efficiently utilized with no dissipation into the support, by which higher sensitivity is achieved. In addition, the undercoat layer facilitate the separation of the light-unexposed portion of the image recording layer from the support, which improves the in-machine developability.

Specific preferable examples of the undercoat layer include a silane coupling agent having an addition-polymerizable ethylenic double bond reactive group, and a phosphorus compound having an ethylenic double bond reactive group described in JP-A No. 10-282679. When the undercoat layer is designed such that it remains on the support even after printing, the stain resistance in the non-image region is improved.

Specific examples of the undercoat layer include a copolymer having a repeating unit (a1) containing at least one ethylenically unsaturated bond, a repeating unit (a2) containing at least one functional group interacting with the support surface, and a repeating unit (a3) containing at least one hydrophilic group described in JP-A No. 2005-125749.

The functional group (a1) having an ethylenically unsaturated bond is preferably represented by the following Formula (A1).

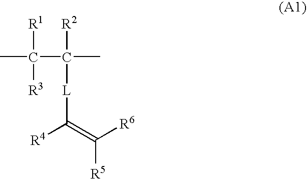

In the Formula, R¹ to R³ each independently represent a hydrogen atom, an alkyl group having 1 to 6 carbon atoms, or a halogen atom. R⁴ to R⁶ each independently represent a hydrogen atom, an alkyl group having 1 to 6 carbon atoms, a halogen atom, an acyl group, or an acyloxy group. R⁴ and R⁵, or R⁵ and R⁶ may form a ring. L represents a divalent linking group selected from the group consisting of —CO—, —O—, —NH—, a divalent aliphatic group, a divalent aromatic group, and a combination thereof.

Specific examples of L composed of a combination are listed below. In the following examples, the left side is bonded to the main chain, and the right side is bonded to the ethylenically unsaturated bond.

L¹: —CO—NH-divalent aliphatic group-O—CO—

L²: —CO-divalent aliphatic group-O—CO—

L³: —CO—O-divalent aliphatic group-O—CO—

L⁴: -divalent aliphatic group-O—CO—

L⁵: —CO—NH-divalent aromatic group-O—CO—

L⁶: —CO—divalent aromatic group-O—CO—

L⁷: -divalent aromatic group-O—CO—

L⁸: —CO-divalent aliphatic group-CO—O-divalent aliphatic group-O—CO—

L⁹: —CO-divalent aliphatic group-O—CO-divalent aliphatic group-O—CO—

L¹⁰: —CO-divalent aromatic group-CO—O-divalent aliphatic group-O—CO—

L¹¹: —CO-divalent aromatic group-O—CO-divalent aliphatic group-O—CO—

L¹²: —CO-divalent aliphatic group-CO—O-divalent aromatic group-O—CO—

L¹³: —CO-divalent aliphatic group-O—CO-divalent aromatic group-O—CO—

L¹⁴: —CO-divalent aromatic group-CO—O-divalent aromatic group-O—CO—

L¹⁵: —CO-divalent aromatic group-O—CO-divalent aromatic group-O—CO—

L¹⁶: —CO—O-divalent aromatic group-O—CO—NH-divalent aliphatic group-O—CO—

L¹⁷: —CO—O-divalent aliphatic group-O—CO—NH-divalent aliphatic group-O—CO—

The divalent aliphatic group refers to an alkylene group, a substituted alkylene group, an alkenylene group, a substituted alkenylene group, an alkynylene group, a substituted alkynylene group, or a polyalkyleneoxy group. Among them, an alkylene group, a substituted alkylene group, an alkenylene group, and a substituted alkenylene group are preferable, and an alkylene group and a substituted alkylene group are more preferable.

The divalent aliphatic group preferably has an open-chain structure rather than a cyclic structure, and further preferably has a linear structure rather than a branched chain structure. The carbon atoms in the divalent aliphatic group is preferably from 1 to 20, more preferably from 1 to 15, even further preferably from 1 to 12, even further preferably from 1 to 10, and most preferably from 1 to 8.

Examples of the substituent of the divalent aliphatic group include a halogen atom (F, Cl, Br, or I), a hydroxyl group, a carboxyl group, an amino group, a cyano group, an aryl group, an alkoxy group, an aryloxy group, an acyl group, an alkoxycarbonyl group, an aryloxycarbonyl group, an acyloxy group, a monoalkylamino group, a dialkylamino group, an arylamino group, and a diarylamino group.

The divalent aromatic group refers to an arylene group or a substituted arylene group, and is preferably a phenylene group, a substituted phenylene group, a naphthylene, or a substituted naphthylene group.

Among the above-described L¹ to L¹⁷, L¹, L³, L⁵, L⁷, and L¹⁷ are preferable.

Examples of the functional group (a2) interacting with the support surface include groups which interact with a metal, metal oxide, or hydroxy group existing on the anodized or hydrophilized support through a covalent bond, ionic bond, hydrogen bond, polarity interaction, or van der Waal's interaction.

Specific examples of the specific functional group are listed below. 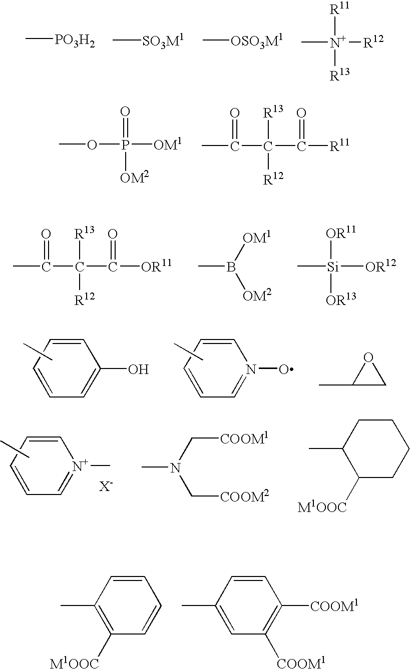
(In the Formula, R¹¹ to R¹³ each independently represent a hydrogen atom, an alkyl group, an aryl group, an alkynyl group, or an alkenyl group, M¹ and M² each independently represent a hydrogen atom, a metal atom, or an ammonium group, X represents a counter anion.)

Among them, an onium base such as an ammonium group and a pyridinium group, and a β-diketone group such as a phosphate group, a phosphonic acid group, a boric acid group, and an acetylacetone group are preferable as the specific functional group.

The logP value of the hydrophilic group (a3) is preferably from −3 to 3, and more preferably from −1 to 2. When the logP value is within the range, favorable in-machine developability and stain resistance are achieved.

The logP value is the logarithm of the octanol/water partition coefficient (P) of the compound calculated using a software PC Models developed by Medical Chemistry Prolect, Pomona College, Claremont. Calif., and available from Daylight Chemical Information System Inc.

Specifically, the hydrophilic group preferably contains an alkyleneoxy group, an amide group, a carboxylic acid (salt) group, a sulfonic acid (salt) group, and particularly preferably contains a sulfonic acid (salt) group from the viewpoint of stain resistance.

The coating amount (solid content) of the undercoat layer is preferably from 0.1 to 100 mg/m², and more preferably from 3 to 30 mg/m²

[Light Exposure]

In the planographic printing method of the invention, the planographic printing plate precursor of the invention is imagewisely exposed to infrared laser light.

The infrared laser used in the invention is not particularly limited, and is preferably a solid laser or a semiconductor laser which emits infrared rays having a wavelength of 760 to 1200 nm. The output of the infrared laser is preferably 100 mW or more. In addition, it is preferable that a multi-beam laser device be used to reduced the light exposure time.

The light exposure time for a pixel is preferably 20μ seconds or less. The amount of irradiation energy is preferably from 10 to 300 mJ/cm².

[Printing]

In the planographic printing method of the invention, as described above, the planographic printing plate precursor of the invention is imagewisely exposed to infrared laser light, and then subjected to the printing process using a oil-based ink and an aqueous component without subjecting to any development process.

Specific examples of the printing method include a method of exposing the planographic printing plate precursor to infrared laser light, and subjecting the precursor to the printing process on a printing machine without subjecting to any development process, and a method of mounting the planographic printing plate precursor on a printing machine, thereafter exposing the precursor to infrared laser light on the printing machine, and subjecting the precursor to the printing process without subjecting to any development process.

The planographic printing plate precursor is imagewisely exposed to infrared laser light, and then subjected to the printing process using an aqueous component and a oil-based ink without subjecting to any development process, wherein the light-exposed portion on the image recording layer is cured to form a oil-based ink-receiving portion having a lipophilic surface. In the light-unexposed portion, the uncured portion of image recording layer is dissolved or dispersed by the aqueous component and/or oil-based ink and removed, where the hydrophilic surface is exposed.

As a result, the aqueous component such as a dampening water adheres to the hydrophilic surface, the oil-based ink settles on the light-exposed region on the image recording layer, then printing is started. Either the aqueous component or oil-based ink may be supplied to the plate surface first, however, it is preferable that the oil-based ink be supplied first to prevent the aqueous component from being contaminated with the light-unexposed portion of the image recording layer. The aqueous component and oil-based ink may be a dampening water and a printing ink used for ordinary planographic printing.

As described above, the planographic printing plate precursor is developed on the offset printing machine, and used for printing on a lot of sheets.

The invention is illustrated by the following Examples, however the invention is not particularly limited to them. In the following Example A, ordinary developing treatment was conducted following light exposure.

### EXAMPLE A

### Examples A1 to A5

### Making of Support

A plate of JIA A 1050 aluminum having a thickness of 0.24 mm and a width of 1030 mm was continuously subjected to the following treatment processs (A) to (j). After each process and water washing, liquids were removed by a nip roller.

(a) Mechanical Surface Roughening Treatment

Using a mechanical surface roughening apparatus, the aluminum plate was mechanically surface roughened with rotating nylon brush rollers while a suspension of an abrasive material (pumice) had a specific gravity of 1.12 in water as an abrasive slurry supplied to the aluminum plate surface. The abrasive material had an average particle diameter of 40 to 45 μm, and a maximum diameter of 200 μm. The nylon brushes were made of nylon-6, 10 and had a bristle length of 50 mm and a bristle diameter of 0.3 mm. Three rotating brush rollers were used, each of which composed of a perforated stainless-steel cylinder having a diameter of 300 mm and bundles of such nylon bristles densely attached thereto by filling them into the perforations. The apparatus had under the brush rollers two supporting rollers (200 mm in diameter) apart from each other at a distance of 300 mm. The brush rollers were pressed against the aluminum plate in such a degree that the load imposed on the driving motor rotating the brush rollers increased to a value higher by 7 kW than that as measured before the brush rollers were pressed against the aluminum plate. The direction of rotation of the brush rollers was the same as the direction of running of the aluminum plate, and the rotational speed thereof was 200 rpm.

(b) Alkali Etching Treatment

The aluminum plate was etched by spraying with an etching solution having a caustic soda concentration of 2.6% by mass and an aluminum ion concentration of 6.5% by mass at a temperature of 70° C. to dissolve the aluminum plate in an amount of 0.3 g/m². Thereafter, the aluminum plate was washed with water by spraying.

(c) Desmutting Treatment

The aluminum plate was desmutted by spraying with an aqueous solution having a nitric acid concentration of 1% by mass (containing 0.5% by mass of aluminum ions) and a temperature of 30° C. Thereafter, the aluminum plate was washed with water by spraying. The aqueous nitric acid solution used for the desmutting treatment was a waste liquid resulting from the process of electrochemical surface roughening with an alternating current in an aqueous nitric acid solution.

(d) Electrochemical Surface Roughening Treatment

The aluminum plate was continuously subjected to electrochemical surface roughening using a 60 Hz AC voltage. The electrolytic solution used was a 1% by mass aqueous nitric acid solution (containing 0.5% by mass of aluminum ions and 0.007% by mass of ammonium ions) having a temperature of 40° C. The AC power source used was one providing a trapezoidal rectangular wave alternating current wherein the TP, which is the time required for the current value to increase from zero to a peak, was 2 msec and the duty ratio was 1:1. A carbon electrode was used as a counter electrode, and ferrite was used as an auxiliary anode to conduct the electrochemical surface roughening treatment.

The current density was 30 A/dm² in terms of peak value, and the quantity of electricity was 255 C/cm² in terms of the sum of electricity at the time when the aluminum plate was functioning as an anode. 5% of the current flowing from the power source was supplied to the auxiliary anode. After this surface roughening treatment, the aluminum plate was washed with water by spraying.

(e) Alkali Etching Treatment

The aluminum plate was etched by spraying with an etching solution having a caustic soda concentration of 26% by mass and an aluminum ion concentration of 6.5% by mass at 32° C. to dissolve the aluminum plate in an amount of 0.2 g/m². Thus, the smut ingredients composed mainly of aluminum hydroxide produced by the preceding process of electrochemical surface roughening with an alternating current were removed and, simultaneously therewith, the edges of the pits formed were partly dissolved away and rounded to be smooth. Thereafter, the aluminum plate was washed with water by spraying.

(f) Desmutting Treatment

The aluminum plate was desmutted by spraying with an aqueous solution having a nitric acid concentration of 25% by mass (containing 0.5% by mass of aluminum ions) and a temperature of 60° C. Thereafter, the aluminum plate was washed with water by spraying.

(g) Electrochemical Surface Roughening Treatment

An anodizing apparatus based on the two-stage-feed electrolytic processing method (lengths of first and second electrolysis zones, 6 m each; length of first feed zone, 3 m; length of second feed zone, 3 m; lengths of first and second feeder electrodes, 2.4 m each) was used to anodize the aluminum plate under the conditions of a sulfuric acid concentration in the electrolysis zones of 170 g/little (containing 0.5% by mass of aluminum ions) and a temperature of 38° C. Thereafter, the aluminum plate was washed with water by spraying.

In this anodizing apparatus, a current supplied from a power source flowed to a first feeder electrode disposed in the first feed zone and then to the aluminum plate through the electrolytic solution to form an oxide film on the surface of the aluminum plate in the first electrolysis zone. The current then passed through an electrolysis electrode disposed in the first feed zone and returned to the power source. On the other hand, another current supplied from the power source flowed to a second feeder electrode disposed in the second feed zone and likewise to the aluminum plate through the electrolytic solution to form an oxide film on the surface of the aluminum plate in the second electrolysis zone. The quantity of electricity fed to the first feed zone from the power source was equal to that fed to the second feed zone from the power source. The current density in the surface of the oxide film in the second feed zone was about 25 A/dm². In the second feed zone, electricity was fed through the oxide film of 1.35 g/m². The amount of the oxide film finally obtained was 2.7 g/m². The aluminum plate subjected to the above-described treatment processs (A) to (g) is referred to as an aluminum support [1].

(h) Hydrophilicity-Imparting Treatment

The aluminum support [1] was subjected to silicate treatment for enhancing the hydrophilicity of the nonimage region of the printing plate. In this treatment, the aluminum web was passed through a 1.5% aqueous solution of No. 3 sodium silicate kept at 70° C., in such a manner that the web/solution contact time was 15 seconds. Thereafter, the web was washed with water. As a result, the amount of Si deposited on the aluminum support was 10 mg/m². The aluminum support [1] having a hydrophilic surface is referred to as an aluminum support [2].

[Formation of Image Recording Layer]

An image recording layer coating solution (1) consisted of the following ingredients was applied to the aluminum support [1] treated as described above in a dry coating amount of 1.0 to 1.2 g/m². The coating was dried at 100° C. for 1 minute to form an image recording layer.

<image recording layer coating solution (1)>

| | | |
|---|---|---|
| Addition polymerizable compound (M-1) | 1.7 | g |
| Binder polymer (B-1) | 1.9 | g |
| Sensitizing dye (Dye-1) | 0.2 | g |
| Photopolymerization initiator (I-1) | 0.40 | g |
| Other additive (C-1) | 0.4 | g |
| Fluorine-based nonionic surfactant (trade | 0.03 | g |
| name: MEGAFAC F-177, manufactured by | | |
| Dainippon Ink And Chemicals, Inc.) | | |
| Heat polymerization inhibitor | 0.01 | g |
| (N-nitrosophenylhydroxylamine aluminum | | |
| salt) | | |
| Coloring pigment dispersion consisted | 2.0 | g |
| of the following ingredients | | |
| Methyl ethyl ketone | 10.0 | g |
| Popylene glycol monomethyl ether | 20.0 | g |
| Methanol | 10.0 | g |
| Water (distilled water) | 2.0 | g |

-Ingredients of coloring pigment dispersion-

| | | |
|---|---|---|
| Pigment Blue 15:6 | 15 | parts by mass |
| Allyl methacrylate/methacrylic acid | 10 | parts by mass |
| copolymer (copolymerization molar ratio 80/20, | | |
| weight-average molecular weight 40000) | | |
| Cyclohexanone | 15 | parts by mass |
| Methoxypropyl acetate | 20 | parts by mass |
| Propylene glycol monomethyl ether | 40 | parts by mass |

The ingredients used in the image recording layer coating solution (1) are as follows.

<Addition Polymerizable Compound>

M-1: Pentaerythritol tetraacrylate (trade name: NK Ester A-TMMT, manufactured by Shin-nakamura Chemical Co., Ltd.)

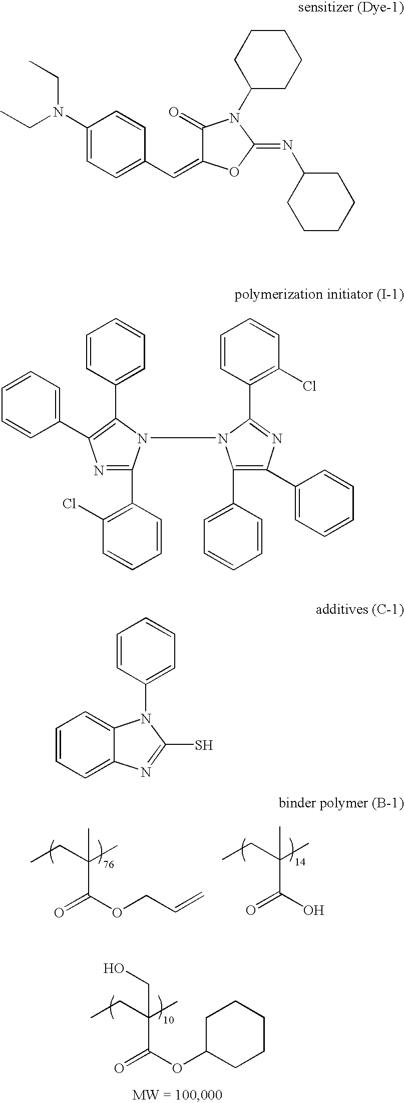

[Formation of Protective Layer]

The protective layer coating solution (1) consisted of the following ingredients was applied to the image recording layer with a wire bar. Thereafter, the coating was dried in an oven at 125° C. for 75 seconds to form a protective layer in a dry coating amount of 1.80 g/m². Thus planographic printing plate precursors of Examples 1 to 5 were obtained.

<Ingredients of protective layer coating solution (1)>

| | | |
|---|---|---|
| 6% by mass aqueous solution of polyvinyl alcohol | 4.12 | g |
| (trade name: PVA 105, manufactured by Kuraray Co., | | |
| Ltd., saponification degree of 98.5 mol %, | | |
| polymerization degree of 500) | | |
| Compound having within the molecule thereof an acid | 0.04 | g |
| group and a partial structure functioning as a base | | |
| (compound listed in Table 1) | | |
| Polyvinylpyrrolidone (K30) | 0.0053 | g |
| 1% by mass aqueous solution of a surfactant (trade | 2.15 | g |
| name: EMALEX 710, manufactured by Kao Corporation) | | |
| Distilled water | 10.60 | g |

The compounds having within the molecule thereof an acid group and a partial structure functioning as a base used in Examples 1 to 4 and below-described Examples 5 to 14 are shown below.

### Comparative Examples A1 and A2

A planographic printing plate precursor of Comparative Example 1 was made in the same manner as Example 1, except that the compound having within the molecule thereof an acid group and a partial structure functioning as a base was not added to the protective layer coating solution (1).

Further, a planographic printing plate precursor of Comparative Example 2 was made in the same manner as Example 1, except that the compound having within the molecule thereof an acid group and a partial structure functioning as a base added to the protective layer coating solution (1) was replaced with the same amount of sodium p-toluenesulfonic acid, which is a known development promoting compound.

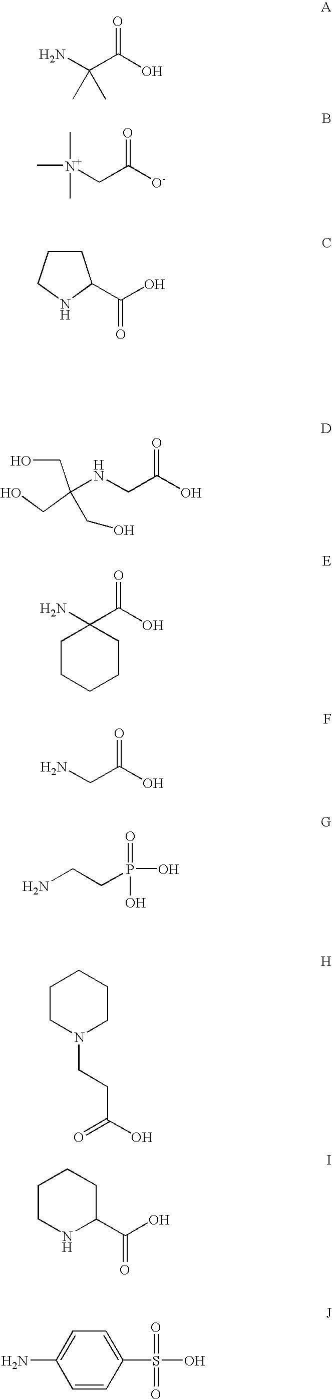

[Light Exposure and Postheating of Planographic Printing Plate Precursors]

The planographic printing plate precursors of Examples A1 to A5, and Comparative Examples A1 and A2 made as described above were each loaded onto a violet semiconductor laser setter (trade name: Vx 9600, manufactured by FUJIFILM Electronic Imaging Ltd) (InGaN semiconductor laser, 405 nm±10 nn emission/output 30 mW), and subjected to halftone dot image exposure from 1% to 99% in increments of 1% at a light intensity of 90 μJ/cm², and a resolution of 2438 dpi. Thereafter, the precursors were heated in an oven at 100° C. for 10 seconds.

[Development/Plate Making]

After the light exposure, the following developer D-1 and finisher (trade name: FP-2W, manufactured by Fuji Photo Film Co., Ltd.) were charged into an automatic developing machine (trade name: FLP-813, manufactured by Fuji Photo Film Co., Ltd.). Each plate which had been exposed was developed to make a planographic printing plate under the conditions of a developer temperature of 30° C. and a developing time of 12 seconds.

[Evaluation of Developability]

The planographic printing plates made as described above were loaded onto a LITHRONE printing machine (manufactured by Komori Corporation), and subjected to continuous printing with a GRAPH G(N) ink (manufactured by Dainippon Ink And Chemicals, Inc.) A hundredth printed sheet was visually observed to evaluate the developability. When no stain was present in the non-image region, the developability was judged as favorable, while when stains were present because of insufficient removal of the non-image region after the development, the developability was judged as defective. The results are shown in the following Table 1.

<Developer (D-1)>

The developer D-1 is an aqueous solution having a pH of 10 and is consisted of the following ingredients.

| | |
|---|---|
| Monoethanolamine | 0.1 parts by mass |
| Triethanolamine | 1.5 parts by mass |
| Compound represented by the following Formula 1 | 4.0 parts by mass |
| Compound represented by the following Formula 2 | 2.5 parts by mass |

Compound represented by the following Formula 30.2 parts by mass

Water 91.7 parts by mass

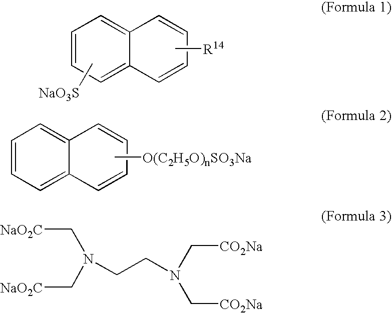

The (Formula 1) represents a mixture of compounds in which R¹⁴ is a hydrogen atom or a butyl group. In the (Formula 2), n is an integer of 2 to 20.

[Image Region Printing Durability Test]

In the same manner as the above-described developability evaluation, printing was continuously conducted using a LITHRONE printing machine (manufactured by Komori Corporation) and a GRAPH G(N) ink (manufactured by Dainippon Ink And Chemicals, Inc.). The printing durability of the solid image region was evaluated in terms of the number of printed sheets obtained by the time when the image began to be thinned. The printing durability was relatively evaluated with the number of printed sheets obtained with the precursor of Comparative Example A1 as 100. The larger the number, the better the printing durability. The results are shown in the following Table 1.

TABLE 1

| | Compound (B) having within | | |
|---|---|---|---|
| | the molecule thereof an acid | | |
| | group and a partial structure | Printing | |
| | functioning as a base | durability | Developability |
| Example A1 | A | 105 | Favorable |
| Example A2 | B | 100 | Favorable |
| Example A3 | C | 105 | Favorable |
| Example A4 | D | 100 | Favorable |
| Comparative | None | 100 | Color residues |
| example A1 | | | |
| Comparative | Sodium | 65 | Favorable |
| example A2 | p-toluenesulfonic acid | | |

As evident from Table 1, the planographic printing plate precursor of the invention having the specific protective layer exhibited sufficient curing property, and the image region obtained exhibited excellent printing durability and favorable developability. On the other hand, Comparative Example 1, which contained in the protective layer thereof no compound (B) having within the molecule thereof an acid group and a partial structure functioning as a base, exhibited insufficient developability, and Comparative Example A2, which contained in the protective layer thereof a known development promoting compound, exhibited favorable developability, while poor curing property was shown because of the decreased oxygen impermeability of the protective layer, and was inferior in printing durability to Examples.

### Examples A5 to A14

The image recording layer coating solution (2) consisted of the following ingredients was applied with a wire bar to the aluminum support [2] made as described above. Thereafter, the coating was dried in an oven at 100° C. for 60 seconds to form an image recording layer in a dry coating amount of 1.3 g/m².

<Image recording layer coating solution (2)>

| | |
|---|---|
| Binder polymer [component (A), compound listed in Table] | 0.162 g |
| Polymerization initiator [component (C), compound listed | 0.160 g |
| in Table] | |
| Infrared ray absorbing agent [sensitizing dye: component | 0.038 g |
| (D), compound listed in Table] | |
| Polymerizable compound [component (B), compound listed | 0.385 g |
| in Table] | |
| Additive (C-1) | 0.080 g |
| Fluorine-based surfactant (1) | 0.044 g |
| Methyl ethyl ketone | 4.091 g |
| 2-methoxy-1-propanol | 8.609 g |

The structure of the binder polymer (A), polymerization initiator (C), polymerizable compound (B), and sensitizing dye (D) used in the image recording layer coating solution (2) is shown below.

[Polymerizable Compound (B)]

M-2: ethoxylated bisphenol A diacrylate (trade name: SR-601, manufactured by Nippon Kayaku Co., Ltd.)

M-3: pentaerythritol triacrylate hexamethylene diisocyanate urethane prepolymer (trade name: UA-306H, manufactured by Kyoeisha Chemical Co., Ltd.) 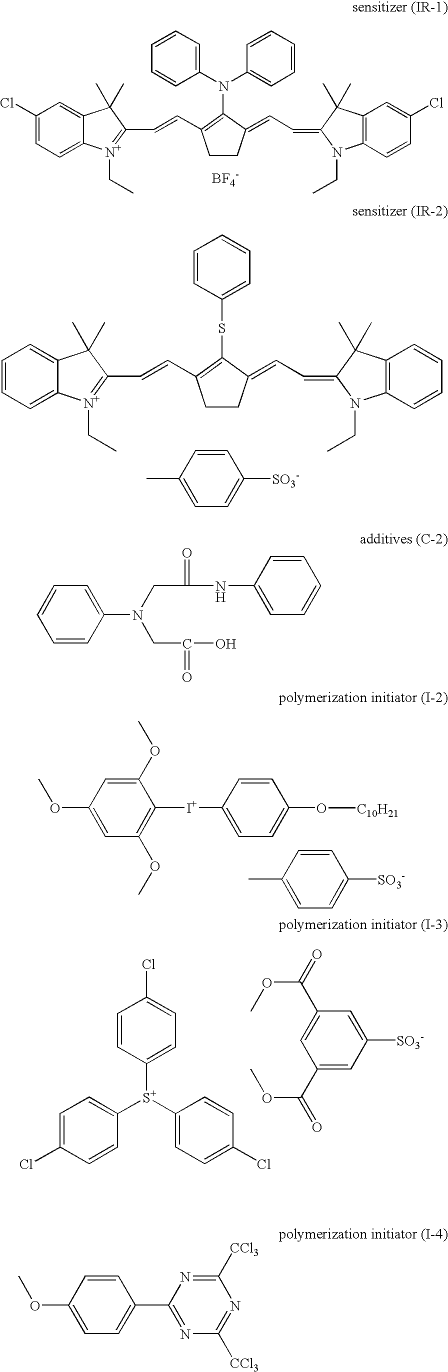 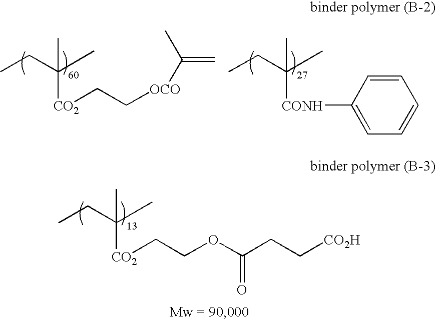
polyurethane compound which is prepared in condensation polymerization of the following monomers at the following rate

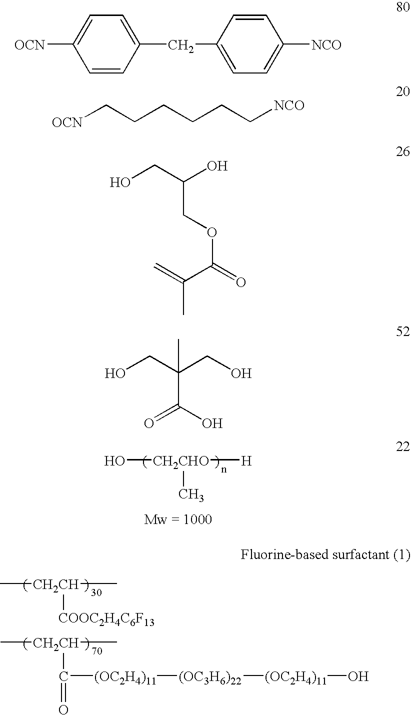

The protective layer coating solution (2) consisted of the following ingredients was applied to the image recording layer with a wire bar. Thereafter, the coating was dried in an oven at 125 C for 75 seconds to form a protective layer in a dry coating amount of 2.00 g/m². Thus planographic printing plate precursors of Examples 5 to 14 were obtained.

<Protective layer coating solution (2)>

| | | |
|---|---|---|
| Polyvinyl alcohol (trade name: PVA105, manufactured by | 2.24 | g |
| Kuraray Co., Ltd., saponification degree of 98.5 mol %, | | |
| polymerization degree of 500) | | |
| Compound having within the molecule thereof an acid | 0.012 | g |
| group and a partial structure functioning as a base | | |
| (compound listed in Table 1) | | |
| Polyvinylpyrrolidone (K30) | 0.0053 | g |
| 1% by mass aqueous solution of a surfactant (trade name: | 2.15 | g |
| EMALEX 710, manufactured by Kao Corporation) | | |
| 3.4% by mass aqueous dispersion of scaly synthetic mica | 3.75 | g |
| (trade name: MEB3L, manufactured by UNICOO, average | | |
| particle diameter 1 to 5 μm) | | |
| Distilled water | 10.60 | g |

[Light Exposure of Planographic Printing Plate Precursor]

The planographic printing plate precursors of Examples 5 to 14, and Comparative Examples 3 and 4 made as described above were subjected to light exposure using Trendsetter 3244 VFS (manufactured by Creo Products, Inc.) equipped with a water-cooled 40 W infrared semiconductor (830 nm) laser with an output power of 9 W, an external drum rotation speed of 210 rpm, a plate surface energy of 100 mJ/cm², and a resolution of 2400 dpi.

[Development/Plate Making]

After the light exposure, a developer (trade name: DV-2, manufactured by Fuji Photo Film Co., Ltd.) and a finisher (trade name: FN-6, manufactured by Fuji Photo Film Co., Ltd.) diluted with water at a ratio of 1:1 were charged into an automatic developing machine (trade name: STABLON 900N, manufactured by Fuji Photo Film Co., Ltd.). Each plate was developed at 30° C. for 12 seconds to make a planographic printing plate.

[Image Region Printing Durability Test]

Printing was conducted using a LITHRONE printing machine (manufactured by Komori Corporation) and a GRAPH G(N) ink (manufactured by Dainippon Ink And Chemicals, Inc.). The printing durability of the solid image region was evaluated in terms of the number of printed sheets obtained by the time when the image began to be thinned. The printing durability was relatively evaluated with the number of printed sheets obtained with the precursor of Comparative Example 3 as 100. The larger the number, the better the printing durability. The results are shown in the following Table 2.

[Developability Test]

The developability of the non-image region after light exposure and development was evaluated in terms of color residues.

After aging, the non-image region after light exposure and development was measured using Spectrodensitometer (manufactured by X-Rite) for the cyan density in the light-unexposed portion. On the basis of the cyan density in the non-image region of the plate after immersion (after development), the color residue rate was calculated by the following Formula. Those showed a color residue rate of 7% or less were regarded as having favorable developability with no color residue, while those showed a color residue rate of 7% or more were regarded as having poor developability with significant color residues. The results are shown in the following Table 2.
Color residue rate(%)=[(cyan density in the light-unexposed portion after development−cyan density of uncoated aluminum substrate)/(cyan density of uncoated aluminum substrate)]

TABLE 2

| | Compound (B) having | | | | | | |
|---|---|---|---|---|---|---|---|
| | within the molecule | | | | | | |
| | thereof an acid group | Compound used in image recording layer | | | | | |
| | and a partial structure | Polymerizable | Binder | Sensitizing | Polymerization | Evaluation result | |
| | functioning as a base | compound (C) | (A) | dye (D) | initiator (B) | Color residues | Printing durability |
| Example A5 | A | M-3 | B-3 | IR-1 | I-2 | Favorable | 105 |
| Example A6 | B | M-3 | B-3 | IR-1 | I-2 | Favorable | 105 |
| Example A7 | C | M-3 | B-3 | IR-1 | I-2 | Favorable | 105 |
| Example A8 | D | M-2 | B-3 | IR-1 | I-3 | Favorable | 100 |
| Example A9 | E | M-2 | B-2 | IR-2 | I-4 | Favorable | 100 |
| Example A10 | F | M-2 | B-3 | IR-2 | I-2 | Favorable | 105 |
| Example A11 | G | M-1 | B-2 | IR-2 | I-2 | Favorable | 105 |
| Example A12 | H | M-3 | B-3 | IR-1 | I-2 | Favorable | 105 |
| Example A13 | I | M-2 | B-2 | IR-1 | I-3 | Favorable | 100 |
| Example A14 | J | M-3 | B-2 | IR-1 | I-2 | Favorable | 105 |
| Comparative example | None | M-2 | B-3 | IR-1 | I-3 | poor | 100 |
| A3 | | | | | | | |
| Comparative example | 2-sodium | M-2 | B-3 | IR-1 | I-3 | Favorable | 65 |
| A4 | naphthalenesulfonate | | | | | | |

As evident from Table 2, the planographic printing plate precursor of the invention having the specific protective layer achieved sufficient curing property, and the image region obtained exhibited excellent printing durability and favorable developability. On the other hand, Comparative Example 3, which contained in the protective layer thereof no compound (B) having within the molecule thereof an acid group and a partial structure functioning as a base, exhibited insufficient developability, and Comparative Example 4, which contained in the protective layer thereof a known development promoting compound, exhibited favorable developability, while poor curing property was shown because of the decreased oxygen impermeability of the protective layer, and was inferior in printing durability to Examples.

These evaluation results show that the planographic printing plate precursor of the invention having the specific protective layer achieves the same excellent effects even when the Formulation of the negative-working image recording layer is changed.

The following Example B describes a case where the light-exposed planographic printing plate precursor is subjected to the printing process using an oil-based ink and an aqueous component without subjecting to any developing treatment process. It involves a printing process, a portion of the planographic printing plate precursor unexposed to infrared laser light is removed during printing.

### EXAMPLE B

The following Example B describes a case where the planographic printing plate precursor after light exposure receives a oil-based ink and an aqueous component, and is subjected to printing without subjecting to any developing treatment. The invention is not limited to it.

1. Making of Planographic Printing Plate Precursor

(1) Making of Support

<Aluminum Plate>

A molten metal of a JIS A1050 aluminum alloy composed of 99.5% by mass or more of Al, 0.30% by mass or more of Fe, 0.10% by mass or more of Si, 0.02 by mass or more of Ti, 0.013 by mass or more of Cu, and the remainder of unavoidable impurities was subjected to cleaning treatment, and casting. The cleaning treatment was conducted by degassing to remove unnecessary gas such as hydrogen from the molten metal, and treating with a ceramic tube filter.

The casting was performed by the DC casting method. The solidified ingot having a plate thickness of 500 mm was scalped to 10 mm from the surface and subjected to a homogenization treatment at 550° C. for 10 hours so as to prevent the intermetallic compound from becoming coarse. Subsequently, the plate was hot-rolled at 400° C., subjected to intermediate annealing at 500° C. for 60 seconds in a continuous annealing furnace, and then cold-rolled to obtain an aluminum rolled plate having a thickness of 0.30 mm. By controlling the roughness of the rolling roller, the center line average surface roughness Ra (according to JIS B0601) after the cold rolling was controlled to 0.2 μm. Thereafter, the plate was applied with a tension leveler to improve the flatness. The obtained aluminum plate was surface-treated as follows.

The aluminum plate was first degreased with an aqueous 10% by mass sodium aluminate solution at 50° C. for 30 seconds to remove the rolling oil on the plate surface and then treated for neutralization and desmutting with an aqueous 30% by mass nitric acid solution at 50° C. for 30 seconds.

Subsequently, the aluminum plate was subjected to a surface-roughening treatment so as to obtain good adhesion between the image recording layer and the support and at the same time to impart water receptivity to the non-image area. More specifically, while passing the aluminum plate web through an aqueous solution (liquid temperature: 45° C.) supplied to an indirect power feed cell and containing 1% by mass of nitric acid and 0.5% by mass of aluminum nitrate, the electrolysis was performed by using an alternating waveform having a duty ratio of 1:1 at a current density of 20 A/dm² to give a quantity of electricity of 240 C/dm² when the aluminum plate was serving as the anode, thereby effecting the electrochemical surface-roughening treatment.

Furthermore, the plate was etched with an aqueous 10% by mass sodium hydroxide solution at 35° C. for 30 seconds and then treated for neutralization and desmutting with an aqueous 30% by mass sulfuric acid solution at 50° C. for 30 seconds.

Thereafter, in order to improve the abrasion resistance, chemical resistance and water receptivity, the aluminum plate was subjected to an anodization treatment. More specifically, while passing the aluminum plate web through an aqueous 20% by mass sulfuric acid solution (liquid temperature: 35° C.) supplied to an indirect power feed cell, the electrolysis was performed by using a direct current at a current density of 14 A/dm² to form an anodic oxide film of 2.5 g/m².

Further, in order to ensure hydrophilicity of the non-image area the plate was subjected to a silicate treatment with 1.5% by mass of an aqueous No. 3 sodium silicate solution at 70° C. for 15 seconds. The amount of Si deposited was 10 mg/m². The resulting support was washed with water to complete the support. The obtained support had a center line average roughness Ra of 0.25 μm.

The following undercoat solution (1) was applied to the above-described support in a dry coating amount of 6 mg/m² to form an undercoat layer containing a water-soluble polymer. Thus supports used for the following experiments were made.

Undercoat solution (1)

| | | |
|---|---|---|
| Undercoat compound (1) shown below (Mw: 40,000) | 0.017 | g |
| Methanol | 9.00 | g |
| Water | 1.00 | g |

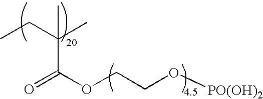

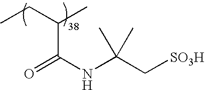

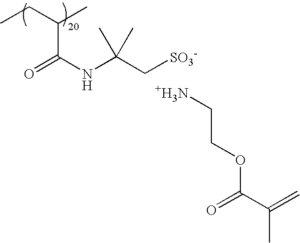

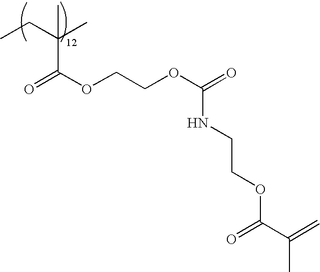

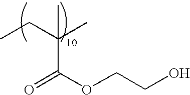

2. Making of Planographic Printing Plate Precursor

### Examples B1 to B10

The image recording layer coating solution (1) consisted of the following ingredients was applied with a wire bar to the support surface having formed with the undercoat layer. Thereafter, the coating was dried in an oven at 100° C. for 60 seconds to form an image recording layer in a dry coating amount of 1.0 g/m². (Descriptions of supports 1 to 4 are omitted.)

The image recording layer coating solution (1) was prepared by mixing and stirring the following photosensitive solution (1) and microgel solution (1) immediately before application.

Photosensitive solution (1)

| | |
|---|---|
| Binder polymer (A) (compound listed in Table 3) | 0.165 g |
| Polymerization initiator (C) (compound listed in Table 3) | 0.090 g |
| Infrared ray absorbing agent (compound listed in Table 3) | 0.020 g |
| Polymerizable compound (B) (compound listed in Table 3) | 0.385 g |
| Fluorine-based surfactant (1) | 0.044 g |
| Methyl ethyl ketone | 1.091 g |
| 2-methoxy-1-propanol | 8.609 g |

Microgel solution (1)

| | |
|---|---|
| Microgel (1) synthesized as described below | 2.640 g |
| Distilled water | 2.425 g |

The structure of the binder polymer (D) [binder polymer B-2 (Mw: 70000), binder polymer B-3 (Mw: 100000-150000)], infrared ray absorbing agent (A), polymerization initiator (B), polymerizable compound (C), and fluorine-based surfactant (1) used in the photosensitive solution (1) is shown below. 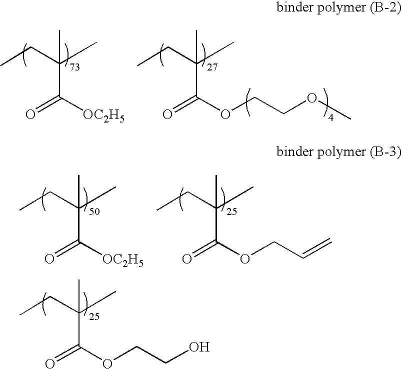
[Polymerization Initiator (C)] 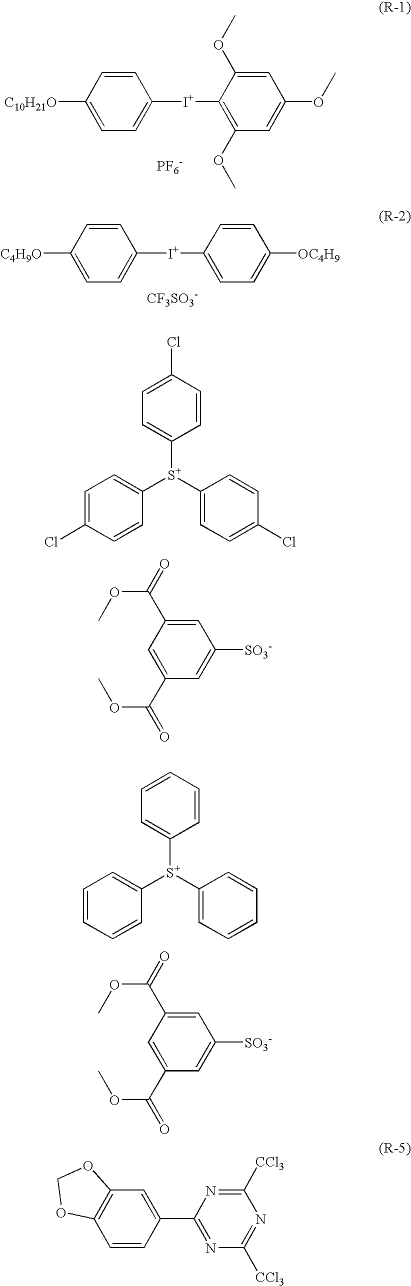
[Infrared Ray Absorbing Agent]

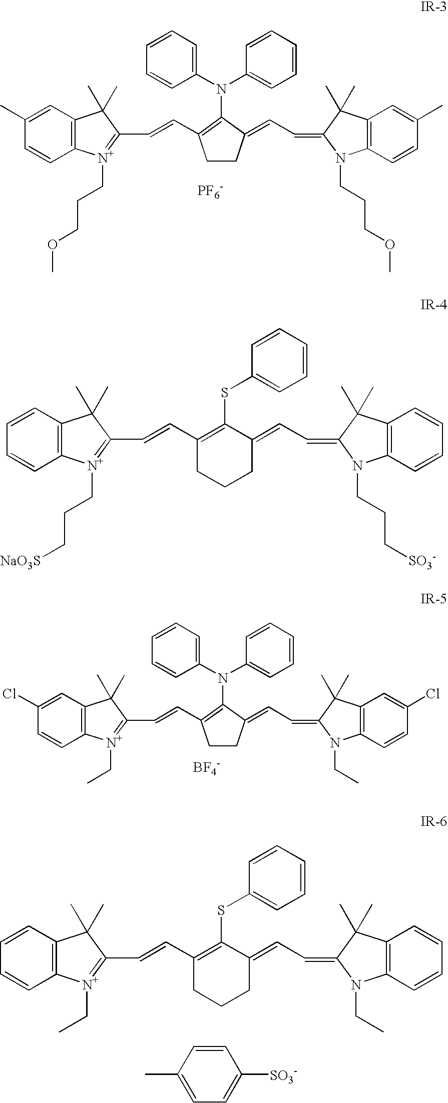

[Polymerizable Compound (B)]

M-1: ARONIX M-215 (manufactured by Toagosei Co., Ltd.)

M-2: dipentaerythritol hydroxypentaacrylate (trade name: SR-399E, manufactured by Nippon Kayaku Co., Ltd.) 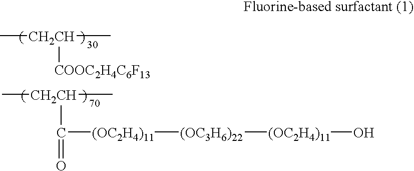
(Synthesis of Microgel (1))

As the oil phase component, 10 g of an adduct of trimethylolpropane and xylene diisocyanate (trade name: TAKENATE D-110N, manufactured by Mitsui Takeda Chemicals, Inc), 3.15 g of pentaerythritol triacrylate (trade name: SR444, manufactured by Nippon Kayaku Co., Ltd.), and 0.1 g of PIONIN A-41C (manufactured by Takemoto Oil & Fat Co., Ltd.) were dissolved in 17 g of ethyl acetate. As the aqueous phase component, 40 g of a 4% by mass aqueous solution of PVA-205 was prepared. The oil phase component was mixed with the aqueous phase component, and emulsified using a homogenizer at 12,000 rpm for 10 minutes. The emulsion thus obtained was added to 25 g of distilled water, stirred at room temperature for 30 minutes, and further stirred at 50° C. for 3 hours. The microgel solution thus obtained was diluted with distilled water in such a manner that the concentration of the solid content was 15% by mass. The average particle diameter was 0.2 μm.

The protective layer coating solution (1) consisted of the following ingredients was applied with a wire bar to the image recording layer. Thereafter, the coating was dried in an oven at 125° C. for 75 seconds to form a protective layer in a dry coating amount of 0.15 g/m². Thus a planographic printing plate precursor was obtained.

Protective layer coating solution (1)

| | | |
|---|---|---|
| 6% by mass aqueous solution of water-soluble polymer | 2.24 | g |
| (A) (polyvinyl alcohol) (trade name: PVA 105, | | |
| manufactured by Kuraray Co., Ltd., saponification | | |
| degree of 98.5 mol %, polymerization degree of 500) | | |
| Water-soluble polymer (a) [polyvinylpyrrolidone (K30)] | 0.0053 | g |
| Compound (b) having within the molecule thereof | 0.25 | g |
| an acid group and a partial structure functioning | | |
| as a base (compound listed in Table 1) | | |
| 1% by mass aqueous solution of a surfactant (trade name: | 2.15 | g |
| EMALEX 710, manufactured by Kao Corporation) | | |
| 3.4% by mass aqueous dispersion of scaly synthetic | 3.75 | g |
| mica (c-1)(trade name: MEB3L, manufactured by | | |
| UNICOO, average particle diameter 1 to 5 μmφ) | | |
| Distilled water | 10.60 | g |

Protective layer coating solution (2)

| | | |
|---|---|---|
| 6% by mass aqueous solution of water-soluble polymer | 4.12 | g |
| (A) (polyvinyl alcohol) (trade name: PVA 105, | | |
| manufactured by Kuraray Co., Ltd., saponification | | |
| degree of 98.5 mol %, polymerization degree of 500) | | |
| Water-soluble polymer (a) [polyvinylpyrrolidone (K30)] | 0.0053 | g |
| Compound (b) having within the molecule thereof an | 0.80 | g |
| acid group and a partial structure functioning as a base | | |
| (compound listed in Table 3) | | |
| 1% by mass aqueous solution of a surfactant (trade name: | 2.15 | g |
| EMALEX 710, manufactured by Kao Corporation) | | |
| Distilled water | 10.60 | g |

A

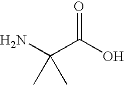

B

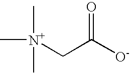

C

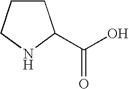

D

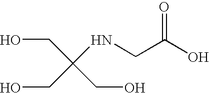

E

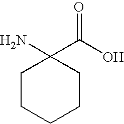

F

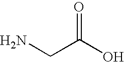

G

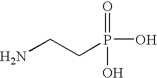

H

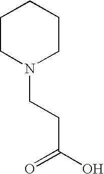

I

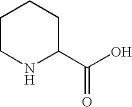

J

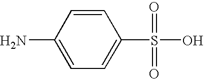

K

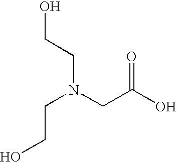

L

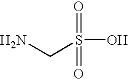

### EXAMPLES B11, B12

The image recording layer coating solution (2) consisted of the following ingredients was applied with a wire bar to each of the supports listed in Table 3. Thereafter, the coating was dried in an oven at 100° C. for 60 seconds to form an image recording layer in a dry coating amount of 1.3 g/m². Subsequently, a protective layer was formed in the same manner as Example 1. Thus planographic printing plate precursors were obtained.

Image recording layer coating solution (2)

| | |
|---|---|
| Binder polymer (A) (compound listed in Table 3) | 0.162 g |
| Polymerization initiator 1 (C) (compound listed in Table 3) | 0.160 g |
| (Polymerization initiator 2 was omitted.) | |
| Infrared ray absorbing agent (compound listed in Table 3) | 0.038 g |
| Polymerizable compound (B) (compound listed in Table 3) | 0.385 g |
| Fluorine-based surfactant (1) | 0.044 g |
| Methyl ethyl ketone | 4.091 g |
| 2-methoxy-1-propanol | 8.609 g |

3. Evaluation of Planographic Printing Plate Precursors

The planographic printing plate precursors made described above were evaluated as follows. The results are shown in the following Table 3.

<Sensitivity Evaluation>

Each of the planographic printing plate precursors was subjected to light exposure using Trendsetter 3244 VX (manufactured by Creo Products, Inc.) equipped with a water-cooled 40 W infrared semiconductor laser with an output power of 9 W, an external drum rotation speed of 210 rpm, and a resolution of 2400 dpi.

The sensitivity was evaluated in terms of the minimum amount of light required to form an image on the exposed printing plate mounted on the printing machine. The smaller number, the higher the sensitivity, and the better the performance.

(Printing: Evaluation of In-Machine Developability and Stability Over Time thereof)

Each of the planographic printing plate precursors was subjected to light exposure using Trendsetter 3244 VX (manufactured by Creo Products, Inc.) equipped with a water-cooled 40 W infrared semiconductor laser with an output power of 9 W, an external drum rotation speed of 210 rpm, and a resolution of 2400 dpi. The light-exposed image contained a thin line chart.

The light-exposed precursor was mounted on the cylinder of a printing machine (trade name: SOR-M, manufactured by Heidelberg) without being subjected to developing treatment. A dampening water [EU-3 (etching solution manufactured by Fuji Photo Film Co., Ltd.)]/water/isopropyl alcohol=1/89/10 (volume ratio)) and a black ink (trade name: TRANS-G(N), manufactured by Dainippon Ink And Chemicals, Inc.) were supplied to the precursor, and printing was conducted at a printing speed of 6,000 sheets an hour.

The in-machine developability was evaluated in terms of the number of printed sheets obtained by the time when no ink was transferred to the light-unexposed portion (non-image region) on the image recording layer. The results are shown in Table 3 as “in-machine developability”.

The light exposed precursors obtained in the same manner as described above were immersed in a constant temperature and humidity bath adjusted to 45° C., 75% RH for 3 days. Thereafter, each of the precursors was light-exposed under the above-described light exposure conditions, and mounted on the cylinder of a printing machine (trade name: SOR-M, manufactured by Heidelberg). A dampening water [IF102 (etching solution manufactured by Fuji Photo Film Co., Ltd.)]/water=4/96 (volume ratio)) and a black ink (trade name: TRANS-G(N), manufactured by Dainippon Ink And Chemicals, Inc.) were supplied to the precursor, and the in-machine developability was determined in the same manner as described above. The results are shown in Table 1 as “In-machine developability after standing high temperature and humidity environment. (The difference in the number of in-machine developed sheets before and after standing is described. The smaller the difference, the higher the stability. When the difference is within 20 sheets, the stability is regarded as favorable.

The smaller the number of in-machine developed sheets before standing, the better the developability.

TABLE 3

| | | | | | | | Evaluation result | | |
|---|---|---|---|---|---|---|---|---|---|
| | | | | | | | | Number of | |
| | | | | | | | | in-machine | |
| | | | | | | | | developed sheets | |
| | Protective layer | | Compounds used in image recording layer | | | | Number of | after standing in | |
| | | Protective | | Infrared ray | | | in-machine | high temperature | |
| | Compound | layer | Polymerization | absorbing | Binder | Polymerizable | developed | and humidity | |
| | (B) | Formulation | initiator (C) | agent | (A) | compound (B) | sheets | environment | Sensitivity |
| Example B1 | A | 1 | R-3 | IR-3 | B-2 | M-1 | 24 | 38 | 80 |
| Example B2 | B | 2 | R-4 | IR-3 | B-2 | M-2 | 24 | 39 | 80 |
| Example B3 | C | 1 | R-1 | IR-3 | B-2 | M-1 | 20 | 25 | 70 |
| Example B4 | D | 2 | R-2 | IR-3 | B-2 | M-2 | 23 | 30 | 70 |
| Example B5 | E | 1 | R-1 | IR-4 | B-2 | M-1 | 22 | 27 | 75 |
| Example B6 | F | 2 | R-5 | IR-4 | B-3 | M-1 | 28 | 45 | 80 |
| Example B7 | G | 1 | R-5 | IR-3 | B-2 | M-2 | 26 | 44 | 80 |
| Example B8 | H | 1 | R-2 | IR-3 | B-3 | M-2 | 23 | 33 | 70 |
| Example B9 | I | 2 | R-1 | IR-3 | B-2 | M-1 | 21 | 27 | 70 |
| Example B10 | J | 1 | R-3 | IR-4 | B-3 | M-1 | 25 | 36 | 80 |
| Example B11 | K | 1 | R-1 | IR-5 | B-2 | M-1 | 21 | 26 | 70 |
| Example B12 | L | 2 | R-5 | IR-6 | B-2 | M-2 | 28 | 46 | 80 |
| Comparative | — | 1 | R-3 | IR-3 | B-2 | M-1 | 40 | 68 | 80 |
| example B1 | | | | | | | | | |
| Comparative | — | 2 | R-5 | IR-6 | B-2 | M-2 | 43 | 75 | 80 |
| example B2 | | | | | | | | | |

As evident from Table 3, according to the planographic printing method of the invention using the planographic printing plate precursor any of Examples 1 to 10 of the invention, excellent in-machine developability which is stable over time is provided with high sensitivity equivalent to that achieved with the planographic printing plate precursors having a prior art protective layer (Comparative Examples 1 and 2) is maintained. The results of Examples 11 and 12 show that the similar effects are achieved even the Formulation of the image recording layer is changed. Further, the comparison between the results of the protective layers 1 and 2 show that the addition of the inorganic layered compound (C-1) to the specific protective layer of the invention further improves the in-machine developability and stability thereof.

The present invention provides a recording material having favorable developability and this material can form the image with sufficient curing property by exposure.

Further, the invention provides: a planographic printing plate method which provides excellent in-machine developability which will not decrease even after storage, wherein an image is drawn directly from digital data such as computer data and recorded on a planographic printing plate precursor capable of image recording using an infrared laser, and the plate is in-machine developed without subjecting the planographic plate precursor to any wet developing process; and a planographic printing plate precursor which is preferably used for the planographic printing plate method and has excellent in-machine developability which is stable over time.

The invention also includes the following embodiments.

<1> An image recording material comprising a support having provided thereon in this order an image recording layer containing a binder polymer (A), a compound having a polymerizable unsaturated group (B), and a polymerization initiator (C), and a layer containing a hydrophilic polymer and a compound having within the molecule thereof an acid group and a partial structure functioning as a base.

<2> The image recording material of item <1>, wherein the image recording layer further comprises a dye (D) having an absorption maximum in a range of from 300 to 1200 nm.

<3> The image recording material of item <2>, wherein the dye (D) having an absorption maximum in a range of from 300 to 1200 nm is an infrared dye.

<4> The image recording material of any one of items <1> to <3>, wherein the binder polymer (A) is a polymer having within the molecule thereof an alkali-soluble group.

<5> The image recording material of item <1>, wherein the layer containing a hydrophilic polymer and a compound having within the molecule thereof an acid group and a partial structure functioning as a base further comprise an inorganic compound.

<6> The image recording material of item <1>, wherein the polymerization initiator (C) is an onium salt.

<7> A planographic printing method comprising an exposure process of imagewise exposing a planographic printing plate precursor to radiation, a process of developing the printing plate precursor, and a printing process of performing printing using an oil-based ink, wherein the planographic printing plate precursor comprises a support having provided thereon in this order an image recording layer which is recordable by irradiation with radiation and contains a binder polymer (A), a compound having a polymerizable unsaturated group (B), and a polymerization initiator (C), and a layer containing a hydrophilic polymer and a compound having within the molecule thereof an acid group and a partial structure functioning as a base.

<8> The planographic printing method of item <7>, wherein the binder polymer (A) is a polymer having within the molecule thereof an alkali soluble group.

<9> The planographic printing method of items <7> or <8>, wherein the layer containing a hydrophilic polymer and a compound having within the molecule thereof an acid group and a partial structure functioning as a base further comprises an inorganic compound.

<10> The planographic printing method of any one of items <7> to <9>, wherein the layer containing a hydrophilic polymer and a compound having within the molecule thereof an acid group and a partial structure functioning as a base further comprises an inorganic compound.

<11.> A planographic printing method comprising an exposure process of imagewise exposing a planographic printing plate precursor to infrared laser light, and a printing process of subjecting the light-exposed planographic printing plate precursor to printing using an oil-based ink and an aqueous component without subjecting the planographic printing plate precursor to any developing, wherein the planographic printing plate precursor comprises a support having provided thereon in this order an image recording layer which is recordable by irradiation with infrared ray and contains a binder polymer (A), a compound having a polymerizable unsaturated group (B), a polymerization initiator (C), and an infrared ray absorbing agent (D), and a layer containing a hydrophilic polymer and a compound having within the molecule thereof an acid group and a partial structure functioning as a base, and a portion of the planographic printing plate precursor unexposed to the infrared laser light is removed during printing.

<12> A planographic printing plate precursor comprising a support having provided thereon in this order an image recording layer containing an infrared ray absorbing agent (A), a polymerization initiator (B), a polymerizable compound (C), and a binder polymer (D), and a layer containing a hydrophilic polymer and a compound having within the molecule thereof an acid group and a partial structure functioning as a base, wherein a non-image region is removable with a printing ink and/or dampening water.

<13> The planographic printing plate precursor of items <11> or <12>, wherein the layer containing a hydrophilic polymer and a compound having within the molecule thereof an acid group and a partial structure functioning as a base further comprises an inorganic compound.

All publications, patent applications, and technical standards mentioned in this specification are herein incorporated by reference to the same extent as if such individual publication, patent application, or technical standard was specifically and individually indicated to be incorporated by reference.

It will be obvious to those having skill in the art that many changes may be made in the above-described details of the preferred embodiments of the present invention. The scope of the invention, therefore, should be determined by the following claims.

What is claimed is:

1. An image recording material comprising a support having provided thereon in this order an image recording layer containing a binder polymer (A), a compound having a polymerizable unsaturated group (B), and a polymerization initiator (C), and a layer containing a hydrophilic polymer and a compound having within the molecule thereof an acid group and a partial structure functioning as a base.

2. The image recording material of claim 1, wherein the image recording layer further comprises a dye (D) having an absorption maximum in a range of from 300 to 1200 nm.

3. The image recording material of claim 2, wherein the dye (D) having an absorption maximum in a range of from 300 to 1200 nm is an infrared dye.

4. The image recording material of claim 1, wherein the binder polymer (A) is a polymer having within the molecule thereof an alkali-soluble group.

5. The image recording material of claim 3, wherein the binder polymer (A) is a polymer having within the molecule thereof an alkali-soluble group.

6. The image recording material of claim 1, wherein the layer containing a hydrophilic polymer and a compound having within the molecule thereof an acid group and a partial structure functioning as a base further comprises an inorganic compound.

7. The image recording material of claim 1, wherein the polymerization initiator (C) is an onium salt.

8. A planographic printing method comprising an exposure process of imagewise exposing a planographic printing plate precursor to radiation, a process of developing the printing plate precursor, and a printing process of performing printing using an oil-based ink, wherein the planographic printing plate precursor comprises the image recording material of claim 1.

9. The planographic printing method of claim 8, wherein the binder polymer (A) is a polymer having within the molecule thereof an alkali soluble group.

10. The planographic printing method of claim 8, wherein the layer containing a hydrophilic polymer and a compound having within the molecule thereof an acid group and a partial structure functioning as a base further comprises an inorganic compound.

11. The planographic printing method of claim 9, wherein the layer containing a hydrophilic polymer and a compound having within the molecule thereof an acid group and a partial structure functioning as a base further comprises an inorganic compound.

12. A planographic printing method comprising an exposure process of imagewise exposing a planographic printing plate precursor to infrared laser light, and a printing process of subjecting the light-exposed planographic printing plate precursor to printing using an oil-based ink and an aqueous component without subjecting the planographic printing plate precursor to any developing, wherein the planographic printing plate precursor comprises a support having provided thereon in this order an image recording layer which is recordable by irradiation with infrared ray and contains a binder polymer (A), a compound having a polymerizable unsaturated group (B), a polymerization initiator (C), and an infrared ray absorbing agent, and a layer containing a hydrophilic polymer and a compound having within the molecule thereof an acid group and a partial structure functioning as a base, and a portion of the planographic printing plate precursor unexposed to the infrared laser light is removed during printing.

13. The planographic printing method of claim 12, wherein the layer containing a hydrophilic polymer and a compound having within the molecule thereof an acid group and a partial structure functioning as a base further comprises an inorganic compound.

14. A planographic printing plate precursor comprising a support having provided thereon in this order an image recording layer containing a binder polymer (A), a compound having a polymerizable unsaturated group (B), a polymerization initiator (C), and an infrared ray absorbing agent and a layer containing a hydrophilic polymer and a compound having within the molecule thereof an acid group and a partial structure functioning as a base, wherein a non-image region is removable with a printing ink and/or dampening water.

15. The planographic printing plate precursor of claim 14, wherein the layer containing a hydrophilic polymer and a compound having within the molecule thereof an acid group and a partial structure functioning as a base further comprises an inorganic compound.
